(19) United States
(12) Patent Application Publication
(10) Pub. No.: US 2025/0234505 A1
(43) Pub. Date: Jul. 17, 2025

(54) SEMICONDUCTOR DEVICE

(71) Applicant: SEMICONDUCTOR ENERGY LABORATORY CO., LTD., Atsugi-shi (JP)

(72) Inventors: Hiromi SAWAI, Atsugi (JP); Motomu KURATA, Isehara (JP); Tsutomu MURAKAWA, Atsugi (JP); Sachiaki TEZUKA, Atsugi (JP); Fumito ISAKA, Zama (JP); Shunpei YAMAZAKI, Tokyo (JP)

(21) Appl. No.: 19/009,189

(22) Filed: Jan. 3, 2025

(30) Foreign Application Priority Data
Jan. 12, 2024 (JP) 2024-003487
Jan. 12, 2024 (JP) 2024-003489
Feb. 16, 2024 (JP) 2024-022000

(51) Int. Cl. H10B 12/00

(52) U.S. Cl. CPC H10B 12/30; H10B 12/05

(57) ABSTRACT

A semiconductor device with high field-effect mobility is provided. The semiconductor device includes an oxide semiconductor; a first conductor and a second conductor separated from each other over the oxide semiconductor; a first insulator that are placed over the first conductor and the second conductor and includes an opening overlapping with a region between the first conductor and the second conductor; a second insulator that is placed in the opening in the first insulator and is in contact with the top surface of the oxide semiconductor, a side surface of the first conductor, a side surface of the second conductor, and a side surface of the first insulator; and a third conductor that is placed over the second insulator in the opening in the first insulator and includes a region overlapping with the oxide semiconductor with the second insulator therebetween. The oxide semiconductor includes a first layer, a second layer over the first layer, and a third layer over the second layer in a region overlapping with the third conductor. The first layer includes gallium. The second layer includes indium oxide. The third layer includes indium, gallium, and oxygen. The indium content of the second layer is higher than the indium content of the third layer.

### BACKGROUND OF THE INVENTION

### 1. Field of the Invention

One embodiment of the present invention relates to a semiconductor device, a memory device, and an electronic appliance each including an oxide semiconductor. Another embodiment of the present invention relates to a method for manufacturing the semiconductor device.

Note that one embodiment of the present invention is not limited to the above technical field. Examples of the technical field of one embodiment of the present invention include a semiconductor device, a display apparatus, a light-emitting apparatus, a power storage device, a memory device, an electronic appliance, a lighting device, an input device (e.g., a touch sensor), an input/output device (e.g., a touch panel), driving methods thereof, and manufacturing methods thereof.

In this specification and the like, a semiconductor device generally means a device that can function by utilizing semiconductor properties. A semiconductor element such as a transistor, a semiconductor circuit, an arithmetic device, and a memory device are each an embodiment of a semiconductor device. A display apparatus (e.g., a liquid crystal display apparatus and a light-emitting display apparatus), a projection device, a lighting device, an electro-optical device, a power storage device, a memory device, a semiconductor circuit, an imaging device, an electronic appliance, and the like may include a semiconductor device.

### 2. Description of the Related Art

In recent years, semiconductor devices have been developed, and large scale integrations (LSIs), central processing units (CPUs), memories, and the like are mainly used in semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic appliances.

A technique by which a transistor is formed using a semiconductor thin film formed over a substrate having an insulating surface has been attracting attention. The transistor is used in a wide range of electronic devices such as an integrated circuit (IC) and an image display apparatus (also simply referred to as a display apparatus). A silicon-based semiconductor material is widely known as a material of a semiconductor thin film that can be used in a transistor. As another material, an oxide semiconductor has been attracting attention.

It is known that a transistor including an oxide semiconductor has an extremely low leakage current in an off state. For example, Patent Document 1 discloses a low-power CPU utilizing a characteristic of a low leakage current of a transistor including an oxide semiconductor. As another example, Patent Document 2 discloses a memory device that can retain stored data for a long time by utilizing a characteristic of a low leakage current of a transistor including an oxide semiconductor.

### REFERENCES

[Patent Document 1] Japanese Published Patent Application No. 2012-257187
[Patent Document 2] Japanese Published Patent Application No. 2011-151383

### SUMMARY OF THE INVENTION

An object of one embodiment of the present invention is to provide a semiconductor device with high field-effect mobility. Another object of one embodiment of the present invention is to provide a semiconductor device with favorable electrical characteristics. Another object of one embodiment of the present invention is to provide a highly reliable semiconductor device. Another object of one embodiment of the present invention is to provide a semiconductor device that can be miniaturized or highly integrated. Another object of one embodiment of the present invention is to provide a semiconductor device that operates at high speed. Another object of one embodiment of the present invention is to provide a semiconductor device with low power consumption. Another object of one embodiment of the present invention is to provide a semiconductor device with a small variation in electrical characteristics of transistors. Another object of one embodiment of the present invention is to provide a novel semiconductor device. Another object of one embodiment of the present invention is to provide a method for manufacturing a semiconductor device with high productivity. Another object of one embodiment of the present invention is to provide a method for manufacturing a novel semiconductor device. Another object of one embodiment of the present invention is to provide a novel display apparatus.

Note that the description of these objects does not preclude the existence of other objects. One embodiment of the present invention does not necessarily achieve all of these objects. Other objects can be derived from the description of the specification, the drawings, and the claims.

One embodiment of the present invention is a semiconductor device including an oxide semiconductor; a first conductor and a second conductor separated from each other over the oxide semiconductor; a first insulator that is placed over the first conductor and the second conductor and includes an opening overlapping with a region between the first conductor and the second conductor; a second insulator that is placed in the opening and is in contact with the top surface of the oxide semiconductor, a side surface of the first conductor, a side surface of the second conductor, and a side surface of the first insulator; and a third conductor that is placed over the second insulator in the opening and includes a region overlapping with the oxide semiconductor with the second insulator therebetween. The oxide semiconductor includes a first layer, a second layer over the first layer, and a third layer over the second layer in a region overlapping with the third conductor. The first layer includes gallium and oxygen. The second layer includes indium oxide. The third layer includes indium, gallium, and oxygen. The indium content of the second layer is higher than the indium content of the third layer.

In the above semiconductor device, the conduction band minimum of the first layer is preferably closer to the vacuum level than the conduction band minimum of the second layer is, and the conduction band minimum of the third layer is preferably closer to the vacuum level than the conduction band minimum of the second layer is.

In the above semiconductor device, the first layer preferably includes indium, and the indium content is preferably lower than the gallium content in the first layer.

In the above semiconductor device, a side surface of part of the first insulator is preferably aligned or substantially aligned with the side surface of the first conductor and the side surface of the second conductor in a plan view.

The above semiconductor device preferably includes a third insulator in contact with the top surface of the third conductor, an upper end portion of the second insulator, and the top surface of the first insulator; and a fourth insulator in contact with the top surface of the third insulator.

In the above semiconductor device, the third insulator preferably includes aluminum oxide.

In the above semiconductor device, the fourth insulator preferably includes silicon nitride.

In the above semiconductor device, the first conductor and the second conductor each preferably include a first conductive layer and a second conductive layer over the first conductive layer, and the shortest distance between the first conductive layer of the first conductor and the first conductive layer of the second conductor is preferably smaller than the shortest distance between the second conductive layer of the first conductor and the second conductive layer of the second conductor.

In the above semiconductor device, a side surface of part of the first insulator is preferably aligned or substantially aligned with a side surface of the second conductive layer of the first conductor and a side surface of the second conductive layer of the second conductor in a plan view.

In the above semiconductor device, the first conductive layer of the first conductor and the first conductive layer of the second conductor each preferably include tantalum nitride.

The above semiconductor device preferably includes a fifth insulator. Preferably, the fifth insulator is placed in the opening and is in contact with the top surface of the first conductive layer of the first conductor, the side surface of the second conductive layer of the first conductor, the top surface of the first conductive layer of the second conductor, and the side surface of the second conductive layer of the second conductor. The fifth insulator preferably includes an opening overlapping with a region between the first conductive layer of the first conductor and the first conductive layer of the second conductor.

In the above semiconductor device, the fifth insulator preferably includes silicon nitride.

In the above semiconductor device, the second insulator preferably includes a first insulating layer, and the first insulating layer preferably includes oxide including hafnium.

In the above semiconductor device, the first insulating layer preferably includes hafnium zirconium oxide.

In the above semiconductor device, the second insulator preferably includes a second insulating layer over the first insulating layer, and the second insulating layer preferably includes silicon nitride.

One embodiment of the present invention can provide a semiconductor device with high field-effect mobility. Another embodiment of the present invention can provide a semiconductor device with favorable electrical characteristics. Another embodiment of the present invention can provide a highly reliable semiconductor device. Another embodiment of the present invention can provide a semiconductor device that can be miniaturized or highly integrated. An embodiment of the present invention can provide a semiconductor device that operates at high speed. Another embodiment of the present invention can provide a semiconductor device with low power consumption. Another embodiment of the present invention can provide a semiconductor device with a small variation in electrical characteristics of transistors. Another embodiment of the present invention can provide a novel semiconductor device. Another embodiment of the present invention can provide a method for manufacturing a semiconductor device with high productivity. Another embodiment of the present invention can provide a method for manufacturing a novel semiconductor device. Another embodiment of the present invention can provide a novel display apparatus.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIG. 1A is a plan view illustrating an example of a semiconductor device, and FIGS. 1B to 1D are cross-sectional views illustrating an example of the semiconductor device;

FIGS. 2A and 2B are cross-sectional views illustrating an example of a semiconductor device;

FIGS. 3A to 3E are cross-sectional views illustrating examples of a semiconductor device;

FIG. 4A is a plan view illustrating an example of a semiconductor device, and FIGS. 4B to 4D are cross-sectional views illustrating an example of the semiconductor device;

FIG. 5A is a plan view illustrating an example of a semiconductor device, and FIGS. 5B to 5D are cross-sectional views illustrating an example of the semiconductor device;

FIGS. 6A to 6C are cross-sectional views illustrating examples of a semiconductor device;

FIG. 7A is a plan view illustrating an example of a semiconductor device, and FIGS. 7B to 7D are cross-sectional views illustrating an example of the semiconductor device;

FIG. 8 is a cross-sectional view illustrating an example of a semiconductor device;

FIG. 9A is a plan view illustrating an example of a method for manufacturing a semiconductor device, and FIGS. 9B to 9D are cross-sectional views illustrating the example of the method for manufacturing the semiconductor device;

FIG. 10A is a plan view illustrating an example of a method for manufacturing a semiconductor device, and FIGS. 10B to 10D are cross-sectional views illustrating the example of the method for manufacturing the semiconductor device;

FIG. 11A is a plan view illustrating an example of a method for manufacturing a semiconductor device, and FIGS. 11B to 11D are cross-sectional views illustrating the example of the method for manufacturing the semiconductor device;

FIG. 12A is a plan view illustrating an example of a method for manufacturing a semiconductor device, and FIGS. 12B to 12D are cross-sectional views illustrating the example of the method for manufacturing the semiconductor device;

FIGS. 13A1 to 13D2 are cross-sectional views illustrating an example of a method for manufacturing a semiconductor device;

FIG. 14A is a plan view illustrating an example of a method for manufacturing a semiconductor device, and FIGS. 14B to 14D are cross-sectional views illustrating the example of the method for manufacturing the semiconductor device;

FIG. 15A is a plan view illustrating an example of a method for manufacturing a semiconductor device, and FIGS. 15B to 15D are cross-sectional views illustrating the example of the method for manufacturing the semiconductor device;

FIG. 16A is a plan view illustrating an example of a method for manufacturing a semiconductor device, and FIGS. 16B to 16D are cross-sectional views illustrating the example of the method for manufacturing the semiconductor device;

FIG. 17 is a band diagram of an oxide semiconductor;

FIG. 18 is a graph showing an example of hysteresis properties;

FIGS. 19A to 19C are equivalent circuit diagrams of a semiconductor device, and FIG. 19D shows an example of Id-Vg characteristics of a transistor;

FIG. 20A is a timing chart for explaining operation of a semiconductor device, and FIG. 20B is a circuit diagram for explaining operation of the semiconductor device;

FIG. 21A is a timing chart for explaining operation of a semiconductor device, and FIG. 21B is a circuit diagram for explaining operation of the semiconductor device;

FIG. 22A is a timing chart for explaining operation of a semiconductor device, and FIG. 22B is a circuit diagram for explaining operation of the semiconductor device;

FIG. 23 is a block diagram illustrating a structure example of a semiconductor device;

FIGS. 24A to 24H each illustrate a circuit structure example of a memory cell;

FIG. 25 is a cross-sectional view illustrating an example of a semiconductor device;

FIGS. 26A and 26B are perspective views each illustrating a structure example of a semiconductor device;

FIG. 27 is a cross-sectional view illustrating an example of a semiconductor device;

FIG. 28 is a cross-sectional view illustrating an example of a semiconductor device;

FIG. 29 is a block diagram illustrating a CPU;

FIGS. 30A and 30B are perspective views illustrating a structure example of a semiconductor device;

FIGS. 31A and 31B are perspective views each illustrating a structure example of a semiconductor device;

FIGS. 32A and 32B each illustrate a hierarchy of various kinds of memory devices;

FIGS. 33A and 33B illustrate examples of electronic appliances, and FIGS. 33C to 33E illustrate an example of a large computer;

FIG. 34 illustrates an example of space equipment;

FIG. 35 illustrates an example of a storage system that can be used in a data center;

FIGS. 36A and 36B illustrate a structure example of a display apparatus;

FIG. 37 illustrates a structure example of a display apparatus;

FIG. 38 illustrates a structure example of a display apparatus;

FIG. 39 illustrates a structure example of a display apparatus;

FIGS. 40A to 40D illustrate structure examples of a display apparatus;

FIGS. 41A and 41B illustrate structure examples of display apparatuses;

FIGS. 42A and 42B illustrate a structure example of a display apparatus;

FIGS. 43A to 43D illustrate structure examples of display apparatuses;

FIGS. 44A to 44D illustrate structure examples of display apparatuses;

FIG. 45 illustrates a structure example of a display apparatus;

FIGS. 46A to 46F illustrate structure examples of electronic appliances;

FIGS. 47A to 47F illustrate structure examples of electronic appliances; and

FIGS. 48A to 48G illustrate structure examples of electronic appliances.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

Note that the terms “film” and “layer” can be used interchangeably depending on the case or the circumstances. For example, the term “conductive layer” can be replaced with the term “conductive film”. The term “insulating film” can be replaced with the term “insulating layer”. The term “oxide semiconductor film” can be replaced with the term “oxide semiconductor layer”. The term “conductor” can be replaced with the term “conductive layer” or “conductive film” depending on the case or the circumstances. The term “insulator” can be replaced with the term “insulating layer” or “insulating film” depending on the case or the circumstances. The term “oxide semiconductor” can be replaced with the term “oxide semiconductor layer” or “oxide semiconductor film” depending on the case or the circumstances.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −20° and less than or equal to 20°. The term “perpendicular” indicates that the angle formed between two straight lines is greater than or equal to 800 and less than or equal to 100°. Thus, the case where the angle is greater than or equal to 850 and less than or equal to 950 is also included. The term “substantially perpendicular” indicates that the angle formed between two straight lines is greater than or equal to 700 and less than or equal to 110°.

The term “opening” includes a groove and a slit, for example. A region where an opening is formed is referred to as an opening portion in some cases.

In the drawings used in this specification and the like, a sidewall of an insulator in an opening is perpendicular or substantially perpendicular to a substrate surface or a formation surface, but the sidewall may be tapered.

In this specification and the like, a tapered shape refers to a shape such that at least part of a side surface of a component is inclined with respect to a substrate surface or a formation surface. For example, the tapered shape preferably includes a region where the angle between the inclined side surface and the substrate surface or the formation surface (the angle is hereinafter referred to as a taper angle in some cases) is less than 90°. Note that the side surface of the component and the substrate surface are not necessarily completely flat and may be substantially flat with a slight curvature or with slight unevenness.

In this specification and the like, a transistor including an oxide semiconductor or a metal oxide in its semiconductor layer and a transistor including an oxide semiconductor or a metal oxide in its channel formation region are each sometimes referred to as an OS transistor. A transistor including silicon in its channel formation region is sometimes referred to as a Si transistor.

### Embodiment 1

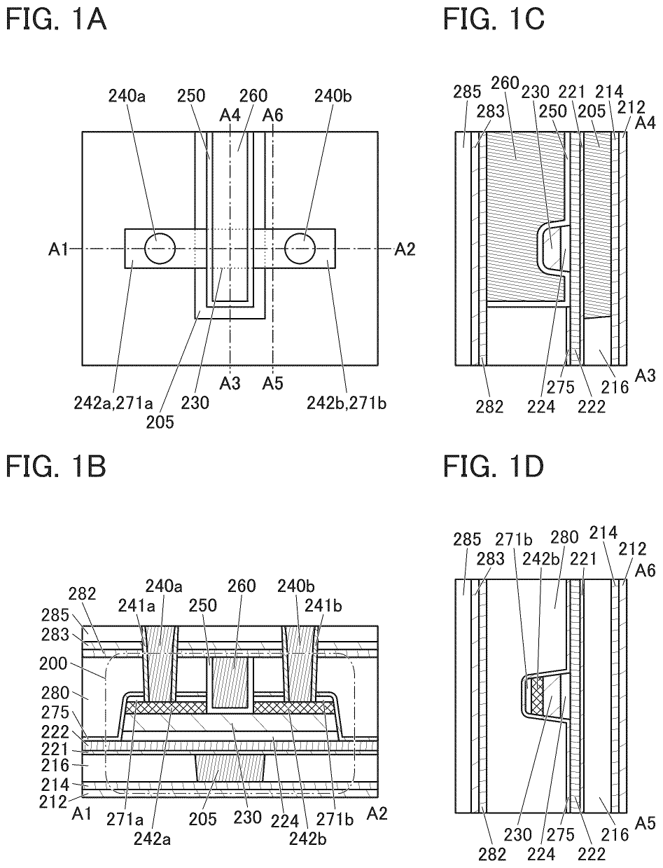

In this embodiment, a semiconductor device including an oxide semiconductor and a method for manufacturing the semiconductor device will be described with reference to FIGS. 1A to 1D to FIGS. 16A to 16D.

### <Structure Example of Semiconductor Device>

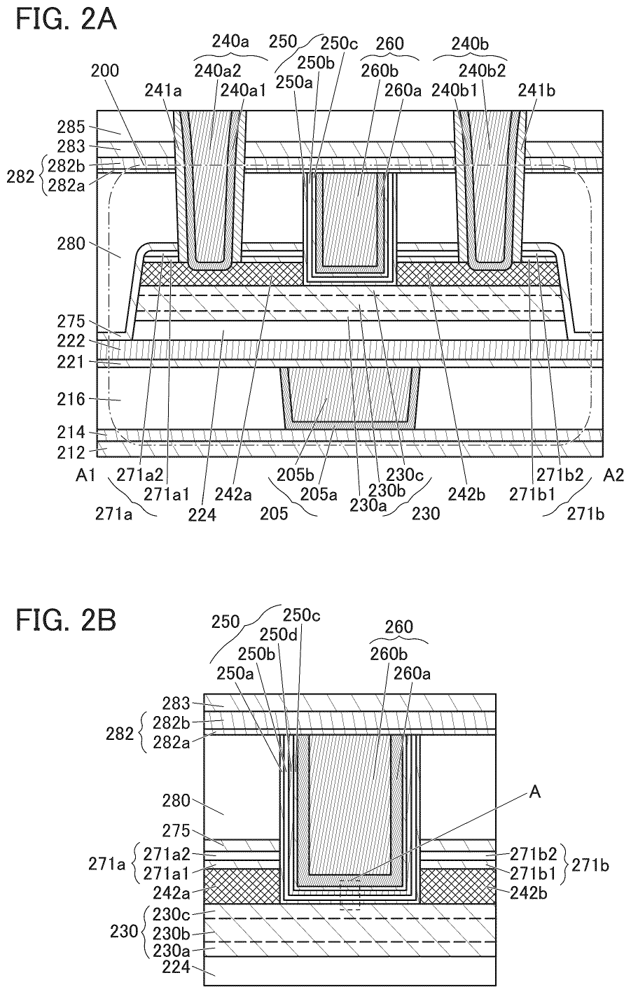

A structure example of a semiconductor device is described with reference to FIGS. 1A to 1D and FIGS. 2A and 2B. FIGS. 1A to 1D are a plan view and cross-sectional views of a semiconductor device (a transistor 200). FIG. 1A is the plan view of the semiconductor device. FIGS. 1B to 1D are the cross-sectional views of the semiconductor device. FIG. 1B illustrates a cross section taken along the dashed-dotted line A1-A2 in FIG. 1A, which corresponds to a cross-sectional view of the transistor 200 in the channel length direction. FIG. 1C illustrates a cross section taken along the dashed-dotted line A3-A4 in FIG. 1A, which corresponds to a cross-sectional view of the transistor 200 in the channel width direction. FIG. 1D illustrates a cross section taken along the dashed-dotted line A5-A6 in FIG. 1A, which corresponds to a cross-sectional view of the transistor 200 in the channel width direction. Note that for simplification, some components are not illustrated in the plan view in FIG. 1A. FIGS. 2A and 2B are enlarged cross-sectional views of the transistor 200 in the channel length direction.

The transistor 200 includes a conductor 205 embedded in an insulator 216, an insulator 221 over the insulator 216 and the conductor 205, an insulator 222 over the insulator 221, an insulator 224 over the insulator 222, an oxide semiconductor 230 over the insulator 224, conductors 242a and 242b over the oxide semiconductor 230, an insulator 271a over the conductor 242a, an insulator 271b over the conductor 242b, an insulator 250 over the oxide semiconductor 230, and a conductor 260 over the insulator 250.

The oxide semiconductor 230 includes a region functioning as a channel formation region of the transistor 200. The conductor 260 includes a region that functions as a first gate electrode (also referred to as an upper gate electrode or a top gate electrode) of the transistor 200. The insulator 250 includes a region functioning as a first gate insulator of the transistor 200. The conductor 205 includes a region that functions as a second gate electrode (also referred to as a lower gate electrode or a bottom gate electrode) of the transistor 200. Each of the insulators 224, 222, and 221 includes a region that functions as a second gate insulator of the transistor 200. The conductor 242a includes a region functioning as one of a source electrode and a drain electrode of the transistor 200. The conductor 242b includes a region functioning as the other of the source electrode and the drain electrode of the transistor 200.

An insulator 275 is provided over the insulators 271a and 271b, and an insulator 280 is provided over the insulator 275. An opening reaching the insulator 222 and the oxide semiconductor 230 is formed in the insulators 280 and 275, and the opening overlaps with a region between the conductor 242a and the conductor 242b. In a top view (also referred to as a plan view), the side surface of the insulator 280 in the opening is aligned or substantially aligned with the side surface of the conductor 242a and the side surface of the conductor 242b. The insulator 250 and the conductor 260 are provided in an opening formed in the insulator 280 and the insulator 275. An insulator 282 is provided in contact with the top surface of the insulator 280, the upper end portion of the insulator 250, and the top surface of the conductor 260. An insulator 283 is provided over the insulator 282. An insulator 285 is provided over the insulator 283. An insulator 214 is provided under the insulator 216 and the conductor 205. An insulator 212 is provided under the insulator 214. The insulators 212, 214, 280, 282, 283, and 285 each function as an interlayer film.

An opening reaching the conductor 242a is formed in the insulators 285, 283, 282, 280, 275, and 271a, and a conductor 240a and an insulator 241a are provided in the opening. The insulator 241a is provided in contact with a sidewall of the opening, and the conductor 240a is provided inward from the insulator 241a. An opening reaching the conductor 242b is formed in the insulators 285, 283, 282, 280, 275, and 271b, and an conductor 240b and an insulator 241b are provided in the opening. The insulator 241b is provided in contact with a sidewall of the opening, and the conductor 240b is provided inward from the insulator 241b. The conductors 240a and 240b function as vias that connect a wiring or the like provided over the transistor 200 to the source or the drain of the transistor 200.

The oxide semiconductor 230 includes a channel formation region. The oxide semiconductor 230 also includes a source region and a drain region. The source region and the drain region are n-type regions (low-resistance regions) having a higher carrier concentration than the channel formation region. The oxide semiconductor 230 may have a single-layer structure or a stacked-layer structure of two or more layers.

There is no particular limitation on the crystallinity of a semiconductor material used for the oxide semiconductor 230, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable to use a single crystal semiconductor or a semiconductor having crystallinity, in which case deterioration of the transistor characteristics can be suppressed.

The band gap of a metal oxide functioning as a semiconductor is preferably greater than or equal to 2.0 eV, further preferably greater than or equal to 2.5 eV. The use of a metal oxide having a wide band gap for the oxide semiconductor 230 can reduce the off-state current of the transistor 200. The off-state current of the OS transistor is low, so that power consumption of the semiconductor device can be sufficiently reduced. The OS transistor has high frequency characteristics, which enables the semiconductor device to operate at high speed.

The description in Embodiment 2 can be referred to for the oxide semiconductor that can be used for the semiconductor layer of the transistor of one embodiment of the present invention. Here, the detailed description is omitted.

Note that for the semiconductor device of this embodiment, a transistor including another semiconductor material in a channel formation region may be used. Examples of another semiconductor material include a single-element semiconductor and a compound semiconductor.

Examples of the single-element semiconductor that can be used as the semiconductor material include silicon and germanium. Examples of silicon that can be used as the semiconductor material include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure. Other examples of the compound semiconductor include an organic semiconductor and a nitride semiconductor. Note that the above-described oxide semiconductor is also a kind of compound semiconductor. These semiconductor materials may include an impurity as a dopant.

Here, the oxide semiconductor 230 used in the semiconductor device preferably includes an indium-containing oxide. For example, indium oxide, indium gallium oxide, indium zinc oxide, indium gallium zinc oxide, or indium gallium tin zinc oxide can be used as the oxide semiconductor 230. Moreover, the oxide semiconductor 230 can have a stacked-layer structure. For example, the oxide semiconductor 230 can have a stacked-layer structure of indium oxide and indium gallium zinc oxide over the indium oxide. Furthermore, as illustrated in FIG. 2A, the oxide semiconductor 230 can include an oxide semiconductor 230a over the insulator 224, an oxide semiconductor 230b over the oxide semiconductor 230a, and an oxide semiconductor 230c over the oxide semiconductor 230b. For example, indium oxide can be used as the oxide semiconductor 230b, and indium gallium zinc oxide can be used as the oxide semiconductors 230a and 230c. With the oxide semiconductor 230 including an indium-containing oxide as described above, it is possible to provide a semiconductor device having high field-effect mobility. It is also possible to provide a semiconductor device having at least one of favorable electrical characteristics, high frequency characteristics, and high reliability. The description in Embodiment 2 can be referred to for a specific structure of the oxide semiconductor 230.

In the oxide semiconductor 230, a channel formation region and source and drain regions of the transistor 200 are formed. The channel formation region is sandwiched between the source and drain regions. At least a part of the channel formation region overlaps with the conductor 260. The source region overlaps with the conductor 242a, and the drain region overlaps with the conductor 242b. Note that the source region and the drain region can be interchanged with each other.

The channel formation region has a smaller amount of oxygen vacancies or a lower concentration of impurities than the source and drain regions, and thus is a high-resistance region with a low carrier concentration. Thus, the channel formation region can be regarded as an i-type (intrinsic) or substantially i-type region.

The source and drain regions have a large amount of oxygen vacancies or a high concentration of impurities such as hydrogen, nitrogen, or a metal element, and thus are low-resistance regions with a high carrier concentration. In other words, the source and drain regions are n-type regions (low-resistance regions) having a higher carrier concentration than the channel formation region.

Note that the carrier concentration in the channel formation region is preferably lower than or equal to 1×10¹⁸ cm⁻³, lower than 1×10⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the channel formation region is not particularly limited and can be, for example, 1×10⁻⁹ cm⁻³.

In order to reduce the carrier concentration of the oxide semiconductor 230, the concentration of impurities in the oxide semiconductor 230 is reduced so that the density of defect states is reduced. In this specification and the like, a state with a low concentration of impurities and a low density of defect states is referred to as a highly purified intrinsic or substantially highly purified intrinsic state. Note that an oxide semiconductor (or metal oxide) having a low carrier concentration may be referred to as a highly purified intrinsic or substantially highly purified intrinsic oxide semiconductor (or metal oxide).

In order to obtain stable electrical characteristics of the transistor 200, reducing the concentration of impurities in the channel formation region of the oxide semiconductor 230 is effective. In order to reduce the concentration of impurities in the oxide semiconductor 230, the concentration of impurities in a film adjacent to the oxide semiconductor 230 is preferably reduced. Examples of the impurities include hydrogen, nitrogen, an alkali metal, an alkaline earth metal, iron, nickel, and silicon. Note that impurities in the oxide semiconductor 230 refer to, for example, elements other than the main components of the oxide semiconductor 230. For example, an element with a concentration lower than 0.1 atomic % can be regarded as an impurity.

In the oxide semiconductor 230, it is sometimes difficult to clearly observe the boundaries between the regions. The concentrations of a metal element and an impurity element such as hydrogen or nitrogen, which are detected in each region, may be not only gradually changed between the regions but also continuously changed in each region. That is, the region closer to the channel formation region may have lower concentrations of a metal element and an impurity element such as hydrogen or nitrogen.

If impurities and oxygen vacancies are present in a channel formation region in an oxide semiconductor, a transistor including the oxide semiconductor may have variable electrical characteristics and poor reliability. In some cases, hydrogen in the vicinity of an oxygen vacancy forms a defect that is an oxygen vacancy into which hydrogen has entered (hereinafter sometimes referred to as V_{O}H), which generates an electron serving as a carrier. Thus, when the channel formation region in the oxide semiconductor includes oxygen vacancies, the transistor tends to have normally-on characteristics (with which the channel is generated even when no voltage is applied to the gate electrode, and current flows through the transistor). Therefore, impurities, oxygen vacancies, and V_{O}H are preferably reduced as much as possible in the channel formation region in the oxide semiconductor. In other words, the channel formation region in the oxide semiconductor is preferably an i-type (intrinsic) or substantially i-type region with a reduced carrier concentration.

As a countermeasure against the above, an insulator containing oxygen that is released by heating (hereinafter sometimes referred to as excess oxygen) is provided in the vicinity of the oxide semiconductor and heat treatment is performed, so that oxygen can be supplied from the insulator to the oxide semiconductor to reduce oxygen vacancies and V_{O}H. However, supply of an excess amount of oxygen to the source region or the drain region might cause a decrease in the on-state current or field-effect mobility of the transistor 200. Furthermore, a variation in the amount of oxygen supplied to the source region or the drain region in the substrate plane leads to a variation in characteristics of semiconductor devices including the transistors. An excessive amount of oxygen supplied from the insulator to the oxide semiconductor adversely affects the electrical characteristics and reliability of the transistor in some cases. Moreover, oxygen is diffused into a conductor such as a gate electrode, a source electrode, or a drain electrode to oxidize the conductor, which might impair the conductivity.

First, an insulator having a barrier property against hydrogen is preferably formed in the vicinity of the transistor 200 to reduce V_{O}H in the channel formation region of the oxide semiconductor 230 and the vicinity thereof.

At least one of the insulators 212, 214, 221, 222, 275, 282, and 283 preferably functions as a barrier insulator against hydrogen. At least one of the insulators 212, 214, 221, 222, 275, 282, and 283 preferably functions as a barrier insulator against impurities. At least one of the insulators 212, 214, 221, 222, 275, 282, and 283 preferably functions as a barrier insulator against oxygen. Note that not all of the insulators 212, 214, 221, 222, 275, 282, and 283 need to be provided. If the barrier properties against hydrogen, impurities, oxygen, and the like are sufficient, any of the insulators 212, 214, 221, 222, 275, 282, and 283 can be formed selectively as appropriate. For example, the insulator 216 and the conductor 205 can be formed in contact with the top surface of the insulator 212, without providing the insulator 214.

Note that in this specification and the like, a barrier insulator refers to an insulator having a barrier property. In this specification and the like, the term “having a barrier property” refers to having a property that does not easily allow diffusion of a target substance (also referred to as a property that does not easily allow passage of a target substance, a property with low permeability of a target substance, or a function of inhibiting diffusion of a target substance). As another example, the term “having a barrier property” refers to having a function of capturing or fixing (also referred to as gettering) a target substance in the insulator. Note that hydrogen described as a target substance refers to at least one of a hydrogen atom, a hydrogen molecule, and a substance bonded to hydrogen, such as a water molecule and OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, and NO₂), and a copper atom. Oxygen described as a target substance refers to, for example, at least one of an oxygen atom and an oxygen molecule.

As the insulator having a function of inhibiting diffusion of hydrogen, silicon nitride or silicon nitride oxide is preferably used, for example. For another example, aluminum oxide, magnesium oxide, hafnium oxide, zirconium oxide, an oxide containing aluminum and hafnium (hafnium aluminate), an oxide containing hafnium and zirconium (hafnium zirconium oxide), gallium oxide, indium gallium zinc oxide, or the like can be used in some cases.

Insulators having a function of inhibiting diffusion of hydrogen are preferably used for the insulators 212, 221, 275, and 283. For example, silicon nitride, which has a higher hydrogen barrier property, is used for the insulators 212, 221, 275, and 283.

Part of the insulator having a function of inhibiting diffusion of hydrogen has a function of capturing or fixing hydrogen. Preferred examples of a material for an insulator having a function of capturing or fixing hydrogen include metal oxides such as an oxide containing hafnium, an oxide containing aluminum, an oxide containing aluminum and hafnium (hafnium aluminate), an oxide containing hafnium and zirconium (hafnium zirconium oxide), and magnesium oxide. The insulator having a function of capturing or fixing hydrogen preferably has an amorphous structure. In such a metal oxide having an amorphous structure, an oxygen atom has a dangling bond with which hydrogen is captured or fixed in some cases. That is, the metal oxide having an amorphous structure has high capability of capturing or fixing hydrogen. When silicon is added to the above metal oxide, the metal oxide is inhibited from being polycrystallized and easily becomes amorphous. Thus, such a metal oxide to which silicon is added (e.g., hafnium silicate or aluminum silicate) is preferably used.

An insulator having a function of capturing or fixing hydrogen is preferably used for the insulators 214, 222, and 282. For example, aluminum oxide is used for the insulators 214 and 282. For example, for the insulator 222 functioning as the second gate insulator, hafnium oxide, which is a high permittivity (high-k) material, is preferably used.

Such inorganic insulators exemplified as an insulator having a function of inhibiting diffusion of hydrogen and an insulator having a function of capturing or fixing hydrogen also have a barrier property against oxygen.

As illustrated in FIG. 2A, the insulator 212 having a function of inhibiting diffusion of hydrogen and the insulator 214 having a function of capturing or fixing hydrogen are preferably provided under the transistor 200. When the insulator 212 is provided under the transistor 200, diffusion of hydrogen from a layer below the transistor 200 can be inhibited. When the insulator 214 is provided over the insulator 212, hydrogen contained in the insulator 216 or the like can be captured or fixed by the insulator 214. Thus, the hydrogen concentration in the oxide semiconductor 230 and in the vicinity thereof can be reduced.

As illustrated in FIG. 2A, the insulator 221 having a function of inhibiting diffusion of hydrogen and the insulator 222 having a function of capturing or fixing hydrogen are preferably provided in a lower portion of the transistor 200. When the insulator 221 is provided in the lower portion of the transistor 200, diffusion of hydrogen from a lower layer in the transistor 200 can be inhibited. When the insulator 222 is provided over the insulator 221, hydrogen contained in the insulator 224 or the like can be captured or fixed by the insulator 222. Thus, the hydrogen concentration in the oxide semiconductor 230 and in the vicinity thereof can be reduced.

As illustrated in FIG. 2A, the insulator 275 is preferably provided to cover the oxide semiconductor 230, the conductors 242a and 242b, and the like. Providing the insulator 275 in such a manner can inhibit diffusion of hydrogen from the insulator 280 into the oxide semiconductor 230, the conductors 242a and 242b, and the like.

As illustrated in FIG. 2A, the insulator 282 having a function of capturing or fixing hydrogen and the insulator 283 having a function of inhibiting diffusion of hydrogen are preferably provided over the transistor 200. When the insulator 283 is provided over the transistor 200, diffusion of hydrogen from a layer above the transistor 200 can be inhibited. When the insulator 282 is provided under the insulator 283, hydrogen contained in the insulator 280 or the like can be captured or fixed by the insulator 282. Thus, the hydrogen concentration in the oxide semiconductor 230 and in the vicinity thereof can be reduced.

When the top and bottom of the transistor 200 are surrounded by barrier insulators against hydrogen in this manner, diffusion of hydrogen into the oxide semiconductor can be reduced and V_{O}H in the channel formation region can be reduced. Thus, the electrical characteristics and reliability of the transistor 200 can be improved.

Furthermore, oxygen released by heating is preferably contained in the insulator 280. When oxygen is supplied to the oxide semiconductor 230 through the insulator 250 by heat treatment, oxygen vacancies in the channel formation region can be reduced.

As illustrated in FIG. 2A, the insulator 282 may have a stacked-layer structure of an insulator 282a and an insulator 282b over the insulator 282a.

In that case, the insulator 282b is deposited by a sputtering method in an atmosphere containing an oxygen gas, whereby oxygen can be added to the insulator 280. At this time, when the insulator 282b is deposited with the insulator 282a provided, oxygen is added through the insulator 282a; hence, the amount of oxygen added to the insulator 280 can be controlled. With a larger thickness of the insulator 282a, the addition of oxygen is more likely to be inhibited, and the amount of oxygen supplied into the insulator 280 decreases. With a smaller thickness of the insulator 282a, the addition of oxygen is less likely to be inhibited, and the amount of oxygen supplied into the insulator 280 increases. For example, when the thickness of the insulator 282a is greater than or equal to 1 nm and less than or equal to 20 nm, preferably greater than or equal to 3 nm and less than or equal to 10 nm, an appropriate amount of oxygen can be supplied to the insulator 280.

The insulator 282a is preferably deposited by an atomic layer deposition (ALD) method to prevent oxygen from being added to the insulator 280 at the time of depositing the insulator 282a. To form the insulator 282a having a small thickness as the above, an ALD method is preferably used. Examples of an ALD method include a thermal ALD method, in which a precursor and a reactant react with each other only by a thermal energy, and a plasma-enhanced ALD (PEALD) method, in which a reactant excited by plasma is used.

A precursor used in an ALD method sometimes contains carbon or the like. For that reason, a film formed by an ALD method may contain an impurity such as carbon in a larger quantity than a film formed by another film formation method. Thus, the insulator 282a has a higher carbon concentration than the insulator 282b in some cases. Note that impurities can be quantified by secondary ion mass spectrometry (SIMS), X-ray photoelectron spectroscopy (XPS), or auger electron spectroscopy (AES).

For example, in the case where both the insulator 282a and the insulator 282b contain aluminum oxide, the carbon concentration of the insulator 282a is higher than that of the insulator 282b in some cases. In that case, the carbon concentration of the insulator 282a is preferably higher than or equal to 1×10¹⁸ atoms/cm³ and lower than or equal to 1×10²¹ atoms/cm³ in SIMS analysis. The insulator 282a may include a region where the carbon concentration is higher than or equal to 1×10¹⁹ atoms/cm³ and lower than or equal to 1×10²¹ atoms/cm³. The carbon concentration of the insulator 282b is preferably higher than or equal to the lower detection limit and lower than or equal to 1×10²⁰ atoms/cm³ in the SIMS analysis. The insulator 282b may include a region where the carbon concentration is higher than or equal to 4.46×10¹⁷ atoms/cm³ and lower than or equal to 1×10¹⁹ atoms/cm³.

As described above, heat treatment is performed on the insulator 280 in a state containing oxygen to be released by heating, whereby an appropriate amount of oxygen can be supplied to the oxide semiconductor 230 through the insulator 250. Since the insulators 282 and 283 each having a barrier property against oxygen are placed over the insulator 280 in the heat treatment, oxygen contained in the insulator 280 can be prevented from being excessively diffused from the insulator 280. Since the insulator 275 having a barrier property against oxygen is formed between the insulator 280 and each of the oxide semiconductor 230 and the conductors 242a and 242b, oxygen contained in the insulator 280 can be prevented from being excessively diffused from the insulator 280. The heat treatment is performed in a state in which the opening is formed in part of the insulators 280, 282, and 283, whereby part of oxygen contained in the insulator 280 can be diffused outwardly and the amount of oxygen supplied from the insulator 280 to the oxide semiconductor 230 can be adjusted.

Here, preferably, the insulator 250 enables oxygen diffusion from the insulator 280 into the oxide semiconductor 230 and inhibition of oxidation of the conductors 242a, 242b, and 260.

As illustrated in FIGS. 1B and 1C, the insulator 250 is provided in the opening formed in the insulators 280 and 275. The insulator 250 is formed in contact with the top surface of the insulator 222, a side surface of the insulator 224, a side surface and the top surface of the oxide semiconductor 230, a side surface of the conductor 242a, a side surface of the conductor 242b, a side surface of the insulator 271a, a side surface of the insulator 271b, a side surface of the insulator 275, and a side surface of the insulator 280 in the opening. As illustrated in FIG. 2A, in the case where the oxide semiconductor 230 includes the oxide semiconductors 230a to 230c, the insulator 250 is in contact with a side surface of the oxide semiconductor 230a, a side surface of the oxide semiconductor 230b, and the top surface and a side surface of the oxide semiconductor 230c. Here, the crystallinity of the oxide semiconductor 230c illustrated in FIG. 2A is preferably high, in which case the transistor 200 in the on state can have high carrier mobility because the oxide semiconductor 230c has a large contact area with the insulator 250.

Here, as illustrated in FIG. 2A, the insulator 250 preferably has a stacked-layer structure of an insulator 250a in contact with the oxide semiconductor 230, an insulator 250b over the insulator 250a, and an insulator 250c over the insulator 250b.

For the insulator 250b, silicon oxide, silicon oxynitride, or the like with a high insulation withstand voltage is preferably used. In order to increase the insulation withstand voltage, the insulator 250b may have a larger thickness than the insulator 250a. With the use of the above oxide insulator, oxygen can be diffused in the insulator 250b by high-temperature heat treatment. Thus, the heat treatment enables oxygen contained in the insulator 280 to be supplied to the oxide semiconductor 230 through the insulator 250b. Note that in this specification and the like, an oxynitride refers to a material that contains more oxygen than nitrogen, and a nitride oxide refers to a material that contains more nitrogen than oxygen. For example, silicon oxynitride refers to a material that contains more oxygen than nitrogen, and silicon nitride oxide refers to a material that contains more nitrogen than oxygen.

In order to inhibit oxidation of the conductors 242a, 242b, and 260, a barrier insulator against oxygen is preferably provided in the vicinity of each of the conductors 242a, 242b, and 260. For example, a barrier insulator against oxygen is preferably provided as the insulators 250a and 250c.

The insulator 250a preferably has a barrier property against oxygen. The insulator 250a is preferably less permeable to oxygen than at least the insulator 250b is. The insulator 250a includes a region in contact with the side surface of the conductor 242a and the side surface of the conductor 242b. When the insulator 250a has a barrier property against oxygen, oxidation of the side surfaces of the conductors 242a and 242b and formation of oxide films on the side surfaces can be inhibited. Accordingly, a reduction in on-state current or field-effect mobility of the transistor 200 can be inhibited. Such a structure can inhibit oxygen contained in the insulator 250b from being absorbed into the conductors 242a and 242b. Thus, an appropriate amount of oxygen can be supplied from the insulator 250b to the oxide semiconductor 230, so that oxygen vacancies in the channel formation region of the oxide semiconductor 230 can be reduced.

When the insulator 250a is provided between the insulator 280 and the insulator 250b and between the insulator 250b and the oxide semiconductor 230, oxygen can be inhibited from being excessively supplied from the insulator 280 to the oxide semiconductor 230, and an appropriate amount of oxygen can be supplied to the oxide semiconductor 230. Thus, the amount of oxygen in the channel formation region of the oxide semiconductor 230 and the vicinity thereof can be controlled to be an appropriate amount; hence, the transistor 200 can be prevented from having excessively normally-off characteristics and can have high reliability. In addition, excessive oxidation of the source and drain regions can be prevented, and a reduction in on-state current or field-effect mobility of the transistor 200 can be inhibited.

Thus, the insulator 250a preferably has a thickness that does not excessively inhibit diffusion of oxygen from the insulator 280 to the insulator 250b and diffusion of oxygen from the insulator 250b to the oxide semiconductor 230. For example, the thickness of the insulator 250a is preferably greater than or equal to 0.1 nm and less than or equal to 5.0 nm, further preferably greater than or equal to 0.5 nm and less than or equal to 5.0 nm, still further preferably greater than or equal to 0.5 nm and less than 3.0 nm, yet still further preferably greater than or equal to 0.5 nm and less than or equal to 2.0 nm.

As described above, it is preferable that diffusion of oxygen from the insulator 280 to the insulator 250b and diffusion of oxygen from the insulator 250b to the oxide semiconductor 230 occur as appropriate, and that diffusion of oxygen from the insulator 250b to the conductors 242a and 242b be inhibited as much as possible. Here, in the semiconductor device of this embodiment, the contact area between the insulator 250a and the conductor 242a and the contact area between the insulator 250a and the conductor 242b are much smaller than the contact area between the insulator 250a and the oxide semiconductor 230. That is, the amount of oxygen diffusing from the insulator 250b to the conductors 242a and 242b through the insulator 250a is presumed to be smaller than the amount of oxygen diffusing from the insulator 250b to the oxide semiconductor 230 through the insulator 250a. Thus, the amount of oxygen contained in the insulator 280 is controlled so that an appropriate amount of oxygen is supplied from the insulator 280 to the insulator 250b and the oxide semiconductor 230, whereby oxidation of the conductors 242a and 242b can be reduced.

The insulator 250a in contact with the channel formation region of the oxide semiconductor 230 preferably has a function of capturing or fixing hydrogen. This can reduce the hydrogen concentration in the channel formation region of the oxide semiconductor 230. Thus, V_{O}H in the channel formation region can be reduced, so that the channel formation region can be an i-type or substantially i-type region.

Moreover, a high permittivity (high-k) material is preferably used for the insulator 250a. An example of the high-k material is an oxide containing aluminum and/or hafnium. With the use of the high-k material for the insulator 250a, a gate potential applied during the operation of the transistor can be lowered while the physical thickness of the gate insulator is maintained. In addition, the equivalent oxide thickness (EOT) of the insulator functioning as the gate insulator can be reduced.

As described above, for the insulator 250a, it is preferable to use an oxide containing aluminum and/or hafnium and it is further preferable to use an oxide that contains aluminum and/or hafnium and has an amorphous structure. Since aluminum oxide can be formed as an amorphous film relatively easily by an ALD method, the use of aluminum oxide having an amorphous structure is further preferred. In this embodiment, an aluminum oxide film is used as the insulator 250a. Aluminum oxide has a function of capturing or fixing hydrogen and has a barrier property against oxygen; thus, aluminum oxide can be suitably used for the insulator 250a.

The insulator 250c also preferably has a barrier property against oxygen. The insulator 250c is provided between the channel formation region of the oxide semiconductor 230 and the conductor 260 and between the insulator 280 and the conductor 260. Such a structure can inhibit oxygen contained in the channel formation region of the oxide semiconductor 230 from diffusing into the conductor 260 and thus can inhibit formation of oxygen vacancies in the channel formation region of the oxide semiconductor 230. Moreover, oxygen contained in the oxide semiconductor 230 and oxygen contained in the insulator 280 can be inhibited from diffusing into the conductor 260 and oxidizing the conductor 260. The insulator 250c is preferably less permeable to oxygen than at least the insulator 250b is. Furthermore, the insulator 250c preferably has a function of inhibiting diffusion of hydrogen. This can prevent diffusion of impurities contained in the conductor 260, such as hydrogen, into the oxide semiconductor 230. For example, a silicon nitride film is preferably used as the insulator 250c.

As illustrated in FIG. 2B, an insulator 250d is preferably provided over the insulator 250b. In this case, as the insulator 250d, an insulator that can be used for the insulator 250a and has a function of capturing or fixing hydrogen can be provided. For example, an oxide containing hafnium is preferably used for the insulator 250d. As the oxide containing hafnium, hafnium oxide, hafnium aluminate, hafnium silicate, hafnium zirconium oxide, or hafnium zirconium oxide containing yttrium can be used, for example. For the insulator 250d, hafnium zirconium oxide containing a lanthanoid such as lanthanum can also be used. Here, when the insulator 250d is provided between the insulator 250c and the insulator 250b, hydrogen contained in the insulator 250b and the like can be captured and fixed more effectively. The channel formation region of the oxide semiconductor 230 and the insulators 250a and 250d each having a function of capturing and fixing hydrogen are provided under the insulator 250c having a function of inhibiting diffusion of hydrogen. In a region where diffusion of hydrogen from above is blocked by the insulator 250c, hydrogen contained in the channel formation region of the oxide semiconductor 230, for example, can be captured or fixed by the insulators 250a and 250d. Accordingly, the hydrogen concentration in the oxide semiconductor 230 can be reduced, so that a shift in the initial characteristics of the transistor 200 in the negative direction can be inhibited and the transistor 200 can have normally-off characteristics. In addition, negative drift degradation in a gate bias-temperature (+GBT) stress test can be inhibited.

Note that the insulators 250a, 250b, and 250d can alternatively be provided without providing the insulator 250c. In that case, an insulator having a function of inhibiting diffusion of hydrogen (e.g., silicon nitride) is preferably provided as the insulator 283 over the insulator 250. With this structure, the oxide semiconductor 230 and the insulators 250a and 250d each having a function of capturing or fixing hydrogen are formed in a region covered with silicon nitride having a high hydrogen barrier property. Accordingly, hydrogen contained in the channel formation region of the oxide semiconductor 230, for example, can be captured or fixed by the insulators 250a and 250d.

With the above structure, the i-type or substantially i-type channel formation region and the n-type source and drain regions can be formed; therefore, a semiconductor device with favorable electrical characteristics can be provided. The semiconductor device with the above structure can have favorable electrical characteristics even when being miniaturized or highly integrated. Furthermore, miniaturization of the transistor 200 can improve the frequency characteristics. Specifically, the cutoff frequency can be improved.

The metal oxide containing hafnium, which is used for the insulator 250d, preferably functions as a high-k material. Accordingly, a gate potential applied during the operation of the transistor can be lowered while the physical thickness of the gate insulator is maintained. In addition, the equivalent oxide thickness (EOT) of the insulator functioning as the gate insulator can be reduced.

The insulator 250d preferably has ferroelectricity. For example, hafnium zirconium oxide or hafnium zirconium oxide containing yttrium, each of which has ferroelectricity, can be used for the insulator 250d. The insulator 250d may have a structure in which a layer of hafnium zirconium oxide is stacked over a layer of hafnium zirconium oxide containing yttrium. Note that in the case where a ferroelectric is used as the insulator 250d, the insulator 250d does not necessarily have a function of capturing or fixing hydrogen. For example, a material that can show ferroelectricity and will be described in Embodiment 4 can be used for the insulator 250d.

Using a ferroelectric as the insulator 250d in the above manner enables the transistor 200 to function as a ferroelectric field-effect transistor (FeFET). An FeFET functions as a memory element by itself. Thus, the size of the memory element can be smaller than that of a dynamic random access memory (DRAM)-type memory element including a transistor and a capacitor. Accordingly, miniaturization and high integration of a memory device including the transistors 200 can be achieved. In addition, the productivity of the memory device including the transistors 200 can be increased.

The insulators 250a to 250d function as part of the first gate insulator. The insulators 250a to 250d are provided together with the conductor 260 in the opening formed in the insulator 280 and the like. The thickness of each of the insulators 250a, 250c, and 250d is preferably small for miniaturization of the transistor 200. The thickness of each of the insulators 250a, 250c, and 250d is preferably greater than or equal to 0.1 nm and less than or equal to 20 nm, further preferably greater than or equal to 0.1 nm and less than or equal to 10 nm, still further preferably greater than or equal to 0.5 nm and less than or equal to 5.0 nm, still further preferably greater than or equal to 1.0 nm and less than 5.0 nm, yet still further preferably greater than or equal to 1.0 nm and less than or equal to 3.0 nm. For example, 1-nm-thick aluminum oxide can be used for the insulator 250a, 2-nm-thick silicon oxide can be used for the insulator 250b, 2-nm-thick hafnium oxide, hafnium zirconium oxide, or hafnium zirconium oxide containing yttrium can be used for the insulator 250d, and 1-nm-thick silicon nitride can be used for the insulator 250c. Note that each of the insulators 250a, 250c, and 250d at least partly includes a region having a thickness in the above range.

To reduce the thicknesses of the insulators 250a, 250c, and 250d as described above, an ALD method is preferably used for the deposition. Furthermore, to form the insulators 250a to 250d with favorable coverage in the opening in the insulator 280 and the like, an ALD method is preferably employed.

Although the case where the insulator 250 has a three-layer structure of the insulators 250a to 250c or a four-layer structure of the insulators 250a to 250d is described above, the present invention is not limited to these structures. The insulator 250 can have a single-layer structure, a two-layer structure, or a stacked-layer structure of five or more layers. Moreover, the insulator 250 can have a structure including at least one of the insulators 250a to 250d. For example, the insulator 250 can have a single-layer structure of the insulator 250c. In this case, the insulator 250 can be a single layer of hafnium zirconium oxide. When the insulator 250 is formed of one, two, or three layer(s) of the insulators 250a to 250d, the manufacturing process of a semiconductor device can be simplified and the productivity can be increased.

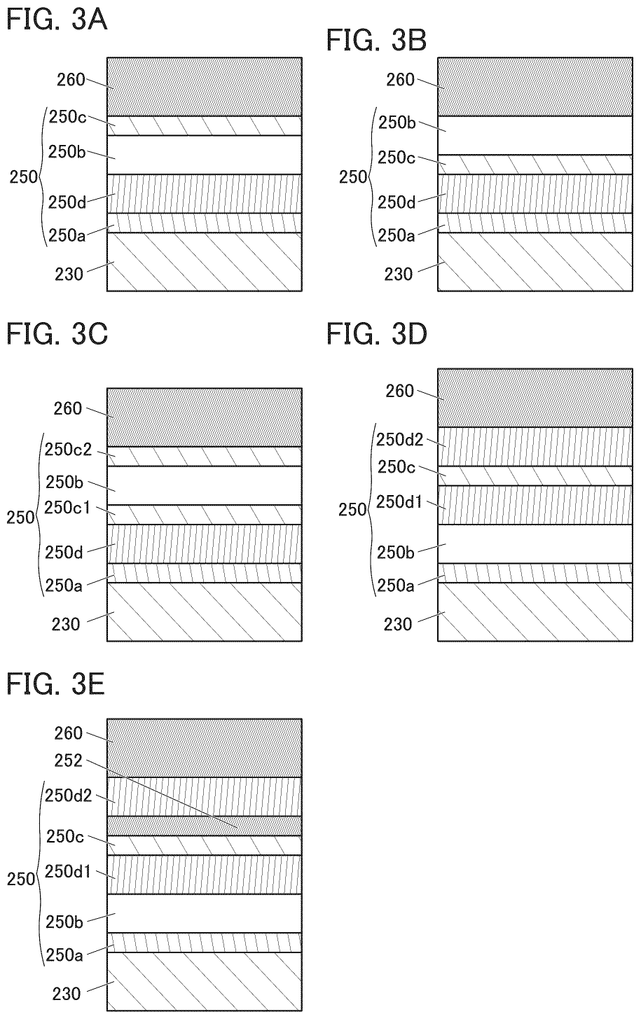

In the case where the insulator 250 has a four-layer structure or a five-layer structure, a stacked-layer structure illustrated in any of FIGS. 3A to 3E can be employed, for example. Here, FIGS. 3A to 3E are enlarged views corresponding to a region A illustrated in FIG. 2B.

FIG. 3A illustrates an example in which the insulator 250 has a stacked-layer structure including the insulator 250a over the oxide semiconductor 230, the insulator 250d over the insulator 250a, the insulator 250b over the insulator 250d, and the insulator 250c over the insulator 250b. That is, in the insulator 250 illustrated in FIG. 3A, the positions of the insulator 250b and the insulator 250d in the insulator 250 illustrated in FIG. 2B are interchanged. For example, 1-nm-thick aluminum oxide can be used for the insulator 250a, 2-nm-thick hafnium zirconium oxide or hafnium zirconium oxide containing yttrium can be used for the insulator 250d, 2-nm-thick silicon oxide can be used for the insulator 250b, and 1-nm-thick silicon nitride can be used for the insulator 250c. The insulator 250d may have a structure in which a layer of hafnium zirconium oxide is stacked over a layer of hafnium zirconium oxide containing yttrium. Without limitation to the above, any of the above-described insulating materials can be selected as appropriate for the insulators 250a to 250d, and the thicknesses of the insulators 250a to 250d can also be selected as appropriate. When the insulators 250a to 250d are stacked as illustrated in FIG. 3A, the insulators 250a and 250d each having a function of capturing or fixing hydrogen are provided adjacent to each other, whereby hydrogen can be captured and fixed more effectively.

As illustrated in FIG. 3B, the positions of the insulator 250c and the insulator 250b can be interchanged. In this case, the insulator 250 has a stacked-layer structure including the insulator 250a over the oxide semiconductor 230, the insulator 250d over the insulator 250a, the insulator 250c over the insulator 250d, and the insulator 250b over the insulator 250c.

In FIG. 3A, the insulator 250c can be provided in contact with the top surface and the bottom surface of the insulator 250b. In this case, as illustrated in FIG. 3C, the insulator 250 has a stacked-layer structure including the insulator 250a over the oxide semiconductor 230, the insulator 250d over the insulator 250a, an insulator 250c1 over the insulator 250d, the insulator 250b over the insulator 250c1, and an insulator 250c2 over the insulator 250b. Here, for the insulators 250cl and 250c2, the above-described insulator that can be used as the insulator 250c is used. For example, 1-nm-thick silicon nitride can be used for each of the insulators 250c1 and 250c2.

FIG. 3D illustrates an example in which the insulator 250 has a stacked-layer structure including the insulator 250a over the oxide semiconductor 230, the insulator 250b over the insulator 250a, an insulator 250d1 over the insulator 250b, the insulator 250c over the insulator 250d1, and an insulator 250d2 over the insulator 250c. That is, the insulator 250 illustrated in FIG. 3D has a structure in which insulators that can be used as the insulator 250d are provided in contact with the top surface and the bottom surface of the insulator 250c in the insulator 250 illustrated in FIG. 2B. Here, an insulator having a function of capturing or fixing hydrogen (e.g., hafnium oxide) can be used for the insulator 250d1, and an insulator having ferroelectricity (e.g., hafnium zirconium oxide or hafnium zirconium oxide containing yttrium) can be used for the insulator 250d2. The insulator 250d2 may have a structure in which a layer of hafnium zirconium oxide is stacked over a layer of hafnium zirconium oxide containing yttrium. When such a structure is employed to use a ferroelectric for the insulator 250d2, the transistor 200 can function as an FeFET. Furthermore, hydrogen can be captured or fixed by the insulator 250d1, so that the electrical characteristics and reliability of the transistor 200 can be improved.

In the case where the insulator 250d2 is provided and formed using a ferroelectric material such as hafnium zirconium oxide, a conductor 252 can be provided in contact with the bottom surface of the insulator 250d2 as illustrated in FIG. 3E. For the conductor 252, a material that easily causes polarization in the insulator 250d2 is preferably used, and for example, titanium nitride is preferably used. In this case, titanium nitride is preferably used also for a portion that is a lower portion of the conductor 260 and is in contact with the insulator 250d2 (e.g., a conductor 260a). With such a structure, the insulator 250d2 can be a ferroelectric and thus the transistor 200 can function as an FeFET.

In the transistor 200, the conductor 205 is provided to overlap with the oxide semiconductor 230 and the conductor 260. For the conductor 205, any of the conductive materials described in the section <<Conductor>> can be used. Here, the conductor 205 is preferably provided to be embedded in an opening formed in the insulator 216. The conductor 205 is preferably provided to extend in the channel width direction as illustrated in FIGS. 1A and 1C. With such a structure, the conductor 205 functions as a wiring when a plurality of transistors are provided.

As illustrated in FIG. 2A, the conductor 205 preferably includes a conductor 205a and a conductor 205b. The conductor 205a is provided in contact with the bottom surface and a sidewall of the opening. The conductor 205b is provided to fill a recess portion that is defined by the conductor 205a and formed along the opening. Here, the top surface of the conductor 205 is level or substantially level with the top surface of the insulator 216.

Here, the conductor 205a preferably contains a conductive material having a function of inhibiting diffusion of impurities such as hydrogen atoms, hydrogen molecules, water molecules, nitrogen atoms, nitrogen molecules, nitrogen oxide molecules (e.g., N₂O, NO, and NO₂), and copper atoms. Alternatively, the conductor 205a preferably contains a conductive material having a function of inhibiting diffusion of oxygen (e.g., at least one of oxygen atoms and oxygen molecules).

When a conductive material having a function of inhibiting diffusion of hydrogen is used for the conductor 205a, impurities such as hydrogen contained in the conductor 205b can be prevented from diffusing into the oxide semiconductor 230 through the insulator 216 and the like. When a conductive material having a function of inhibiting diffusion of oxygen is used for the conductor 205a, the conductivity of the conductor 205b can be inhibited from being lowered because of oxidation of the conductor 205b. Examples of the conductive material having a function of inhibiting diffusion of oxygen include titanium, titanium nitride, tantalum, tantalum nitride, ruthenium, and ruthenium oxide. The conductor 205a can have a single-layer structure or a stacked-layer structure of the above conductive material(s). For example, the conductor 205a preferably contains titanium nitride.

The conductor 205b is preferably formed using a conductive material containing tungsten, copper, or aluminum as its main component. For example, the conductor 205b preferably contains tungsten.

The conductor 205 can function as the second gate electrode. In that case, by changing a potential applied to the conductor 205 not in conjunction with but independently of a potential applied to the conductor 260, the threshold voltage (Vth) of the transistor 200 can be controlled. In particular, by applying a negative potential to the conductor 205, Vth of the transistor 200 can be made higher and its off-state current can be reduced. Thus, a drain current at the time when a potential applied to the conductor 260 is 0 V can be lower in the case where a negative potential is applied to the conductor 205 than in the case where the negative potential is not applied to the conductor 205.

The electrical resistivity of the conductor 205 is designed in consideration of the potential applied to the conductor 205, and the thickness of the conductor 205 is determined in accordance with the electrical resistivity. The thickness of the insulator 216 is substantially equal to that of the conductor 205. The conductor 205 and the insulator 216 are preferably as thin as possible in the allowable range of the design of the conductor 205. The insulator 216 with a smaller thickness contains a smaller absolute amount of impurities such as hydrogen, inhibiting the diffusion of the impurities into the oxide semiconductor 230.

Although the stacked-layer structure of the conductors 205a and 205b is described with reference to FIG. 2A, the present invention is not limited to this structure. The conductor 205 may have a single-layer structure or a stacked-layer structure of three or more layers. For example, the conductor 205a may have a two-layer structure of tantalum nitride and titanium nitride over the tantalum nitride, and the conductor 205b including tungsten may be provided over the conductor 205a. With such a structure, impurities such as hydrogen and metal impurities such as copper contained in the layer below the transistor 200 can be inhibited from diffusing into the conductor 205.

The insulator 224, the insulator 221, and the insulator 222 function as the second gate insulator.

For the insulator 224 in contact with the oxide semiconductor 230, any of the insulating materials described in the section <<Insulator>> can be used. The insulator 224 preferably contains, for example, silicon oxide or silicon oxynitride. Accordingly, oxygen can be supplied from the insulator 224 to the oxide semiconductor 230, so that oxygen vacancies can be reduced. Note that the insulator 224 may have a stacked-layer structure of two or more layers. In that case, without limitation to a stacked-layer structure formed of the same material, a stacked-layer structure formed of different materials may be employed.

The insulator 224 is preferably processed into an island shape like the oxide semiconductor 230. Thus, in the case where a plurality of the transistors 200 are provided, the transistors 200 have the insulator 224 of substantially the same size. Accordingly, among the transistors 200, the amount of oxygen supplied from the insulator 224 to the oxide semiconductor 230 is substantially the same. As a result, variations in electrical characteristics of the transistors 200 in the substrate plane can be reduced.

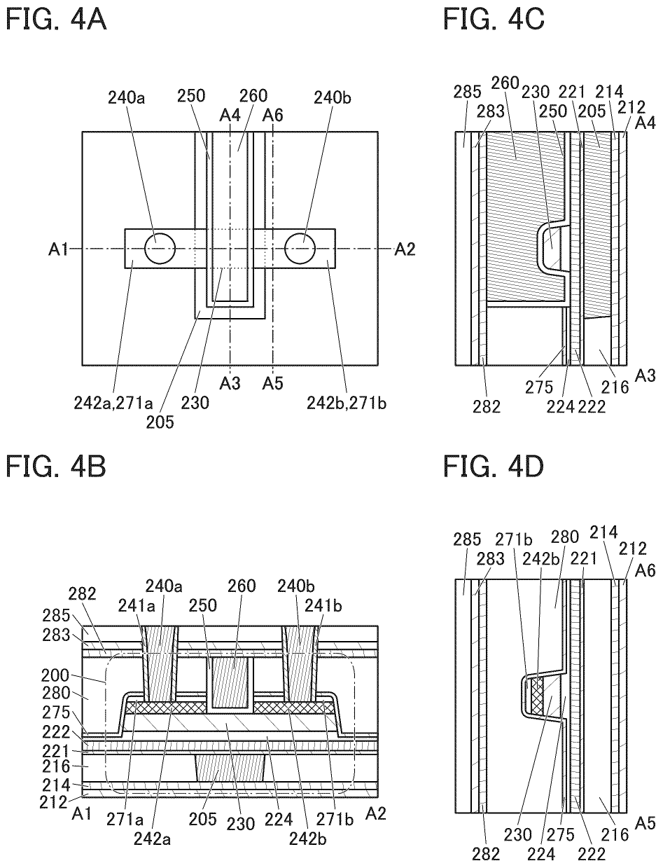

Note that the insulator 224 is not necessarily processed into an island shape. For example, as illustrated in FIGS. 4A to 4D, the insulator 224 may have a shape in which an opening is partly formed, instead of having an island shape. Here, FIGS. 4A to 4D correspond to FIGS. 1A to 1D, respectively, and are the same as FIGS. 1A to 1D except for the shape of the insulator 224.

The insulator 224 illustrated in FIGS. 4A to 4D has a smaller thickness in a region not overlapping with the oxide semiconductor 230 than in a region overlapping with the oxide semiconductor 230. An opening is formed in a region not overlapping with the oxide semiconductor 230 but overlapping with the insulator 250. In the case where a plurality of transistors are provided over one substrate, forming the insulator 224 in this manner results in formation of the oxide semiconductor 230 of each transistor over the same insulator 224. Accordingly, a variation in the amount of oxygen supplied from the insulator 224 to the oxide semiconductor 230 of each transistor can be reduced. Thus, variations in electrical characteristics of the transistors can be reduced.

Note that in the insulator 224 illustrated in FIGS. 4A to 4D, the opening is formed in the region not overlapping with the oxide semiconductor 230 but overlapping with the insulator 250; however, a structure without the opening may be employed.

For the conductors 242a, 242b, and 260, any of the conductive materials described in the section <<Conductor>> can be used. Specifically, a conductive material that is less likely to be oxidized or a conductive material having a function of inhibiting diffusion of oxygen is preferably used for the conductors 242a, 242b, and 260. Examples of such conductive materials include a conductive material containing nitrogen and a conductive material containing oxygen. The use of such conductive materials can inhibit a reduction in the conductivity of the conductors 242a, 242b, and 260. In the case where a conductive material containing a metal and nitrogen is used for each of the conductors 242a, 242b, and 260, the conductors 242a, 242b, and 260 contain at least the metal and nitrogen.

For the conductors 242a and 242b, a metal nitride is preferably used; for example, a nitride containing tantalum, a nitride containing titanium, a nitride containing molybdenum, a nitride containing tungsten, a nitride containing tantalum and aluminum, or a nitride containing titanium and aluminum is preferably used. For example, tantalum nitride can be used for the conductors 242a and 242b. As another example, ruthenium, ruthenium oxide, ruthenium nitride, an oxide containing strontium and ruthenium, or an oxide containing lanthanum and nickel may be used. These materials are preferable because they are conductive materials that are not easily oxidized or materials that maintain their conductivity even after absorbing oxygen.

Note that hydrogen contained in the oxide semiconductor 230 or the like diffuses into the conductor 242a or 242b in some cases. In particular, when a nitride containing tantalum is used for the conductors 242a and 242b, hydrogen contained in the oxide semiconductor 230 or the like is likely to diffuse into the conductor 242a or 242b, and the diffused hydrogen is bonded to nitrogen contained in the conductor 242a or 242b in some cases. That is, hydrogen contained in the oxide semiconductor 230 or the like is sometimes absorbed by the conductor 242a or 242b.

The conductors 242a and 242b may each have a stacked-layer structure. In this case, the above-described conductive material is used for lower layers of the stacked-layer structures of the conductors 242a and 242b, and a conductive material having higher conductivity is used for upper layers of the stacked-layer structures of the conductors 242a and 242b. For example, tantalum nitride can be used for the lower layers and tungsten can be used for the upper layers.

The insulators 271a and 271b function as etching stoppers at the time of processing the conductors 242a and 242b, and are inorganic insulators that protect the conductors 242a and 242b. Since the insulators 271a and 271b are respectively in contact with the conductors 242a and 242b, the insulators 271a and 271b are preferably inorganic insulators that are less likely to oxidize the conductors 242a and 242b. Thus, as illustrated in FIG. 2A, the insulator 271a preferably has a stacked-layer structure of an insulator 271a1 and an insulator 271a2 over the insulator 271a1, and the insulator 271b preferably has a stacked-layer structure of an insulator 271b1 and an insulator 271b2 over the insulator 271b1. Here, the insulators 271a1 and 271b1 are preferably formed using the nitride insulator that can be used for the insulator 250c, so as not to easily oxidize the conductors 242a and 242b. The insulators 271a2 and 271b2 are preferably formed using the oxide insulator that can be used for the insulator 250b, so as to function as etching stoppers.

Here, the insulator 271a1 is in contact with the top surface of the conductor 242a and a part of the insulator 275, and the insulator 271b1 is in contact with the top surface of the conductor 242b and another part of the insulator 275. The insulator 271a2 is in contact with the top surface of the insulator 271a1 and the bottom surface of the insulator 275, and the insulator 271b2 is in contact with the top surface of the insulator 271b1 and the bottom surface of the insulator 275. For example, silicon nitride can be used for the insulators 271a1 and 271b1, and silicon oxide can be used for the insulators 271a2 and 271b2.

An insulator to be the insulators 271a and 271b functions as a mask for a conductor to be the conductors 242a and 242b, and thus the conductors 242a and 242b do not have a curved surface between the side surface and the top surface as illustrated in FIG. 1D. Accordingly, an end portion at the intersection of the side surface and the top surface of each of the conductors 242a and 242b is angular. The cross-sectional area of each of the conductors 242a and 242b is larger in the case where the end portion at the intersection of the side surface and the top surface of each of the conductors 242a and 242b is angular than in the case where the end portion is rounded. Furthermore, when a nitride insulator that is less likely to oxidize metal is used for the insulators 271a1 and 271b1, excessive oxidation of the conductors 242a and 242b can be prevented. Accordingly, the resistance of the conductors 242a and 242b is reduced, so that the on-state current of the transistor can be increased.

As illustrated in FIGS. 1B and 1C, the conductor 260 is provided in the opening formed in the insulators 280 and 275. The conductor 260 is formed in the opening to cover the top surface of the insulator 222, the side surface of the insulator 224, and the side and top surfaces of the oxide semiconductor 230 with the insulator 250 therebetween. The top surface of the conductor 260 is positioned to be level or substantially level with the upper end portion of the insulator 250 and the top surface of the insulator 280.

Note that the sidewall of the opening in which the conductor 260 and the insulator 250 are provided may be perpendicular or substantially perpendicular to the top surface of the insulator 222 or may be tapered. The tapered sidewall can improve the coverage with the insulator 250 formed in the opening in the insulator 280, so that the number of defects such as voids can be reduced.

The conductor 260 functions as the first gate electrode of the transistor 200. Here, the conductor 260 is preferably provided to extend in the channel width direction as illustrated in FIGS. 1A and 1C. With such a structure, the conductor 260 functions as a wiring when a plurality of transistors are provided.

In the case where the above structure is employed, a curved surface may be provided between the side and top surfaces of the oxide semiconductor 230 in a cross-sectional view of the transistor 200 in the channel width direction, as illustrated in FIG. 1C. In other words, the end portion of the side surface and the end portion of the top surface may be curved (rounded).

The radius of curvature of the curved surface is preferably greater than 0 nm and less than the thickness of the oxide semiconductor 230 in a region overlapping with the conductors 242a and 242b, or less than half of the length of a region that does not have the curved surface. Specifically, the radius of curvature of the curved surface is greater than 0 nm and less than or equal to 20 nm, preferably greater than or equal to 1 nm and less than or equal to 15 nm, further preferably greater than or equal to 2 nm and less than or equal to 10 nm. Such a shape can improve the coverage of the oxide semiconductor 230 with the insulator 250 and the conductor 260.

Note that in this specification and the like, a transistor structure in which a channel formation region is electrically surrounded by at least the electric field of the first gate electrode is referred to as a surrounded channel (S-channel) structure. The S-channel structure disclosed in this specification and the like is different from a Fin structure or a planar structure. However, the S-channel structure disclosed in this specification and the like can be regarded as a kind of the Fin structure. In this specification and the like, the Fin structure refers to a structure in which at least two surfaces (specifically, two surfaces, three surfaces, four surfaces, or the like) of a channel are covered with a gate electrode. With the use of the Fin structure or the S-channel structure, a transistor with high resistance to a short-channel effect, i.e., a transistor in which a short-channel effect is less likely to occur, can be obtained.

When the transistor 200 has the above-described S-channel structure, the channel formation region can be electrically surrounded. Since the S-channel structure is a structure with the electrically surrounded channel formation region, the S-channel structure is, in a sense, equivalent to a gate-all-around (GAA) structure or a lateral gate-all-around (LGAA) structure. When the transistor 200 has any of the S-channel structure, the GAA structure, and the LGAA structure, the channel formation region formed at the interface between the oxide semiconductor 230 and the gate insulator or in the vicinity thereof can correspond to the whole bulk of the oxide semiconductor 230. Consequently, the density of current flowing through the transistor can be increased, so that the on-state current or field-effect mobility of the transistor should be increased.

In this embodiment, the insulator 224 is provided to have an island shape. Accordingly, as illustrated in FIG. 1C, at least part of the bottom surface of the conductor 260 can be at a position lower than the bottom surface of the oxide semiconductor 230. Thus, the conductor 260 can be provided to face the top and side surfaces of the oxide semiconductor 230, so that an electric field of the conductor 260 can act on the top and side surfaces of the oxide semiconductor 230. When the insulator 224 with an island shape is provided in this manner, the transistor 200 can have the S-channel structure.

Note that although FIG. 1C illustrates a transistor with the S-channel structure as the transistor 200, the semiconductor device of one embodiment of the present invention is not limited to this. For example, a transistor structure that can be employed in one embodiment of the present invention is one or more selected from a planar structure, a Fin-type structure, and a GAA structure.

As illustrated in FIG. 2A, the conductor 260 preferably has a two-layer structure. Here, the conductor 260 preferably includes the conductor 260a and a conductor 260b over the conductor 260a. For example, the conductor 260a is preferably placed to cover the bottom and side surfaces of the conductor 260b. Here, a conductive material that is less likely to be oxidized or a conductive material having a function of inhibiting diffusion of oxygen is preferably used for the conductor 260a.

The conductor 260a is preferably formed using a conductive material having a function of inhibiting diffusion of impurities such as hydrogen atoms, hydrogen molecules, water molecules, nitrogen atoms, nitrogen molecules, nitrogen oxide molecules, and copper atoms. Alternatively, the conductor 260a is preferably formed using a conductive material having a function of inhibiting diffusion of oxygen (e.g., at least one of oxygen atoms and oxygen molecules).

When the conductor 260a has a function of inhibiting diffusion of oxygen, the conductivity of the conductor 260b can be inhibited from being lowered because of oxidation of the conductor 260b due to oxygen in the insulator 280 and the like. As the conductive material having a function of inhibiting diffusion of oxygen, for example, titanium, titanium nitride, tantalum, tantalum nitride, ruthenium, or ruthenium oxide is preferably used.

The conductor 260b is preferably formed using a conductor having high conductivity. For example, a conductive material containing tungsten, copper, or aluminum as its main component can be used for the conductor 260b. The conductor 260b may have a stacked-layer structure, for example, a stacked-layer structure of titanium or titanium nitride and the above conductive material.

In the transistor 200, the conductor 260 is formed in a self-aligned manner to fill the opening formed in the insulator 280 and the like. In this manner, the conductor 260 can be provided to overlap with a region between the conductor 242a and the conductor 242b without alignment.

The insulators 216, 280, and 285 each preferably have a lower permittivity than the insulator 222. When materials with a low permittivity are used for the interlayer films, parasitic capacitance generated between wirings can be reduced.

For example, each of the insulators 216, 280, and 285 each preferably includes one or more of silicon oxide, silicon oxynitride, silicon oxide to which fluorine is added, silicon oxide to which carbon is added, silicon oxide to which carbon and nitrogen are added, and porous silicon oxide.

Silicon oxide and silicon oxynitride are particularly preferable because of their thermal stability. In particular, materials such as silicon oxide, silicon oxynitride, and porous silicon oxide are preferably used, in which case a region containing oxygen that is released by heating can be easily formed.

Each of the top surfaces of the insulators 216 and 280 may be planarized.

The concentration of impurities such as water and hydrogen in the insulator 280 is preferably reduced. For example, the insulator 280 preferably contains an oxide containing silicon, such as silicon oxide or silicon oxynitride.

For the conductors 240a and 240b, any of the conductive materials described in the section <<Conductor>> can be used. The conductors 240a and 240b are preferably formed using a conductive material containing tungsten, copper, or aluminum as its main component, for example. The conductors 240a and 240b may each have a stacked-layer structure.

For example, as illustrated in FIG. 2A, the conductors 240a and 240b may each have a two-layer structure. The conductor 240a includes a conductor 240a1 formed along the opening and a conductor 240a2 formed on the inner side of the conductor 240a1. The conductor 240b includes a conductor 240b1 formed along the opening and a conductor 240b2 formed on the inner side of the conductor 240b1.

The conductors 240a1 and 240b1 are preferably formed using a conductive material having a function of inhibiting passage of impurities such as water and hydrogen, like the conductor 205a. For example, tantalum, tantalum nitride, titanium, titanium nitride, ruthenium, or ruthenium oxide is preferably used. The conductive material having a function of inhibiting passage of impurities such as water and hydrogen can be used as a single layer or stacked layers. Providing the conductors 240a1 and 240b1 can inhibit entry of impurities such as water and hydrogen into the oxide semiconductor 230 through the conductors 240a2 and 240b2. Note that the conductors 240a2 and 240b2 can be formed using any of the conductive materials that can be used for the conductors 240a and 240b.

As illustrated in FIG. 1B, the conductors 240a and 240b can be formed such that their top surfaces are level or substantially level with the top surface of the insulator 285. As illustrated in FIG. 2A, the conductor 240a may be formed such that its lower portion is embedded in the conductor 242a. Similarly, the conductor 240b may be formed such that its lower portion is embedded in the conductor 242b.

The insulators 241a and 241b can be formed using a barrier insulator that can be used for the insulator 275 and the like. For example, silicon nitride is used for the insulators 241a and 241b. The insulators 241a and 241b are provided in contact with the insulators 285, 283, 282, 275, 271a, and 271b. Thus, impurities such as water and hydrogen contained in the insulator 280 or the like can be inhibited from entering the oxide semiconductor 230 through the conductors 240a and 240b. Silicon nitride is particularly preferable because of its high blocking property against hydrogen. Furthermore, oxygen contained in the insulator 280 can be prevented from being absorbed by the conductors 240a and 240b.

The insulators 241a and 241b may each have a stacked-layer structure. In this case, a combination of a barrier insulator against oxygen and a barrier insulator against hydrogen is preferably used for a first insulator in contact with a sidewall of the opening formed in the insulator 280 and the like and a second insulator on the inner side of the first insulator.

### Variation Example 1

In FIG. 1B and the like, the insulator 250 is in contact with the side surface of the insulator 280 in the opening portion provided in the insulator 280; however, the present invention is not limited to this structure. For example, an insulator may be provided between the insulator 250 and the insulator 280 in the opening portion.

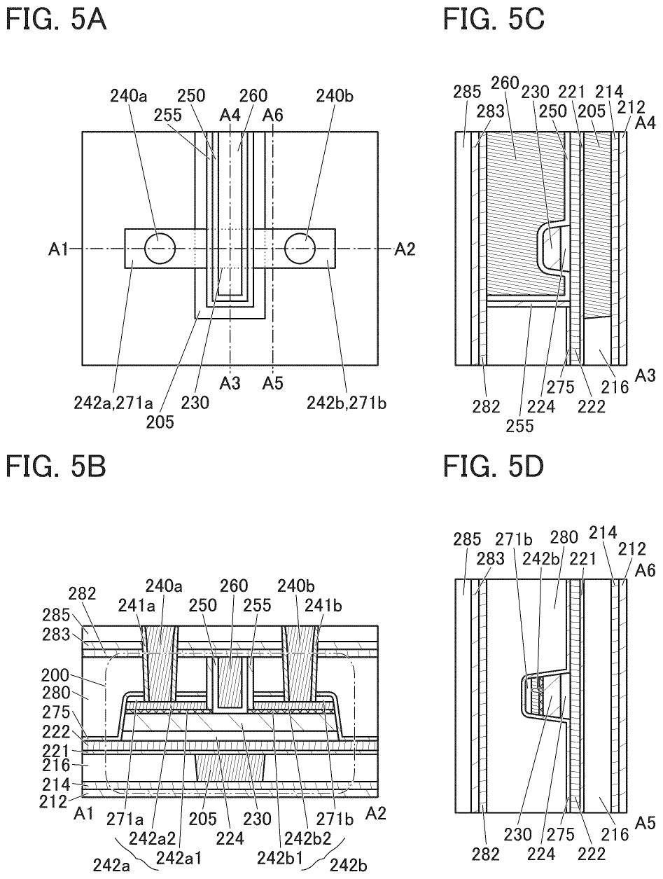

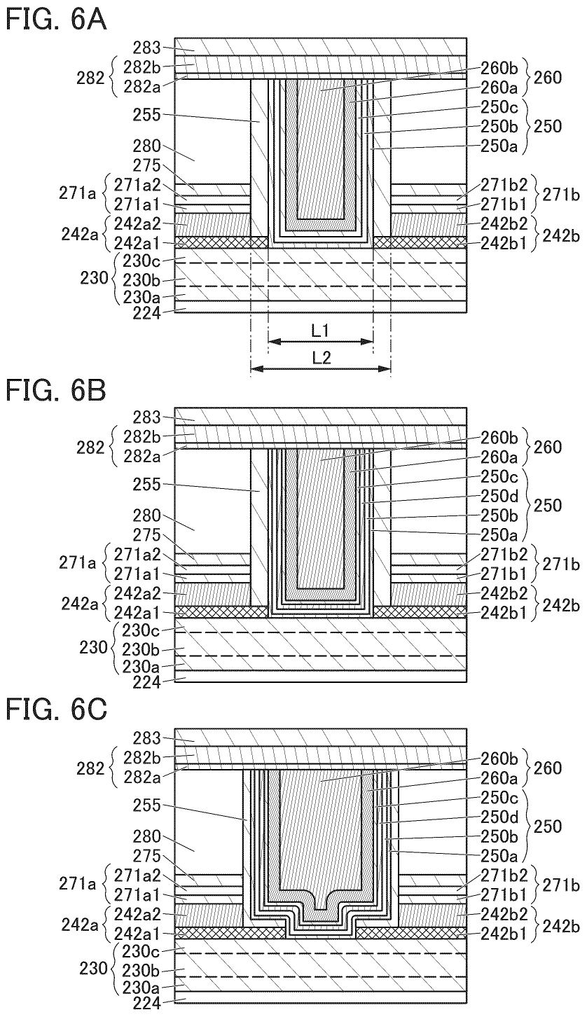

A variation example of the semiconductor device described in <Structure example of semiconductor device> will be described with reference to FIGS. 5A to 5D and FIGS. 6A to 6C. FIGS. 5A to 5D are a plan view and cross-sectional views of a semiconductor device including the transistor 200 and correspond to the plan view and cross-sectional views in FIGS. 1A to 1D. FIGS. 6A to 6C are enlarged cross-sectional views of the transistor 200 in the channel length direction and correspond to the enlarged cross-sectional view in FIG. 2B.

The transistor 200 illustrated in FIGS. 5A to 5D is a variation example of the transistor 200 illustrated in FIGS. 1A to 1D. Specifically, the transistor 200 illustrated in FIGS. 5A to 5D is different from the transistor 200 illustrated in FIGS. 1A to 1D mainly in including an insulator 255. Differences from the above description of <Structure example of semiconductor device> are mainly described below. The description of <Structure example of semiconductor device> is referred to for the same portions, and the description of the same portion is omitted in some cases.

Note that in FIGS. 5A to 5D, the conductors 242a and 242b each have a two-layer structure. The conductor 242a has a stacked-layer structure of a conductor 242a1 and a conductor 242a2 over the conductor 242a1. The conductor 242b has a stacked-layer structure of a conductor 242b1 and a conductor 242b2 over the conductor 242b1. The conductors 242a1 and 242b1 correspond to the lower layers of the conductors 242a and 242b, and the conductors 242a2 and 242b2 correspond to the upper layers of the conductors 242a and 242b.

As illustrated in FIGS. 5B and 5C, the insulator 255 is provided inside the opening portion formed in the insulator 280 and the like, and is in contact with the side surface of the insulator 280, the side surface of the conductor 242a2, the side surface of the conductor 242b2, the top surface of the conductor 242a1, the top surface of the conductor 242b1, and the top surface of the insulator 222 in the opening portion. In other words, the insulator 255 is formed in a sidewall shape to be in contact with a sidewall of the opening portion formed in the insulator 280 and the like. Here, the sidewall of the opening portion corresponds to, for example, the side surface of the insulator 280 and the like in the opening portion.

The insulator 250 is in contact with a side surface of the insulator 255.

The insulator 255 preferably has a barrier property against oxygen. When the insulator 255 has a barrier property against oxygen, oxidation of the side surfaces of the conductors 242a and 242b, which forms oxide films on the side surfaces, can be inhibited. It is thus possible to inhibit a reduction in the on-state current or field-effect mobility of the transistor 200. The insulator 255 can be formed using a barrier insulator that can be used for the insulator 275 and the like. For example, silicon nitride is used for the insulator 255.

The opening portion formed in the insulator 280 overlap with a region between the conductors 242a2 and 242b2. In a top view, the side surface of the insulator 280 in the opening portion is aligned or substantially aligned with the side surfaces of the conductors 242a2 and 242b2. Parts of the conductors 242a1 and 242b1 are formed to extend to the inside of the opening portion. In other words, part of the conductor 242a1 having a top surface on which the insulator 255 is formed (hereinafter sometimes referred to as an extending portion of the conductor 242a1) is formed to extend beyond the conductor 242a2 toward the conductor 260. Similarly, part of the conductor 242b1 having a top surface on which the insulator 255 is formed (hereinafter sometimes referred to as an extending portion of the conductor 242b1) is formed to extend beyond the conductor 242b2 toward the conductor 260.

Part of the top surface of the conductor 242a1 is in contact with the conductor 242a2, and part of the top surface of the conductor 242b1 is in contact with the conductor 242b2. Accordingly, the insulator 255 is in contact with another part of the top surface of the conductor 242a1, another part of the top surface of the conductor 242b1, the side surface of the conductor 242a2, and the side surface of the conductor 242b2 inside the opening portion. Moreover, the insulator 250 is in contact with the top surface of the oxide semiconductor 230, a side surface of the conductor 242a1, a side surface of the conductor 242b1, and the side surface of the insulator 255.

After a conductive layer is divided into the conductor 242a2 and the conductor 242b2, the insulator 255 is formed by anisotropic etching. The insulator 255 is formed in a sidewall shape to be in contact with the sidewall of the opening portion provided in the insulator 280. The insulator 255 is formed in contact with the side surfaces of the conductors 242a2 and 242b2 and has a function of protecting the conductors 242a2 and 242b2.

The insulator 255 functions as a mask at the time of dividing the conductive layer into the conductors 242a1 and 242b1. Thus, as illustrated in FIG. 6A, in the cross-sectional view of the transistor 200, side end portions of the insulator 255 are preferably aligned with a side end portion of the conductor 242a1 and a side end portion of the conductor 242b1.

Note that heat treatment in an oxygen-containing atmosphere is preferably performed after the division of the conductive layer into the conductors 242a1 and 242b1 and before the formation of the insulator 250. At this time, since the insulator 255 is formed in contact with the side surfaces of the conductors 242a2 and 242b2, excessive oxidation of the conductors 242a2 and 242b2 can be prevented. Furthermore, even in the case where microwave treatment is performed after the division of the conductive layer into the conductors 242a1 and 242b1, formation of an oxide film on the side surfaces of the conductors 242a and 242b can be inhibited.

Portions of the insulators 255 and 250 and the conductor 260 that are placed in the opening portion provided in the insulator 280 are provided to reflect the shape of the opening portion. Thus, the insulator 255 is provided to cover the sidewall of the opening portion, the insulator 250 is provided to cover the bottom portion of the opening portion and the insulator 255, and the conductor 260 is provided to fill a recess portion defined by the insulator 250.

Note that the insulator 250 may have a stacked-layer structure as in <Structure example of semiconductor device> described above. For example, as illustrated in FIG. 6A, the insulator 250 may have a three-layer structure of the insulators 250a, 250b, and 250c. As another example, as illustrated in FIG. 6B, the insulator 250 may have a four-layer structure of the insulators 250a, 250b, 250c, and 250d. Without limitation to the structure illustrated in FIG. 6B, any one or more of the insulators 250a, 250b, 250c, and 250d can be selected to form the insulator 250. For example, the insulator 250 can have any of the structures illustrated in FIGS. 3A to 3D.

The thickness of the insulator 255 is preferably greater than or equal to 0.5 nm and less than or equal to 20 nm, further preferably greater than or equal to 0.5 nm and less than or equal to 10 nm, still further preferably greater than or equal to 0.5 nm and less than or equal to 3 nm. When the insulator 255 has a thickness in the above range, excessive oxidation of the conductors 242a2 and 242b2 can be inhibited. Note that at least part of the insulator 255 includes a region with the above thickness. Since the insulator 255 is provided in contact with the sidewall of the opening formed in the insulator 280 and the like, the insulator 255 is preferably formed by a method capable of forming a film with good coverage, such as an ALD method. When the thickness of the insulator 255 is excessively large, the time for depositing the insulator 255 by an ALD method is long, which decreases the productivity; for this reason, the thickness of the insulator 255 is preferably in the above range. Moreover, the insulator 255 preferably has a thickness that does not excessively inhibit diffusion of excess oxygen from the insulator 280 to the insulator 250b and diffusion of excess oxygen from the insulator 250b to the oxide semiconductor 230.

As illustrated in FIG. 6A, in the cross-sectional view of the transistor 200 in the channel length direction, a distance L1 between the conductors 242a1 and 242b1 is smaller than a distance L2 between the conductors 242a2 and 242b2. Here, the distance L1 refers to the shortest distance between the conductors 242a1 and 242b1, and the distance L2 refers to the shortest distance between the conductors 242a2 and 242b2. With such a structure, the distance between the source and the drain can be shortened, and the channel length can be accordingly shortened. This can improve the frequency characteristics of the transistor 200. In this manner, scaling down of the semiconductor device enables the semiconductor device to have a higher operating speed.

In the structure illustrated in FIG. 6A, the difference between the distance L2 and the distance L1 is twice the thickness of the insulator 255. In other words, the distance L2 is equal to the sum of the distance L1 and twice the thickness of the insulator 255. Here, the thickness of the insulator 255 corresponds to the width in the A1-A2 direction of at least part of the insulator 255.

The insulator 255 may have a stacked-layer structure of two or more layers. In such a case, at least one of the stacked layers is the above-described inorganic insulator that is less likely to be oxidized. For example, an inorganic insulator that is less likely to be oxidized is used as a first insulator of the insulator 255, and an insulator (e.g., silicon oxide) that can be used as the insulator 250b is used as a second insulator over the first insulator of the insulator 255. The second insulator of the insulator 255 preferably has a lower permittivity than the first insulator of the insulator 255. When the insulator 255 has a two-layer structure to have a large thickness in the above manner, the distance between the conductor 260 and the conductor 242a or 242b can be increased and thus the parasitic capacitance can be reduced.

Although an example in which the insulator 255 is formed in a sidewall shape by anisotropic etching is described above, the present invention is not limited thereto. As illustrated in FIG. 6C, the insulator 255 can have an opening inside the opening formed in the insulator 280 and the like. In this case, the opening of the insulator 255 can be formed by removing part of an insulating film to be the insulator 255 by a lithography method. The opening of the insulator 255 preferably overlaps with a region between the conductors 242a1 and 242b1.

As illustrated in FIG. 6C, protruding portions are formed in a lower portion of the insulator 255 in the cross-sectional view. The protruding portions of the insulator 255 overlap with the extending portion of the conductor 242a1 and the extending portion of the conductor 242b1.

### Variation Example 2

Although Variation example 1 describes the structure in which the insulator 255 is provided in contact with the sidewall of the opening portion formed in the insulator 280 and the like, the present invention is not limited to this structure. For example, a structure where the insulator 255 is not provided in the opening portion may be employed.

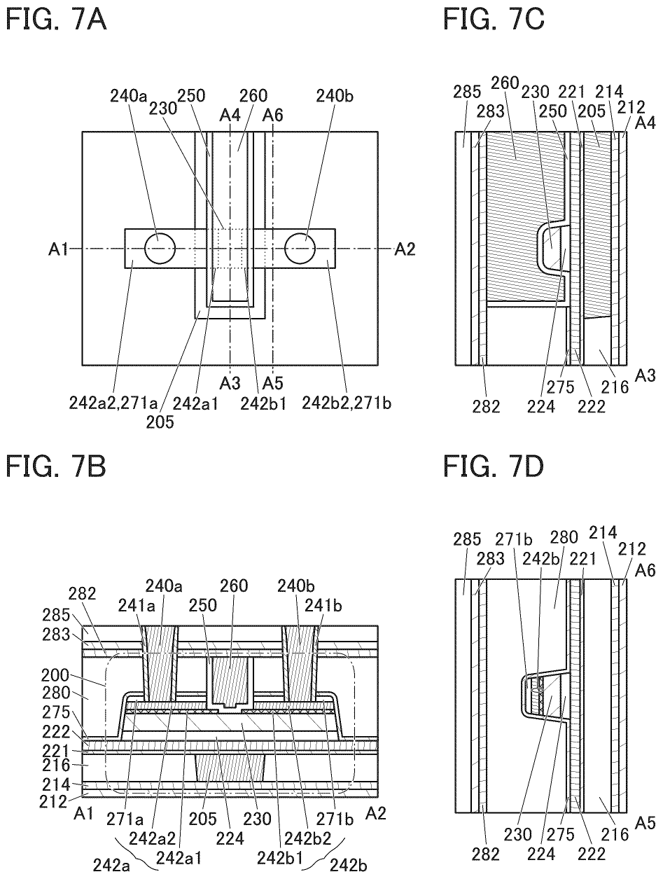

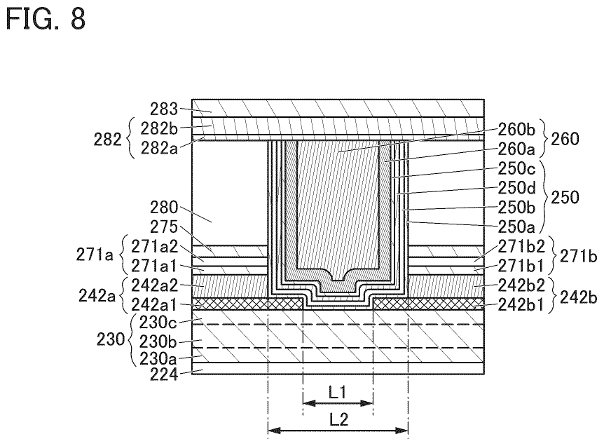

A variation example of the semiconductor device described in Variation example 1 will be described with reference to FIGS. 7A to 7D and FIG. 8. FIGS. 7A to 7D are a plan view and cross-sectional views of a semiconductor device including the transistor 200 and correspond to the plan view and cross-sectional views in FIGS. 5A to 5D. FIG. 8 is an enlarged cross-sectional view of the transistor 200 in the channel length direction and corresponds to the enlarged cross-sectional view in FIG. 6C.

The transistor 200 illustrated in FIGS. 7A to 7D is a variation example of the transistor 200 illustrated in FIGS. 5A to 5D. Specifically, the transistor 200 illustrated in FIGS. 7A to 7D is different from the transistor 200 illustrated in FIGS. 5A to 5D mainly in not including the insulator 255. Differences from the above description of <Structure example of semiconductor device> and <Variation example 1> are mainly described below. The description of <Structure example of semiconductor device> and <Variation example 1> is referred to for the same portions, and the description of the same portion is omitted in some cases.

As illustrated in FIG. 8, in the case where the insulator 255 is not provided, part of the insulator 250 is positioned to overlap with the extending portions of the conductors 242a1 and 242b1. In some cases, part of the conductor 260 is positioned to overlap with the extending portions of the conductors 242a1 and 242b1. Here, the extending portions of the conductors 242a1 and 242b1 are in contact with the insulator 250. The side surface of the insulator 250 is in contact with the side surfaces of the insulators 280, 275, 271a, and 271b and the side surfaces of the conductors 242a2 and 242b2.

A portion of the insulator 250 that is placed in the opening portion provided in the insulator 280 is formed to reflect the shape of the opening portion. Accordingly, the insulator 250 is formed to reflect the shapes of the conductors 242a1 and 242b1 that extend in the opening portion.

As illustrated in FIG. 8, in the cross-sectional view of the transistor 200 in the channel length direction, the distance L1 between conductors 242a1 and 242b1 is smaller than the distance L2 between the conductors 242a2 and 242b2. With this structure, the distance between the source and the drain can be shortened, and the channel length can be accordingly shortened. This can improve the frequency characteristics of the transistor 200. In this manner, scaling down of the semiconductor device enables the semiconductor device to have a higher operating speed.

Furthermore, with the structure illustrated in FIG. 8, the width of the upper portion of the conductor 260 can be larger than the distance L1. This can reduce the wiring resistance of the conductor 260. Consequently, power consumption of the semiconductor device can be reduced.

Note that the insulator 250 may have a stacked-layer structure as in <Structure example of semiconductor device> described above. For example, as illustrated in FIG. 6A, the insulator 250 may have a three-layer structure of the insulators 250a, 250b, and 250c. As another example, as illustrated in FIG. 6B, the insulator 250 may have a four-layer structure of the insulators 250a, 250b, 250c, and 250d. Without limitation to the structure illustrated in FIG. 6B, any one or more of the insulators 250a, 250b, 250c, and 250d can be selected to form the insulator 250. For example, the insulator 250 can have any of the structures illustrated in FIGS. 3A to 3D.

### <Materials for Semiconductor Device>

Materials that can be used for the semiconductor device will be described below. Note that the layers included in the semiconductor device may each have a single-layer structure or a stacked-layer structure.

### <<Substrate>>

As a substrate where a transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Another example includes a semiconductor substrate in which an insulator region is provided in the above semiconductor substrate, such as a silicon-on-insulator (SOI) substrate. Examples of the conductor substrate include a graphite substrate, a metal substrate, an alloy substrate, and a conductive resin substrate. Examples of the substrate include a substrate including a metal nitride, a substrate including a metal oxide, an insulator substrate provided with a conductor or a semiconductor, a semiconductor substrate provided with a conductor or an insulator, and a conductor substrate provided with a semiconductor or an insulator. Alternatively, these substrates provided with one or more kinds of elements may be used. Examples of the element provided for the substrate include a capacitor, a resistor, a switching element, a light-emitting element, and a memory element.

### <<Insulator>>

Any of the following insulators can be used as appropriate for the insulators 212, 214, 216, 221, 222, 224, 250, 275, 280, 282, 283, 285, 241a, 241b, 271a, 271b, and 255 described in this embodiment. Examples of the insulators include an insulating oxide, an insulating nitride, an insulating oxynitride, an insulating nitride oxide, an insulating metal oxide, an insulating metal oxynitride, and an insulating metal nitride oxide.

With miniaturization and high integration of transistors, for example, a problem such as generation of leakage current may arise because of a thin gate insulator. When a high-k material is used for the insulator functioning as a gate insulator, the voltage at the time of operation of the transistor can be lowered while the physical thickness is maintained. By contrast, when a material having a low dielectric constant is used for the insulator functioning as an interlayer film, parasitic capacitance generated between wirings can be reduced. Thus, a material is preferably selected depending on the function of an insulator.

Examples of the insulator having a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator having a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

A transistor including a metal oxide can have stable electrical characteristics when surrounded by an insulator having a function of inhibiting passage of oxygen and impurities such as hydrogen. The insulator having a function of inhibiting passage of oxygen and impurities such as hydrogen can have, for example, a single-layer structure or a stacked-layer structure of an insulator(s) including one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specific examples of the insulator having a function of inhibiting passage of oxygen and impurities such as hydrogen include a metal oxide such as aluminum oxide, magnesium oxide, gallium oxide, germanium oxide, yttrium oxide, zirconium oxide, lanthanum oxide, neodymium oxide, hafnium oxide, and tantalum oxide and a nitride such as aluminum nitride, silicon nitride oxide, and silicon nitride.

The insulator functioning as a gate insulator preferably includes a region containing oxygen that is released by heating. For example, silicon oxide or silicon oxynitride that includes a region containing oxygen that is released by heating can be provided in contact with the oxide semiconductor 230 to compensate for oxygen vacancies in the oxide semiconductor 230.

### <<Conductor>>

Any of the following conductors can be used as appropriate for the conductors 205, 242a, 242b, 260, 240a, and 240b described in this embodiment. For the conductor, it is preferable to use a metal element selected from aluminum, chromium, copper, silver, gold, platinum, tantalum, nickel, cobalt, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. Examples of the conductors include tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. Alternatively, a semiconductor having high electric conductivity, typified by polycrystalline silicon containing an impurity element such as phosphorus, or silicide such as nickel silicide may be used.

In the case where a stacked-layer structure of conductors is used, for example, a stacked-layer structure combining a material containing any of the metal elements and a conductive material containing oxygen, a stacked-layer structure combining a material containing any of the metal elements and a conductive material containing nitrogen, or a stacked-layer structure combining a material containing any of the above metal elements, a conductive material containing oxygen, and a conductive material containing nitrogen may be employed.

When an oxide is used for the channel formation region of the transistor, the conductor functioning as the gate electrode preferably has a stacked-layer structure combining a material containing any of the above metal elements and a conductive material containing oxygen. In this case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing any of the above metal elements and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may also be used. With the use of such a material, hydrogen contained in the metal oxide where the channel is formed can be captured in some cases. Hydrogen entering from an outer insulator or the like can also be captured in some cases.

### <Example of Method for Manufacturing Semiconductor Device>

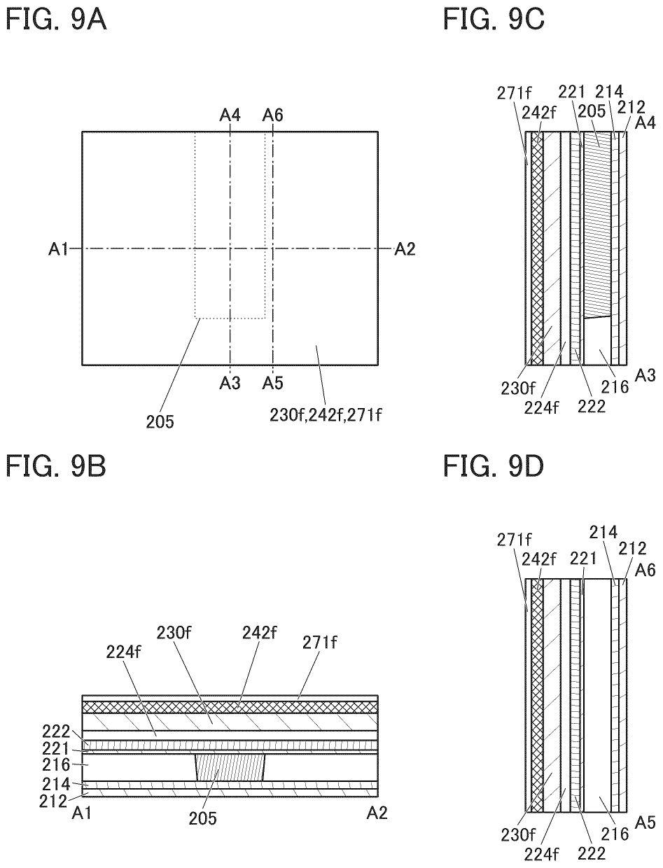

An example of a method for manufacturing the semiconductor device of one embodiment of the present invention will be described with reference to FIGS. 9A to 9D to FIGS. 16A to 16D. Here, the case of manufacturing the semiconductor device illustrated in FIGS. 1A to 1D will be described as an example.

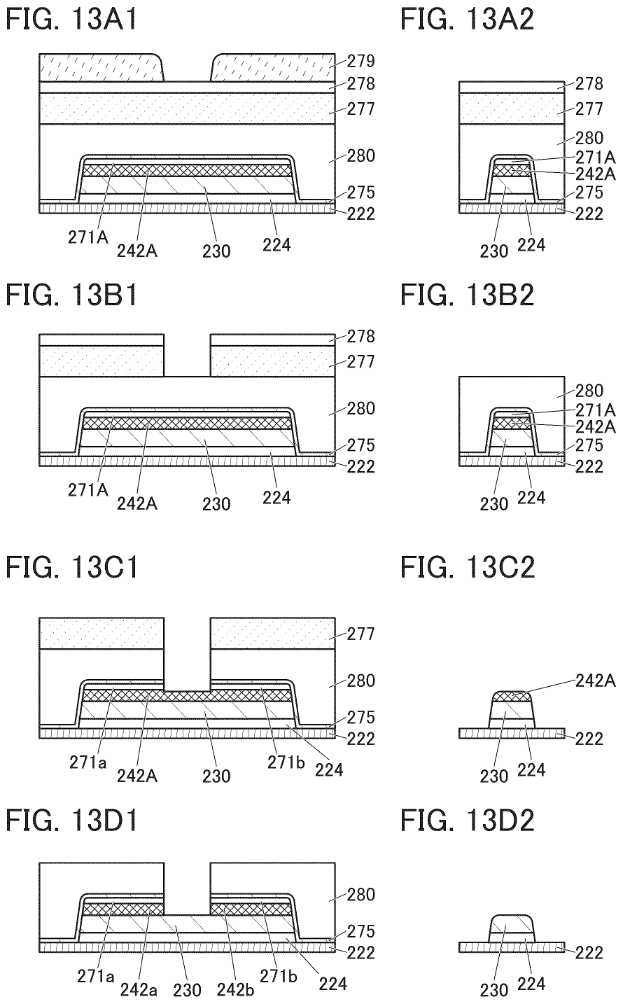

FIGS. 9A, 10A, 11A, 12A, 14A, 15A, and 16A are plan views. FIGS. 9B, 10B, 11B, 12B, 14B, 15B and 16B are cross-sectional views taken along the dashed-dotted lines A1-A2 in FIGS. 9A, 10A, 11A, 12A, 14A, 15A and 16A, illustrating the transistor 200 in the channel length direction. FIGS. 9C, 10C, 11C, 12C, 14C, 15C and 16C are cross-sectional views taken along the dashed-dotted lines A3-A4 in FIGS. 9A, 10A, 11A, 12A, 14A, 15A and 16A, illustrating the transistor 200 in the channel width direction. FIGS. 9D, 10D, 11D, 12D, 14D, 15D and 16D are cross-sectional views taken along the dashed-dotted lines A5-A6 in FIGS. 9A, 10A, 11A, 12A, 14A, 15A and 16A, illustrating the transistor 200 in the channel width direction. Note that for simplification, some components are not illustrated in the plan views of FIGS. 9A, 10A, 11A, 12A, 14A, 15A and 16A. FIGS. 13A1, 13B1, 13C1, and 13D1 are cross-sectional views corresponding to part of FIG. 1B, illustrating the transistor 200 in the channel length direction. FIGS. 13A2, 13B2, 13C2, and 13D2 are cross-sectional views corresponding to part of FIG. 1C, illustrating the transistor 200 in the channel width direction.

In the following steps, an insulating material for forming an insulator, a conductive material for forming a conductor, or a semiconductor material for forming a semiconductor can be formed by a sputtering method, a chemical vapor deposition (CVD) method, a molecular beam epitaxy (MBE) method, a pulsed laser deposition (PLD) method, an ALD method, or the like as appropriate.

First, a substrate (not illustrated) is prepared, the insulator 212 is formed over the substrate, and the insulator 214 is formed over the insulator 212 (see FIGS. 9A to 9D). Any of the above insulating materials can be used for the insulators 212 and 214. The insulators 212 and 214 can be formed, for example, by a sputtering method, a CVD method, an MBE method, a PLD method, or an ALD method. A sputtering method that does not need to use a molecule containing hydrogen as a film formation gas is preferably used, in which case the hydrogen concentration in the insulators 212 and 214 can be reduced.

In this embodiment, a silicon nitride film is formed by a sputtering method as the insulator 212, and an aluminum oxide film is formed by a sputtering method as the insulator 214. When silicon nitride having a function of inhibiting diffusion of hydrogen is used for the insulator 212, diffusion of hydrogen from a layer below the transistor 200 can be inhibited. Furthermore, when aluminum oxide having a function of capturing or fixing hydrogen is used for the insulator 214, hydrogen contained in the insulator 216 or the like can be captured or fixed by the insulator 214. Thus, the hydrogen concentration in the oxide semiconductor 230 and in the vicinity thereof can be reduced.

Before the insulator 212 is formed, heat treatment is preferably performed to reduce water and hydrogen adsorbed on the substrate (including a circuit element and an interlayer film formed over the substrate). In this embodiment, the temperature of the heat treatment is 400° C.

Next, the insulator 216 is formed over the insulator 214. The insulator 216 is preferably formed by a sputtering method. By using a sputtering method that does not need to use a molecule containing hydrogen as a film formation gas, the hydrogen concentration in the insulator 216 can be reduced. Note that the insulator 216 can alternatively be formed as appropriate by a CVD method, an MBE method, a PLD method, or an ALD method, for example, instead of a sputtering method. In this embodiment, a silicon oxide film is formed as the insulator 216 by a sputtering method.

The insulators 212, 214, and 216 are preferably formed successively without exposure to the air. For example, a multi-chamber film formation apparatus is used. As a result, the amount of hydrogen in the formed films of the insulators 212, 214, and 216 can be reduced, and furthermore, entry of hydrogen in the films between the film formation steps can be inhibited.

Then, an opening reaching the insulator 214 is formed in the insulator 216. The opening is formed in a region where the conductor 205 is to be formed. Wet etching can be used for the formation of the opening; however, dry etching is preferable for microfabrication. The insulator 214 is preferably an insulator that functions as an etching stopper film at the time of etching of the insulator 216. For example, in the case where silicon oxide or silicon oxynitride is used as the insulator 216, the insulator 214 is preferably silicon nitride, aluminum oxide, hafnium oxide, or the like.

After the formation of the opening, a conductive film to be the conductor 205 is formed and subjected to CMP treatment until the insulator 216 is exposed, so that part of the conductive film to be the conductor 205 is removed. Thus, the conductor 205 embedded in the insulator 216 can be formed (see FIGS. 9A to 9D).

The conductive film to be the conductor 205 can be formed using any of the above conductive materials by a sputtering method, a CVD method, an MBE method, a PLD method, an ALD method, or the like. For example, a tantalum nitride film, a titanium nitride film, and a tungsten film are stacked by a CVD method. Thus, as illustrated in FIG. 2A, the conductor 205 can have a stacked-layer structure of the conductor 205a in which titanium nitride is stacked over tantalum nitride and the conductor 205b of tungsten.

Next, the insulator 221 is formed over the insulator 216 and the conductor 205 (see FIGS. 9A to 9D).

The above-described insulator having a barrier property against oxygen, hydrogen, and water is used as the insulator 221. The insulator 221 can be formed by a sputtering method, a CVD method, an MBE method, a PLD method, or an ALD method, for example. In this embodiment, a silicon nitride film is formed as the insulator 221 by a PEALD method.

Then, the insulator 222 is formed over the insulator 221 (see FIGS. 9A to 9D).

The insulator 222 is preferably formed using an insulator containing an oxide of one or both of aluminum and hafnium. Note that as the insulator containing an oxide of one or both of aluminum and hafnium, aluminum oxide, hafnium oxide, or an oxide containing aluminum and hafnium (hafnium aluminate) is preferably used, for example. Alternatively, hafnium zirconium oxide is preferably used. The insulator containing an oxide of one or both of aluminum and hafnium has a barrier property against oxygen, hydrogen, and water. When the insulator 222 has a barrier property against hydrogen and water, hydrogen and water contained in a component provided around the transistor can be inhibited from diffusing into the transistor through the insulator 222, and accordingly oxygen vacancies can be inhibited from being generated in the oxide semiconductor 230.

The insulator 222 can be formed by a sputtering method, a CVD method, an MBE method, a PLD method, or an ALD method, for example. In this embodiment, a hafnium oxide film is formed as the insulator 222 by a thermal ALD method.

In this embodiment, a silicon nitride film is formed as the insulator 221 by a PEALD method, and a hafnium oxide film is formed as the insulator 222 by a thermal ALD method. The use of silicon nitride having a function of inhibiting diffusion of hydrogen for the insulator 221 can inhibit diffusion of hydrogen from a layer below the transistor 200. Furthermore, with the use of hafnium oxide having a function of capturing or fixing hydrogen for the insulator 222, hydrogen contained in the insulator 224 or the like can be captured or fixed by the insulator 222. Thus, the hydrogen concentration in the oxide semiconductor 230 and in the vicinity thereof can be reduced.

Next, an insulating film 224f is formed over the insulator 222 (see FIGS. 9A to 9D). For the insulating film 224f, an insulator corresponding to the insulator 224 is used. By forming the insulating film 224f in this manner, the insulating film 224f is formed in parallel or substantially in parallel with the surface of the substrate.

The insulating film 224f can be formed by a sputtering method, a CVD method, an MBE method, a PLD method, or an ALD method, for example. In this embodiment, a silicon oxide film is formed as the insulating film 224f by a sputtering method. Since a molecule containing hydrogen is not used as a film formation gas in a sputtering method, the hydrogen concentration in the insulating film 224f can be reduced. The hydrogen concentration in the insulating film 224f is preferably reduced in this manner because the insulating film 224f is in contact with the oxide semiconductor 230 in a later step.

Next, an oxide semiconductor film 230f is formed over the insulating film 224f (see FIGS. 9A to 9D). The oxide semiconductor film 230f is formed by the same method as an oxide semiconductor that will be described in Embodiment 2. For the oxide semiconductor film 230f, it is preferable to use an indium-containing oxide (e.g., indium oxide, indium gallium oxide, indium zinc oxide, indium gallium zinc oxide, or indium gallium tin zinc oxide). With the oxide semiconductor film 230f including an indium-containing oxide, it is possible to provide a semiconductor device having high field-effect mobility. It is also possible to provide a semiconductor device having at least one of favorable electrical characteristics, high frequency characteristics, and high reliability. Note that the oxide semiconductor film 230f formed in the above manner is formed in parallel or substantially in parallel with the surface of the substrate.

For example, in the case where the oxide semiconductor 230 has a three-layer structure of the oxide semiconductors 230a to 230c as illustrated in FIG. 2A, films to be the oxide semiconductors 230a and 230b can be formed by an ALD method and a film to be the oxide semiconductor 230c can be formed by a sputtering method. Specifically, the film to be the oxide semiconductor 230a can be formed to have a composition of In:Ga:Zn=1:3:2 [atomic ratio] or in the neighborhood thereof. Alternatively, gallium oxide may be used for the film to be the oxide semiconductor 230a. The film to be the oxide semiconductor 230b can be formed using indium oxide. The film to be the oxide semiconductor 230c can be formed using an oxide target with a composition of In:Ga:Zn=1:1:1.2 [atomic ratio] or in the neighborhood thereof.

As another example, the oxide semiconductor 230a in the above structure can be deposited by a sputtering method. Specifically, the film to be the oxide semiconductor 230a can be formed using an oxide target with a composition of In:Ga:Zn=1:3:2 [atomic ratio] or in the neighborhood thereof.

Next, heat treatment is preferably performed. The heat treatment of the oxide semiconductor film 230f can be performed by the same method as heat treatment that will be described in Embodiment 2.

For example, heat treatment can be performed at 450° C. for one hour at a flow rate ratio of a nitrogen gas to an oxygen gas of 4:1.

By performing the heat treatment, the crystallinity of the oxide semiconductor 230 can be improved. Accordingly, the on-state current, subthreshold swing value (S value), field-effect mobility, frequency characteristics, and the like of the transistor 200 can be improved, so that a semiconductor device having favorable electrical characteristics can be provided. Moreover, a highly reliable semiconductor device can be provided.

Note that the heat treatment is preferably performed in a nitrogen gas atmosphere, an inert gas atmosphere, or an atmosphere containing an oxidizing gas at 10 ppm or more, 1% or more, or 10% or more. The heat treatment may be performed under a reduced pressure. Alternatively, the heat treatment may be performed in such a manner that heat treatment is performed in an atmosphere of a nitrogen gas or an inert gas, and then another heat treatment is performed in an atmosphere containing an oxidizing gas at 10 ppm or more, 1% or more, or 10% or more in order to compensate for released oxygen.

The gas used in the above heat treatment is preferably highly purified. For example, the amount of moisture contained in the gas used in the above heat treatment is preferably 1 ppb or less, further preferably 0.1 ppb or less, still further preferably 0.05 ppb or less. The heat treatment using a highly purified gas can prevent the entry of moisture or the like into the oxide semiconductor film 230f and the like as much as possible. Note that a highly purified gas can also be used in heat treatment before this step and heat treatment after this step.

With the heat treatment using the above-described oxygen gas, impurities such as carbon, water, and hydrogen in the oxide semiconductor film 230f can be reduced. Impurities in the film are reduced in the above manner, whereby the crystallinity of the oxide semiconductor film 230f can be improved and a denser structure can be obtained. Accordingly, the crystal region in the oxide semiconductor film 230f can be increased, and in-plane variations of crystal regions in the oxide semiconductor film 230f can be reduced. Thus, in-plane variations in electrical characteristics of the transistors can be reduced.

The heat treatment can supply oxygen to the oxide semiconductor film 230f to reduce oxygen vacancies in the oxide semiconductor film 230f. Thus, the reliability of the transistor 200 can be improved.

By the heat treatment, hydrogen contained in the insulator 216, the insulating film 224f, and the oxide semiconductor film 230f is transferred to the insulator 222 and is absorbed by the insulator 222. In other words, hydrogen contained in the insulator 216, the insulating film 224f, and the oxide semiconductor film 230f diffuses into the insulator 222. Accordingly, the hydrogen concentration in the insulator 222 increases, whereas the hydrogen concentrations in the insulator 216, the insulating film 224f, and the oxide semiconductor film 230f decrease. Note that the insulator 221 is provided in contact with the bottom surface of the insulator 222, whereby entry of moisture or impurities such as hydrogen from below the insulator 221, which would be caused by the heat treatment, can be prevented.

Specifically, the insulating film 224f (to be the insulator 224 later) functions as the second gate insulator of the transistor 200, and the oxide semiconductor film 230f (to be the oxide semiconductor 230 later) function as the channel formation region of the transistor 200. The transistor 200 including the insulating film 224f and the oxide semiconductor film 230f with reduced hydrogen concentrations is preferable because of its favorable reliability.

Subsequently, a conductive film 242f is formed over the oxide semiconductor film 230f (see FIGS. 9A to 9D). For the conductive film 242f, a conductor corresponding to the conductors 242a and 242b is used. The conductive film 242f is formed over and in contact with the oxide semiconductor film 230f without an etching step or the like performed after the formation of the oxide semiconductor film 230f, whereby the top surface of the oxide semiconductor film 230f can be protected by the conductive film 242f. Thus, diffusion of impurities into the oxide semiconductor 230 included in the transistor can be reduced, so that the electrical characteristics and reliability of the semiconductor device can be improved.

The conductive film 242f can be formed by a sputtering method, a CVD method, an MBE method, a PLD method, an ALD method, or the like.

In this embodiment, a tantalum nitride film is formed as the conductive film 242f by a sputtering method. Note that heat treatment may be performed before the formation of the conductive film 242f. The heat treatment may be performed under a reduced pressure, and the conductive film 242f may be successively formed without exposure to the air. By such treatment, moisture and hydrogen adsorbed on the surface of the oxide semiconductor 230 can be removed, and the moisture concentration and the hydrogen concentration in the oxide semiconductor 230 can be reduced. The heat treatment temperature is preferably higher than or equal to 100° C. and lower than or equal to 400° C.

Next, an insulating film 271f is formed over the conductive film 242f (see FIGS. 9A to 9D). The insulating film 271f can be formed by a sputtering method, a CVD method, an MBE method, a PLD method, an ALD method, or the like. The insulating film 271f is preferably an insulating film having a function of inhibiting transmission of oxygen. For example, a stacked-layer film of a silicon nitride film and a silicon oxide film over the silicon nitride film is formed as the insulating film 271f by a sputtering method. With such a structure, the insulator 271a (or the insulator 271b) can have a stacked-layer structure of the insulator 271a1 (or the insulator 271b1) of silicon nitride and the insulator 271a2 (or the insulator 271b2) of silicon oxide.

Here, in the case where the insulating film 271f is formed by stacking films, the films are preferably formed successively without exposure to the air. By the film formation without exposure to the air, the interface between the stacked films of the insulating film 271f and the vicinity thereof can be kept clean. It is further preferable to form the conductive film 242f and the insulating film 271f successively without exposure to the air.

Note that heat treatment may be performed before the formation of the insulating film 271f. The heat treatment may be performed under a reduced pressure, and the insulating film 271f may be successively formed without exposure to the air. Such treatment can remove moisture and hydrogen adsorbed on the surface of the conductive film 242f and reduce the moisture concentration and the hydrogen concentration in the conductive film 242f. The heat treatment temperature is preferably higher than or equal to 100° C. and lower than or equal to 400° C.

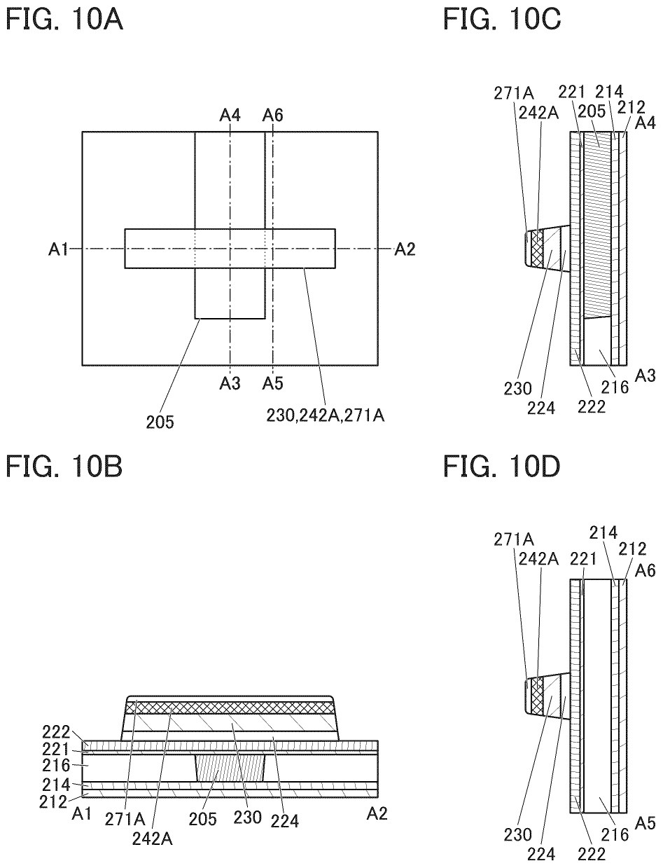

Next, the insulating film 224f, the oxide semiconductor film 230f, the conductive film 242f, and the insulating film 271f are processed into an island shape by a lithography method, whereby the insulator 224, the oxide semiconductor 230, a conductor 242A, and an insulator 271A are formed (see FIGS. 10A to 10D).

The processing can be performed by a dry etching method or a wet etching method. A dry etching method is suitable for microfabrication. The insulating film 224f, the oxide semiconductor film 230f, the conductive film 242f, and the insulating film 271f may be processed under different conditions.

Here, the insulator 224, the oxide semiconductor 230, the conductor 242A, and the insulator 271A are preferably processed into an island shape at one time. In that case, the side end portion of the conductor 242A is preferably aligned or substantially aligned with the side end portion of the oxide semiconductor 230. The side end portion of the insulator 224 is preferably aligned or substantially aligned with the side end portion of the oxide semiconductor 230. The side end portion of the insulator 271A is preferably aligned or substantially aligned with the side end portion of the conductor 242A. With such a structure, the number of steps for the semiconductor device of one embodiment of the present invention can be reduced. Thus, a method for manufacturing a semiconductor device with high productivity can be provided.

The insulator 224, the oxide semiconductor 230, the conductor 242A, and the insulator 271A are formed to at least partly overlap with the conductor 205. The insulator 222 is exposed in a region not overlapping with the insulator 224, the oxide semiconductor 230, the conductor 242A, or the insulator 271A. However, without limitation to this structure, the insulator 224 can remain over the insulator 222 in a region not overlapping with the oxide semiconductor 230. In this case, the insulator 224 has a shape in which an opening is partly formed as in the transistor 200 in FIGS. 4A to 4D, instead of having an island shape.

As illustrated in FIGS. 10B to 10D, the side surfaces of the insulator 224, the oxide semiconductor 230, the conductor 242A, and the insulator 271A may be tapered. The taper angle of the side surfaces of the insulator 224, the oxide semiconductor 230, the conductor 242A, and the insulator 271A may be, for example, greater than or equal to 60° and less than 90°. With such tapered side surfaces, the coverage with the insulator 275 and the like can be improved in a later step, so that the number of defects such as voids can be reduced.

Without limitation to the above, the insulator 224, the oxide semiconductor 230, the conductor 242A, and the insulator 271A may have side surfaces that are perpendicular or substantially perpendicular to the top surface of the insulator 222. This structure enables a plurality of transistors to be provided in a small area at high density.

In a lithography method, first, a resist is exposed to light through a mask. Next, a region exposed to light is removed or left using a developing solution, so that a resist mask is formed. Then, etching is conducted with the resist mask, whereby a conductor, a semiconductor, an insulator, or the like can be processed into a desired shape. For example, the resist mask can be formed by exposing the resist to KrF excimer laser light, ArF excimer laser light, or extreme ultraviolet (EUV) light, for example. A liquid immersion technique may be employed in which a portion between a substrate and a projection lens is filled with a liquid (e.g., water) to perform light exposure. An electron beam or an ion beam may be used instead of the above-mentioned light. Note that a photomask may be unnecessary in the case of using an electron beam or an ion beam.

To remove the resist mask which is no longer needed after the processing, dry etching treatment such as ashing using oxygen plasma (hereinafter referred to as oxygen plasma treatment in some cases) or wet etching treatment may be performed. Alternatively, wet etching treatment may be performed after dry etching treatment, or dry etching treatment may be performed after wet etching treatment.

A hard mask formed of an insulator or a conductor may be used under the resist mask. In the case of using a hard mask, a hard mask with a desired shape can be formed in the following manner: an insulating film or a conductive film that is the material of the hard mask is formed over the insulating film 271f, a resist mask is formed thereover, and then the hard mask material is etched. For example, tungsten may be used as the hard mask material. The etching of the insulating film 271f and the like may be performed after or without removal of the resist mask. In the latter case, the resist mask sometimes disappears during the etching. The hard mask may be removed by etching after the etching of the oxide semiconductor film 230f and the like. The hard mask does not need to be removed when the hard mask material does not affect the following process or can be utilized in the following process.

A spin on carbon (SOC) film and a spin on glass (SOG) film may be formed between an object to be processed and the resist mask. Using the SOC film and the SOG film as masks can improve the adhesion between the object to be processed and the resist mask and the durability of a mask pattern. For example, the SOC film, the SOG film, and the resist mask are formed in this order over the object to be processed and lithography can be performed.

An etching gas containing halogen can be used as a dry etching gas; specifically, an etching gas containing one or more of fluorine, chlorine, and bromine can be used. For example, as the etching gas, a C₄F₆ gas, a C₅F₆ gas, a C₄F₈ gas, a CF₄ gas, a SF₆ gas, a CHF₃ gas, a CH₂F₂ gas, a Cl₂ gas, a BCl₃ gas, a SiCl₄ gas, a BBr₃ gas, or the like can be used alone or in combination. To the above etching gas, an oxygen gas, a carbon dioxide gas, a nitrogen gas, a helium gas, an argon gas, a hydrogen gas, a hydrocarbon gas, or the like can be added as appropriate. Depending on an object to be subjected to the dry etching, a gas that contains a hydrocarbon gas or a hydrogen gas and does not contain a halogen gas can be used as the etching gas. As the hydrocarbon used for the etching gas, one or more of methane (CH₄), ethane (C₂H₆), propane (C₃H₈), butane (C₄H₁₀), ethylene (C₂H₄), propylene (C₃H₆), acetylene (C₂H₂), and propyne (C₃H₄) can be used. The etching conditions can be set as appropriate depending on an object to be etched.

As a dry etching apparatus, a capacitively coupled plasma (CCP) etching apparatus including parallel plate electrodes can be used. The capacitively coupled plasma etching apparatus including parallel plate electrodes may have a structure where a high-frequency voltage is applied to one of the parallel plate electrodes. Alternatively, high-frequency voltages with the same frequency may be applied to the parallel plate electrodes. Further alternatively, high-frequency voltages with different frequencies may be applied to the parallel plate electrodes. Such a CCP etching apparatus is referred to as a dual frequency capacitively coupled plasma (DF-CCP) etching apparatus. In the DF-CCP etching apparatus, high-frequency voltages with different frequencies are applied to the parallel plate electrodes. Alternatively, different high-frequency voltages may be applied to one of the parallel plate electrodes. A dry etching apparatus including a high-density plasma source can be used. As the dry etching apparatus including a high-density plasma source, an inductively coupled plasma (ICP) etching apparatus can be used, for example. The etching apparatus can be set as appropriate depending on an object to be etched. Note that in the above dry etching apparatus, a high-frequency voltage is applied to the electrode on the substrate side to generate a self-bias potential, whereby reactive ion etching can be performed. In reactive ion etching, ion species in plasma are accelerated to collide with an object to be processed, whereby etching with high anisotropy can be performed.

In the above etching step, the insulator 271A can function as an etching stopper that protects the conductor 242A. For example, when a metal hard mask is formed over the insulator 271A in the above etching step, it is sometimes difficult to obtain the etching selectivity of the hard mask to the conductor 242A at the time of removing the hard mask. However, when the insulator 271A is formed over the conductor 242A, the insulator 271A can function as an etching stopper that protects the conductor 242A in the etching for removing the hard mask. This can prevent formation of a curved surface between the side surface and the top surface of the conductor 242A, and thus the end portion at the intersection of the side surface and the top surface of each of the conductors 242a and 242b to be formed later is angular as illustrated in FIG. 1D. The cross-sectional area of the conductor 242A is larger in the case where the end portion at the intersection of the side surface and the top surface of the conductor 242A is angular than in the case where the end portion is rounded. Furthermore, when a nitride insulator that is less likely to oxidize metal is used for the insulator 271A, excessive oxidation of the conductor 242A can be prevented. Thus, the resistance of the conductors 242a and 242b is reduced, so that the on-state current of the transistor can be increased.

By processing the insulator 224 into an island shape, the insulator 275 can be provided in contact with the side surface of the insulator 224 and the top surface of the insulator 222 in a step to be described later. That is, the insulator 224 can be isolated from the insulator 280 by the insulator 275. Such a structure can prevent an excess amount oxygen and impurities such as hydrogen from entering the oxide semiconductor 230 from the insulator 280 through the insulator 224.

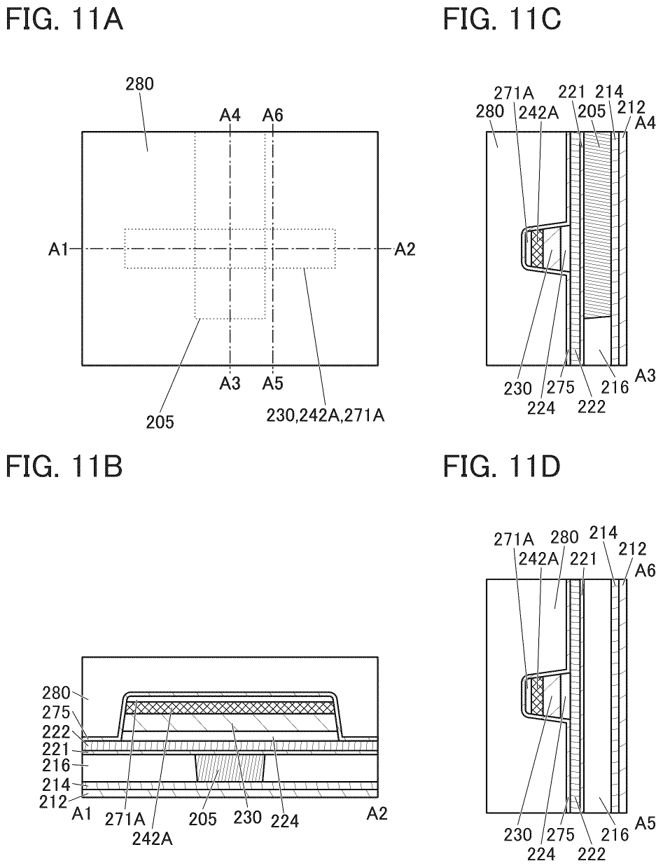

Next, the insulator 275 is formed to cover the insulator 224, the oxide semiconductor 230, the conductor 242A, and the insulator 271A, and the insulator 280 is formed over the insulator 275 (see FIGS. 11A to 11D). The above-described insulating materials can be used for the insulators 275 and 280.

Here, the insulator 275 is preferably in contact with the top surface of the insulator 222.

As the insulator 280, an insulator having a flat top surface is preferably formed in the following manner: an insulating film to be the insulator 280 is formed and then the insulating film is subjected to CMP treatment. Note that a silicon nitride film may be formed over the insulator 280 by a sputtering method, for example, and then subjected to CMP treatment until the insulator 280 is exposed.

Each of the insulators 275 and 280 can be formed by a sputtering method, a CVD method, an MBE method, a PLD method, or an ALD method, for example.

The insulator 275 is preferably formed using an insulator having a function of inhibiting passage of oxygen. For example, a silicon nitride film is preferably formed as the insulator 275 by a PEALD method. Alternatively, as the insulator 275, aluminum oxide may be deposited by a sputtering method and silicon nitride may be deposited thereover by a PEALD method. When the insulator 275 has such a stacked-layer structure, the functions of inhibiting diffusion of oxygen and impurities such as water and hydrogen can be improved.

In this manner, the oxide semiconductor 230 and the conductor 242A can be covered with the insulator 275 having a function of inhibiting diffusion of oxygen. This can inhibit direct diffusion of oxygen from the insulator 280 and the like into the oxide semiconductor 230 and the conductor 242A in a later step.

A silicon oxide film is preferably formed as the insulator 280 by a sputtering method. When an insulating film to be the insulator 280 is formed by a sputtering method in an oxygen-containing atmosphere, the insulator 280 containing excess oxygen can be formed. By using a sputtering method that does not need to use a molecule containing hydrogen as a film formation gas, the hydrogen concentration in the insulator 280 can be reduced. Note that heat treatment may be performed before the formation of the insulating film. The heat treatment may be performed under a reduced pressure, and the insulating film may be successively formed without exposure to the air. Such treatment can remove moisture and hydrogen adsorbed on the surface of the insulator 275 and the like. The heat treatment can be performed under the above-described heat treatment conditions.

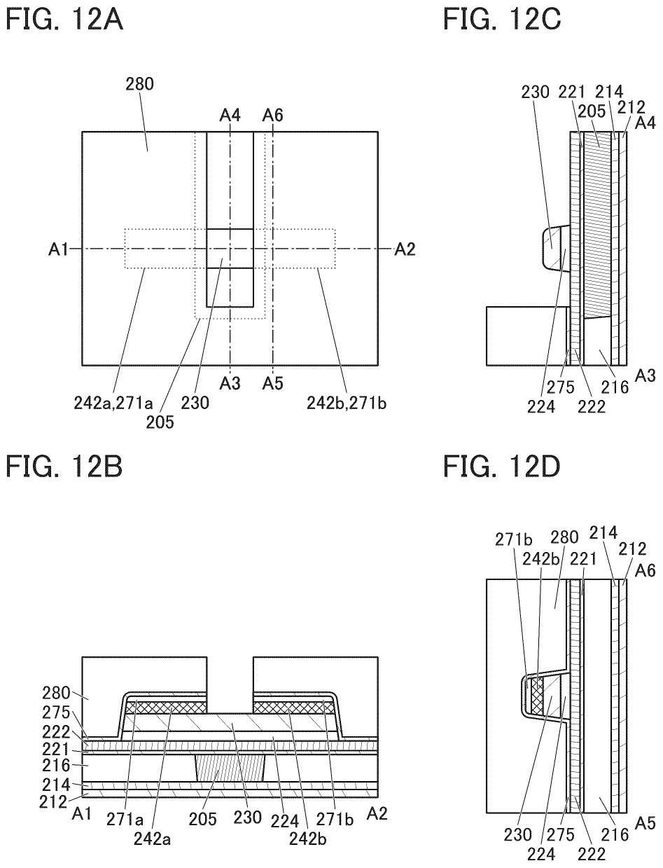

Next, the conductor 242A, the insulator 271A, the insulator 275, and the insulator 280 are processed by a lithography method, thereby forming an opening reaching the oxide semiconductor 230 and the insulator 222 (see FIGS. 12A to 12D). Here, the conductor 242A is divided into the conductors 242a and 242b, and the insulator 271A is divided into the insulators 271a and 271b. The opening formed in the insulator 280 and the insulator 275 overlaps with the oxide semiconductor 230 and the conductor 205.

The above-described method can be used as appropriate as the lithography method. In order to process the opening in the insulator 280 finely, an electron beam or short-wavelength light such as EUV light is preferably used in the lithography method. For example, the opening is formed in the insulator 280 and the conductors 242a and 242b are formed by a method illustrated in FIGS. 13A1 to 13D2.

First, a coating film 277 is formed over the insulator 280, and a coating film 278 is formed thereover (see FIGS. 13A1 and 13A2). The coating films 277 and 278 may have a function of improving adhesion between a resist mask described later and the insulator 280. The coating films 277 and 278 are formed by a spin coating method, for example. For the coating films 277 and 278, a non-photosensitive organic resin is used.

Here, the coating film 278 functions as a mask in etching treatment for processing the coating film 277. Therefore, the etching rate of the coating film 278 is preferably lower than that of the coating film 277 under the etching conditions of the coating film 277. For example, the coating film 277 is a film including carbon, and the coating film 278 is a film including silicon and carbon. In this embodiment, an SOC film is formed as the coating film 277, and an SOG film is formed as the coating film 278.

Note that the coating films 277 and 278 each contain an organic solvent such as alcohol at the time of application, but such an organic substance contained may be reduced or removed in later steps or when the semiconductor device is completed. Note that the coating films are provided as necessary; only one of the coating films may be formed or the coating films are not necessarily provided in the case where a resist mask to be described later can adequately work.

Next, a resist mask 279 having an opening is formed over the coating film 278 by a lithography method (see FIGS. 13A1 and 13A2). The resist mask 279 can be formed by exposing the resist to KrF excimer laser light, ArF excimer laser light, or extreme ultraviolet (EUV) light, for example. A liquid immersion technique may be employed in which a portion between a substrate and a projection lens is filled with a liquid (e.g., water) to perform light exposure. An electron beam or an ion beam may be used instead of the above-mentioned light. Note that a mask may be unnecessary in the case of using an electron beam or an ion beam.

In the steps of FIGS. 13B1 to 13D2, the object to be processed is preferably processed by a dry etching method. A dry etching method enables anisotropic etching and thus is suitable for forming an opening having a high aspect ratio. In the case of performing anisotropic etching, reactive ion etching is preferably performed, for example. Note that the above description can be referred to for the conditions and an apparatus for the dry etching method. Note that the steps of FIGS. 13B1 to 13D2 are preferably performed successively without exposure to the air. For example, the processing is performed without exposure to the air by using a multi-chamber etching apparatus.

First, the coating film 278 is processed using the resist mask 279, whereby the coating film 278 having an opening is formed. For example, in the case where an SOG film is used as the coating film 278, etching treatment can be performed using CF₄ as an etching gas with a DF-CCP etching apparatus.

Next, the coating film 277 is processed using the coating film 278 as a mask, thereby forming the coating film 277 having an opening (see FIGS. 13B1 and 13B2). For example, in the case where an SOC film is used as the coating film 277, etching treatment can be performed using H₂ and N₂ as etching gases with a DF-CCP etching apparatus. Here, the SOG film is used as the coating film 278, so that the coating film 278 can be prevented from disappearing in the etching step of the coating film 277.

The resist mask 279 is preferably removed during the processing of the coating film 277. Since the SOC film is used as the coating film 277, the resist mask 279 can be easily removed. In the case where the resist mask 279 remains after the formation of the coating film 277, the resist mask 279 is preferably removed.

Then, the insulator 280 is processed using the coating film 277 as a mask, whereby the insulator 280 having an opening is formed. For example, in the case where a silicon oxide film is used as the insulator 280, etching treatment can be performed using C₄F₈, C₄F₆, O₂, and Ar as etching gases with a DF-CCP etching apparatus.

Furthermore, the insulators 275 and 271A are processed using the coating film 277 as a mask, thereby forming the insulators 275, 271a, and 271b having an opening (see FIGS. 13C1 and 13C2). For example, in the case where a silicon oxide film and a silicon nitride film are used as the insulators 275 and 271A, etching treatment can be performed using CH₂F₂, O₂, and Ar as etching gases with a DF-CCP etching apparatus. At this time, the conductor 242A and the insulator 222 can function as etching stoppers. The coating film 278 is preferably removed during the processing of the insulators 275 and 271A.

After the insulators 271a and 271b are formed, dry etching treatment such as ashing using oxygen plasma is preferably performed to remove the coating film 277. However, without limitation to this step, the coating film 277 may be removed after the conductors 242a and 242b are formed.

Next, a surface oxide film of the conductor 242A is preferably removed using the insulator 280 as a mask. For example, in the case where a tantalum nitride film is used as the conductor 242A, etching treatment can be performed using BCl₃ and Cl₂ as etching gases with an ICP etching apparatus.

Furthermore, the conductor 242A is processed using the insulator 280 as a mask, thereby forming the conductors 242a and 242b (see FIGS. 13D1 and 13D2). For example, in the case where a tantalum nitride film is used as the conductor 242A, etching treatment can be performed using Cl₂ and Ar as etching gases with an ICP etching apparatus. At this time, the oxide semiconductor 230 and the insulator 222 can function as etching stoppers. Here, as illustrated in FIG. 13D2, a curved surface may be formed between the side and top surfaces of the oxide semiconductor 230 in the cross-sectional view of the transistor 200 in the channel width direction. That is, an end portion of the side surface and an end portion of the top surface are rounded in some cases.

A recess portion is sometimes formed in a portion of the oxide semiconductor 230 that is exposed from the conductors 242a and 242b. In other words, in the top surface of the oxide semiconductor 230, the level of a region sandwiched between the conductors 242a and 242b is lower than the level of a region overlapping with the conductor 242a and the level of a region overlapping with the conductor 242b in some cases.

In the above manner, the opening can be formed in the insulators 275 and 280, and the insulators 271a and 271b and the conductors 242a and 242b can be formed.

Note that ashing treatment using oxygen plasma may be performed after the processing of the conductor 242A. Such oxygen plasma treatment can remove impurities that are generated by the above etching treatment and diffused into the oxide semiconductor 230 or the like. The impurities are generated from a component of the object processed by the above etching treatment and a component contained in a gas or the like used for the etching. Examples of the impurities include chlorine, fluorine, tantalum, silicon, and hafnium. Removal of impurities attached to the oxide semiconductor 230 in this manner can improve the electrical characteristics and reliability of the transistor.

The processing of the conductor 242A and the oxygen plasma treatment can be performed successively without exposure to the air. For example, the processing is performed without exposure to the air by using a multi-chamber etching apparatus.

In order to remove the impurities attached to the surface of the oxide semiconductor 230 in the etching step, cleaning treatment is preferably performed. Examples of cleaning methods include wet cleaning using a cleaning solution or the like (which can also be referred to as wet etching treatment), plasma treatment using plasma, and cleaning by heat treatment, and any of these cleaning methods may be combined as appropriate. The cleaning treatment sometimes makes the recess portion deeper.

The wet cleaning may be performed using an aqueous solution in which one or more of oxalic acid, phosphoric acid, and hydrofluoric acid are diluted with carbonated water or pure water. The wet cleaning may be performed using an aqueous solution in which ammonia water is diluted with carbonated water or pure water. The wet cleaning may be performed using pure water, carbonated water, or the like. Alternatively, ultrasonic cleaning using such an aqueous solution, pure water, or carbonated water may be performed. Further alternatively, any of these cleaning methods may be combined as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is preferably higher than or equal to 0.01% and lower than or equal to 5%, further preferably higher than or equal to 0.1% and lower than or equal to 0.5%. The concentration of hydrogen fluoride in the diluted hydrofluoric acid is preferably higher than or equal to 0.01 ppm and lower than or equal to 100 ppm, further preferably higher than or equal to 0.1 ppm and lower than or equal to 10 ppm.

A frequency greater than or equal to 200 kHz is preferably used for the ultrasonic cleaning, and a frequency greater than or equal to 900 kHz is further preferably used. Damage to the oxide semiconductor 230 and the like can be reduced with such a frequency.

The cleaning treatment may be performed a plurality of times, and the cleaning solution may be changed in every cleaning treatment. For example, first cleaning treatment may use diluted hydrofluoric acid or diluted ammonia water, and second cleaning treatment may use pure water or carbonated water.

As the cleaning treatment in this embodiment, wet cleaning is performed with the use of carbonated water. The cleaning treatment allows removal of impurities that are attached onto the surfaces of the oxide semiconductor 230 and the like or diffused into the oxide semiconductor 230 and the like. Furthermore, the surface layer of the oxide semiconductor 230 that has been damaged by the above etching treatment can be removed.

After the etching or the cleaning, heat treatment is preferably performed. The heat treatment temperature is higher than or equal to 100° C. and lower than or equal to 650° C., preferably higher than or equal to 250° C. and lower than or equal to 600° C., further preferably higher than or equal to 300° C. and lower than or equal to 550° C., still further preferably higher than or equal to 350° C. and lower than or equal to 400° C. Note that the heat treatment is performed in a nitrogen gas atmosphere, an inert gas atmosphere, or an atmosphere containing an oxidizing gas at 10 ppm or more, 1% or more, or 10% or more. The heat treatment is preferably performed in an oxygen-containing atmosphere. For example, it is preferable that the flow rate ratio of a nitrogen gas to an oxygen gas be 4:1 and the heat treatment be performed at 350° C. for one hour. Accordingly, oxygen can be supplied to the oxide semiconductor 230 to reduce oxygen vacancies. In addition, the crystallinity of the oxide semiconductor 230 can be improved by the heat treatment. Furthermore, hydrogen remaining in the oxide semiconductor 230 reacts with supplied oxygen, so that the hydrogen can be removed as H₂O (dehydration). This can inhibit recombination of hydrogen remaining in the oxide semiconductor 230 with oxygen vacancies and formation of V_{O}H. Accordingly, a transistor including the oxide semiconductor 230 can have favorable electrical characteristics and high reliability. In addition, variations in electrical characteristics of transistors formed over the same substrate can be reduced. The heat treatment may be performed under a reduced pressure. Alternatively, the heat treatment may be performed as follows: heat treatment is performed in an oxygen atmosphere, and then another heat treatment is successively performed in a nitrogen atmosphere without exposure to the air. The heat treatment can also serve as the heat treatment performed after the formation of the oxide semiconductor film 230f. Thus, the crystal region of the oxide semiconductor 230 grows through the heat treatment in some cases.

In the case where heat treatment is performed in a state where the oxide semiconductor 230 is in contact with the conductors 242a and 242b, the sheet resistance sometimes decreases in the oxide semiconductor 230 in a region overlapping with the conductor 242a and a region overlapping with the conductor 242b. In addition, the carrier concentration may increase in these regions. Thus, in the oxide semiconductor 230, the resistance in the regions overlapping with the conductors 242a and 242b can be lowered in a self-aligned manner.

For example, even when the oxide semiconductor 230 has a stacked-layer structure as illustrated in FIG. 2A and the oxide semiconductor 230c is a metal oxide with relatively low conductivity or a metal oxide with a wide band gap, the resistance of the oxide semiconductor 230 in the regions overlapping with the conductors 242a and 242b can be lowered as described above. Thus, the source region and the drain region can be formed in the oxide semiconductor 230c.

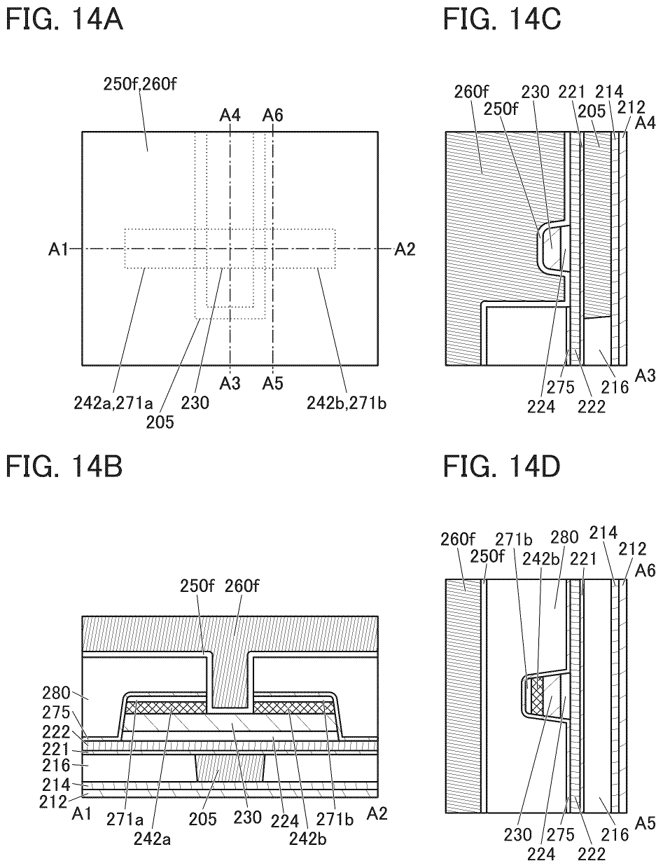

Next, an insulating film 250f to be the insulator 250 is formed to cover the opening formed in the insulator 280 and the like (see FIGS. 14A to 14D). Here, the insulating film 250f is formed along the opening in the insulators 280 and 275. The insulating film 250f is in contact with the insulator 280, the conductors 242a and 242b, the insulators 222 and 224, and the oxide semiconductor 230.

The insulating film 250f can be formed by a sputtering method, a CVD method, an MBE method, a PLD method, or an ALD method. For example, the insulating film 250f is preferably formed by an ALD method. The insulating film 250f is preferably formed to have a small thickness, and a variation in the thickness needs to be reduced. In an ALD method, a precursor and a reactant (such as an oxidizer) are alternately introduced to form a film, and the film thickness can be adjusted depending on the number of repetition times of the sequence of the introduction; thus, accurate control of the film thickness is possible. The insulating film 250f needs to be formed to favorably cover the bottom and side surfaces of the opening. An ALD method enables an atomic layer to be deposited one by one on the bottom and side surfaces of the opening, whereby the insulating film 250f can be formed in the opening with good coverage.

When the insulating film 250f is formed by an ALD method, ozone (O₃), oxygen (O₂), water (H₂O), or the like is used as the oxidizer. When an oxidizer without hydrogen, such as ozone (O₃) or oxygen (O₂), is used, the amount of hydrogen diffusing into the oxide semiconductor 230 can be reduced.

The insulator 250 can have a stacked-layer structure as illustrated in FIG. 2B and the like. A method for forming the insulating film 250f in the case where the insulator 250 has a four-layer structure of the insulators 250a, 250b, 250d, and 250c as in FIG. 2B will be described below.

First, a film to be the insulator 250a is formed to cover the opening formed in the insulator 280 and the like, and then a film to be the insulator 250b is formed over the film to be the insulator 250a. In this embodiment, an aluminum oxide film is formed by a thermal ALD method as the film to be the insulator 250a, and a silicon oxide film is formed by a PEALD method as the film to be the insulator 250b.

Next, microwave treatment is preferably performed in an oxygen-containing atmosphere. Here, the microwave treatment refers to, for example, treatment using an apparatus including a power source for generating high-density plasma using microwaves. In this specification and the like, a microwave refers to an electromagnetic wave having a frequency greater than or equal to 300 MHz and less than or equal to 300 GHz.

The microwave treatment is preferably performed with a microwave treatment apparatus including a power source for generating high-density plasma using microwaves, for example. Here, the frequency of the microwave treatment apparatus is preferably higher than or equal to 300 MHz and lower than or equal to 300 GHz, further preferably higher than or equal to 2.4 GHz and lower than or equal to 2.5 GHz, and can be 2.45 GHz, for example. High-density oxygen radicals can be generated with high-density plasma. The electric power of the power source that applies microwaves of the microwave treatment apparatus is preferably higher than or equal to 1000 W and lower than or equal to 10000 W, further preferably higher than or equal to 2000 W and lower than or equal to 5000 W. The microwave treatment apparatus may be provided with a power source that applies RF to the substrate side. Application of RF to the substrate side allows oxygen ions generated by high-density plasma to be introduced into the oxide semiconductor 230 efficiently.

The microwave treatment is preferably performed under a reduced pressure, and the pressure is preferably higher than or equal to 10 Pa and lower than or equal to 1000 Pa, further preferably higher than or equal to 300 Pa and lower than or equal to 700 Pa. The treatment temperature is preferably lower than or equal to 750° C., further preferably lower than or equal to 500° C., and can be approximately 250° C., for example. The oxygen plasma treatment may be followed successively by heat treatment without exposure to the air. The heat treatment temperature is preferably higher than or equal to 100° C. and lower than or equal to 750° C., further preferably higher than or equal to 300° C. and lower than or equal to 500° C., for example.

The microwave treatment can be performed using an oxygen gas and an argon gas, for example. Here, the oxygen flow rate ratio (O₂/(O₂+Ar)) is higher than 0% and lower than or equal to 100%. The oxygen flow rate ratio (O₂/(O₂+Ar)) is preferably higher than 0% and lower than or equal to 50%. The oxygen flow rate ratio (O₂/(O₂+Ar)) is further preferably higher than or equal to 10% and lower than or equal to 40%. The oxygen flow rate ratio (O₂/(O₂+Ar)) is still further preferably higher than or equal to 10% and lower than or equal to 30%. The carrier concentration of the region of the oxide semiconductor 230 exposed in the opening can be reduced by thus performing the microwave treatment in an oxygen-containing atmosphere. Preventing introduction of an excess amount of oxygen into the chamber in the microwave treatment can prevent an excessive reduction in the carrier concentration of the oxide semiconductor 230.

The microwave treatment in an oxygen-containing atmosphere converts an oxygen gas into plasma using a high-frequency wave such as a microwave or an RF and applies the oxygen plasma to a region of the oxide semiconductor 230 that is between the conductors 242a and 242b. By the effects of plasma, a microwave, and the like, V_{O}H in the region can be divided into oxygen vacancies and hydrogen, and hydrogen can be removed from the region. Here, in the case of employing the structure illustrated in FIG. 2B and the like, the film to be the insulator 250a is preferably an insulating film having a function of capturing or fixing hydrogen (e.g., aluminum oxide). With such a structure, hydrogen generated by the microwave treatment can be captured or fixed in the film to be the insulator 250a. In this manner, the amount of V_{O}H contained in the channel formation region can be reduced. As a result, oxygen vacancies and V_{O}H in the channel formation region can be reduced to lower the carrier concentration. In addition, oxygen radicals generated by the oxygen plasma can be supplied to oxygen vacancies formed in the channel formation region, thereby further reducing oxygen vacancies and lowering the carrier concentration in the channel formation region.

Oxygen implanted into the channel formation region has a variety of forms such as an oxygen atom, an oxygen molecule, an oxygen ion, and an oxygen radical (also referred to as an O radical, which is an atom, a molecule, or an ion having an unpaired electron). The oxygen implanted into the channel formation region preferably has one or more of the above forms. An oxygen radical is particularly preferable. In addition, the insulator 250 can have a higher film quality, which increases the reliability of the transistor.

Meanwhile, the oxide semiconductor 230 includes a region overlapping with the conductor 242a or 242b. The region can function as a source region or a drain region. Here, the conductors 242a and 242b preferably function as blocking films preventing the effect of the high-frequency wave such as the microwave or RF, the oxygen plasma, or the like in the microwave treatment in an oxygen-containing atmosphere. Thus, the conductors 242a and 242b preferably have a function of blocking an electromagnetic wave greater than or equal to 300 MHz and less than or equal to 300 GHz, for example, greater than or equal to 2.4 GHz and less than or equal to 2.5 GHz.

Since the conductors 242a and 242b prevent the effect of the high-frequency wave such as the microwave or RF, the oxygen plasma, or the like, the effect does not reach the region of the oxide semiconductor 230 that overlaps with the conductor 242a or 242b. Hence, a reduction in V_{O}H and supply of an excess amount of oxygen due to the microwave treatment do not occur in the source and drain regions, preventing a decrease in carrier concentration.

In the above manner, oxygen vacancies and V_{O}H can be selectively removed from the channel formation region in the oxide semiconductor, whereby the channel formation region can be an i-type or substantially i-type region. Furthermore, supply of an excess amount of oxygen to the regions functioning as the source region and the drain region can be inhibited, and the conductivity before the microwave treatment (the state of the low-resistance regions) can be maintained. As a result, a change in the electrical characteristics of the transistor can be inhibited; thus, variations in electrical characteristics of the transistors in the substrate plane can be inhibited.

The microwave treatment improves the quality of the films to be insulators 250a and 250b, thereby inhibiting diffusion of hydrogen, water, impurities, and the like. Accordingly, hydrogen, water, impurities, and the like can be inhibited from diffusing into the oxide semiconductor 230 and the like through the insulator 250 in the following step such as formation of a conductive film to be the conductor 260 or the following treatment such as heat treatment. By thus improving the film quality of the insulator 250, the reliability of the transistor can be improved.

Next, a film to be the insulator 250d is formed over the film to be the insulator 250b. In this embodiment, a hafnium oxide film is formed by a thermal ALD method as the film to be the insulator 250d. Alternatively, a hafnium zirconium oxide film can be formed by a thermal ALD method as the film to be the insulator 250d. After the film to be the insulator 250d is formed, microwave treatment may be performed again.

Subsequently, a film to be the insulator 250c is formed over the film to be the insulator 250d. In this embodiment, a silicon nitride film is formed by a PEALD method as the film to be the insulator 250c. In this manner, the insulating film 250f including the films to be the insulators 250a to 250d can be formed.

Although an example in which microwave treatment is performed after the formation of the film to the insulator 250b and the formation of the film to be the insulator 250d is described above, the present invention is not limited to the example. The microwave treatment can be performed after the formation of the film to be the insulator 250c. Alternatively, the microwave treatment can be performed before the formation of the film to be the insulator 250a. Alternatively, microwave treatment may be performed three or more times. In some cases, the microwave treatment can also serve as the heat treatment that will be described in Embodiment 2. Thus, the crystal region of the oxide semiconductor 230 grows through the microwave treatment in some cases.

After the microwave treatment, heat treatment may be performed with the reduced pressure being maintained. Such treatment enables hydrogen in the insulating film and the oxide semiconductor 230 to be removed efficiently. Alternatively, the step of performing microwave treatment and then performing heat treatment with the reduced pressure being maintained may be repeated a plurality of cycles. The repetition of the heat treatment enables hydrogen in the insulating film and the oxide semiconductor 230 to be removed more efficiently. Note that the heat treatment temperature is preferably higher than or equal to 300° C. and lower than or equal to 500° C. The heat treatment can also serve as the heat treatment that will be described in Embodiment 2. Thus, the crystal region of the oxide semiconductor 230 grows through the heat treatment in some cases.

Next, a conductive film 260f to be the conductor 260 is formed (see FIGS. 14A to 14D). The conductive film 260f can be formed using any of the above conductive materials by a sputtering method, a CVD method, an MBE method, a PLD method, a plating method, or an ALD method. For example, a titanium nitride film and a tungsten film are stacked by a CVD method. As illustrated in FIG. 2A, the conductor 260 can have a stacked-layer structure of the conductor 260a of titanium nitride and the conductor 260b of tungsten. Note that the conductive film 260f may be formed while the substrate is being heated. The substrate heating can also serve as the heat treatment that will be described in Embodiment 2. Thus, the crystal region of the oxide semiconductor 230 grows through the substrate heating in some cases.

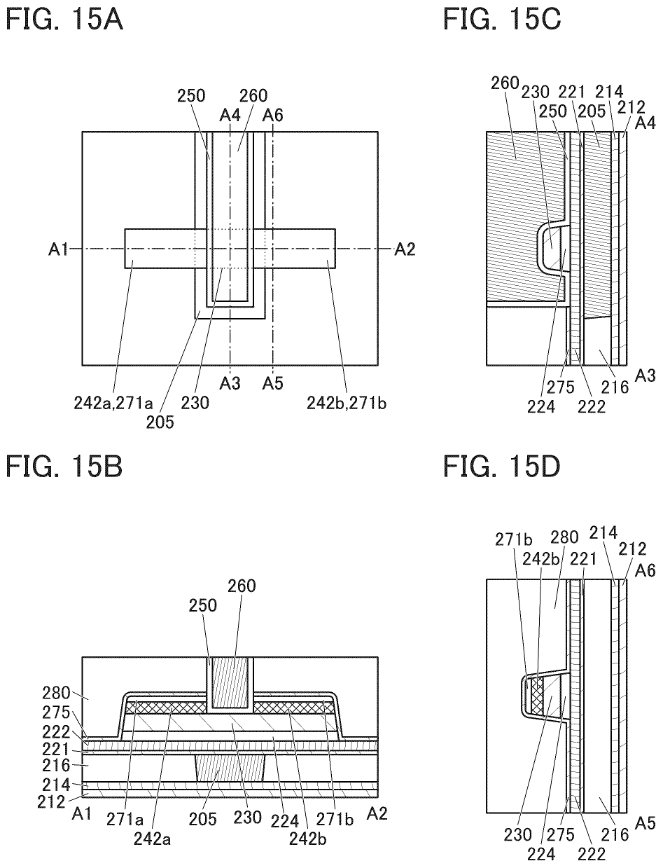

Then, the insulating film 250f and the conductive film 260f are polished by CMP treatment until the insulator 280 is exposed. That is, portions of the insulating film 250f and the conductive film 260f exposed from the opening are removed. Thus, the insulator 250 and the conductor 260 (the conductors 260a and 260b) are formed in the opening overlapping with the conductor 205 (see FIGS. 15A to 15D).

Accordingly, the insulator 250 is in contact with the conductors 242a and 242b, the oxide semiconductor 230, and the insulators 224 and 222 in the opening. The conductor 260 is provided to fill the opening with the insulator 250 therebetween. In this manner, the transistor 200 is formed.

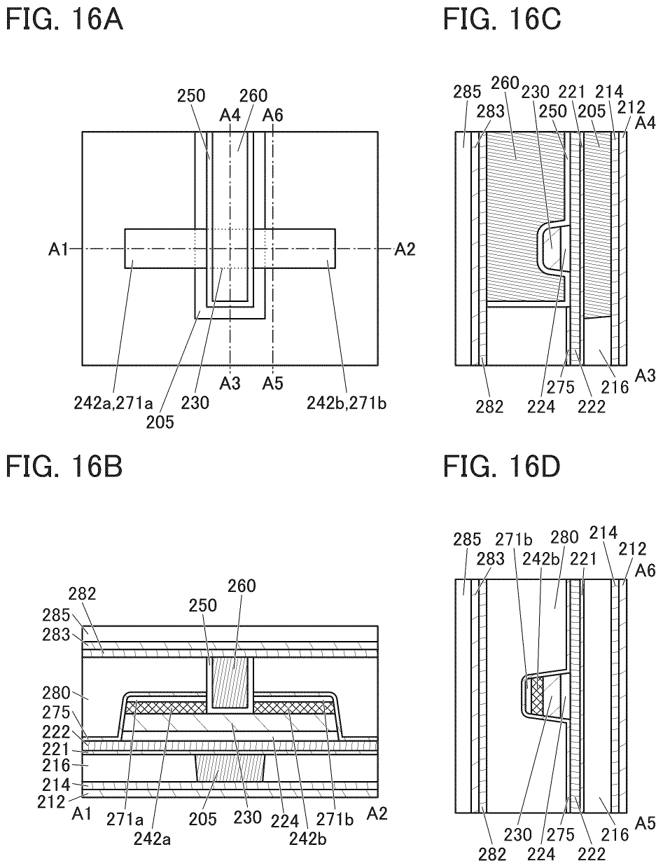

Next, the insulator 282 is formed over the insulator 250, the conductor 260, and the insulator 280 (see FIGS. 16A to 16D). The insulator 282 can be formed by a sputtering method, a CVD method, an MBE method, a PLD method, or an ALD method, for example. The insulator 282 is preferably formed by a sputtering method. Since a molecule containing hydrogen is not used as a film formation gas in a sputtering method, the concentration of hydrogen in the insulator 282 can be reduced.

As illustrated in FIG. 2A, the insulator 282 preferably has a stacked-layer structure of the insulators 282a and 282b. Here, the insulator 282a is preferably formed by an ALD method, and the insulator 282b is preferably formed by a sputtering method.

In this embodiment, an aluminum oxide film is formed as the insulator 282a by a thermal ALD method. Here, the thickness of the insulator 282a is greater than or equal to 1 nm and less than or equal to 20 nm, preferably greater than or equal to 3 nm and less than or equal to 10 nm.

When the insulator 282a is formed by an ALD method, the insulator 282a can be formed without excessive damage to the formation surface. This can prevent excessive damage to the upper end portion of the insulator 250 and the top surface of the conductor 260, improving the electrical characteristics and reliability of the transistor 200.

When the insulator 282a is formed by an ALD method, the insulator 282a can be formed without adding oxygen to the insulator 280. In this manner, addition of an excess amount of oxygen to the insulator 280 can be prevented. Thus, the electrical characteristics and reliability of the transistor 200 can be improved.

In this embodiment, an aluminum oxide film is formed as the insulator 282b by a sputtering method. Since a molecule containing hydrogen is not used as a film formation gas in a sputtering method, the concentration of hydrogen in the insulator 282 can be reduced.

Forming the insulator 282b in an oxygen-containing atmosphere by a sputtering method can add oxygen to the insulator 280 during the formation. Thus, excess oxygen can be contained in the insulator 280. The formation of the insulator 282b is preferably performed while the substrate is heated. Here, when the insulator 282b is formed over the insulator 282a, oxygen is added through the insulator 282a; hence, the amount of oxygen supplied into the insulator 280 can be controlled. With a larger thickness of the insulator 282a, the addition of oxygen is more likely to be inhibited, and the amount of oxygen supplied into the insulator 280 decreases. With a smaller thickness of the insulator 282a, the addition of oxygen is less likely to be inhibited, and the amount of oxygen supplied into the insulator 280 increases. For example, when the thickness of the insulator 282a is within the above range, an adequate amount of oxygen can be supplied to the oxide semiconductor 230, and an excessive amount of oxygen can be prevented from being supplied to the oxide semiconductor 230. Thus, the reliability and electrical characteristics of the transistor 200 can be improved. Note that in forming the insulator 282b, oxygen can be added not only to the insulator 280 but also to the upper end portion of the insulator 250.

When the insulator 282b is formed over the insulator 282a, the upper end portion of the insulator 250 and the top surface of the conductor 260 can be protected from an impact of ion collision caused by formation of the insulator 282b by sputtering.

The aluminum oxide film is formed using an aluminum target in an atmosphere containing an oxygen gas. The amount of oxygen implanted into the insulator 280 can be controlled depending on the amount of a bias power applied to the substrate in a sputtering method. For example, the amount of oxygen supplied into the insulator 280 is smaller as the bias power is lower, and the amount of oxygen is easily saturated even when the insulator 282b has a small thickness. Furthermore, as the bias power becomes higher, the amount of oxygen implanted into the insulator 280 increases. With lower bias power, the amount of oxygen implanted into the insulator 280 can be reduced. Note that in the case where the substrate bias is applied by an RF power source, the RF frequency is preferably higher than or equal to 10 MHz. The typical frequency is 13.56 MHz. The higher the RF frequency is, the less damage to the substrate can be.

Heat treatment may be performed before the formation of the insulator 282b. The heat treatment may be performed under a reduced pressure, and the insulator 282b may be successively formed without exposure to the air. Such treatment enables moisture and hydrogen adsorbed on the surface of the insulator 280 to be captured or fixed by the insulator 282a, so that the moisture concentration and the hydrogen concentration in the insulator 280 can be reduced. The heat treatment temperature is preferably higher than or equal to 100° C. and lower than or equal to 400° C. In this embodiment, the heat treatment temperature is 250° C.

Next, the insulator 283 is formed over the insulator 282 (see FIGS. 16A to 16D). The insulator 283 can be formed by a sputtering method, a CVD method, an MBE method, a PLD method, or an ALD method. The insulator 283 is preferably formed by a sputtering method. By using a sputtering method that does not need to use a molecule containing hydrogen as a film formation gas, the hydrogen concentration in the insulator 283 can be reduced. In this embodiment, a silicon nitride film is formed as the insulator 283 by a sputtering method.

In this embodiment, a silicon nitride film is formed as the insulator 283 by a sputtering method, and an aluminum oxide film is formed as the insulator 282 by a thermal ALD method and a sputtering method. The use of silicon nitride having a function of inhibiting diffusion of hydrogen for the insulator 283 can inhibit diffusion of hydrogen from a layer above the transistor 200. Furthermore, the use of aluminum oxide having a function of capturing or fixing hydrogen for the insulator 282 enables hydrogen contained in the insulator 280 or the like to be captured or fixed by the insulator 282. Thus, the hydrogen concentration in the oxide semiconductor 230 and in the vicinity thereof can be reduced.

Next, the insulator 285 is formed over the insulator 283 (see FIGS. 16A to 16D). The insulator 285 can be formed by a sputtering method, a CVD method, an MBE method, a PLD method, or an ALD method. The insulator 285 is preferably formed by a sputtering method. Since a molecule containing hydrogen is not used for a film formation gas in a sputtering method, the concentration of hydrogen in the insulator 285 can be reduced. In this embodiment, a silicon oxide film is formed as the insulator 285 by a sputtering method.

Here, it is preferable to form the insulators 282, 283, and 285 successively by a sputtering method without exposure to the air. Film formation without exposure to the air can prevent attachment of impurities or moisture from the air onto the insulators 282, 283, and 285, so that the interface between the insulators 282 and 283, the interface between the insulators 283 and 285, and the vicinities of the interfaces can be kept clean.

Then, an opening reaching the conductor 242a is formed in the insulators 271a, 275, 280, 282, 283, and 285, and an opening reaching the conductor 242b is formed in the insulators 271b, 275, 280, 282, 283, and 285. The openings are formed by a lithography method. To form the openings, the above insulators are preferably processed by a dry etching method. A dry etching method makes anisotropic etching possible and thus is suitable for forming an opening having a high aspect ratio. In the case of performing anisotropic etching, reactive ion etching is preferably performed, for example. Note that the above description can be referred to for the conditions and an apparatus for the dry etching method. Note that the shape of the openings in the top view can be a circular shape, an almost circular shape such as an elliptical shape, a polygonal shape such as a quadrangular shape, or a polygonal shape such as a quadrangular shape with rounded corners, for example.

Subsequently, heat treatment is performed after the formation of the openings. The heat treatment temperature is higher than or equal to 100° C. and lower than or equal to 600° C., preferably higher than or equal to 250° C. and lower than or equal to 550° C., further preferably higher than or equal to 350° C. and lower than or equal to 450° C. Note that the heat treatment is preferably performed in a nitrogen gas or inert gas atmosphere. The heat treatment is performed in a state where the conductors 242a and 242b are exposed; thus, the heat treatment is preferably performed in an atmosphere not containing an oxidizing gas or an oxygen gas. For example, heat treatment is preferably performed at 400° C. in a nitrogen gas atmosphere for one hour. The heat treatment may be performed under a reduced pressure. By the heat treatment, oxygen contained in the insulator 280 can be supplied to the oxide semiconductor 230 through the insulator 250. Thus, oxygen vacancies in the channel formation region of the oxide semiconductor 230 can be reduced. The heat treatment can also serve as the heat treatment that will be described in Embodiment 2. Accordingly, the crystal region of the oxide semiconductor 230 grows through the heat treatment in some cases.

Here, the side surface of the insulator 280 is exposed in the opening; hence, oxygen contained in the insulator 280 is diffused outwardly by the heat treatment, so that the amount of oxygen contained in the insulator 280 can be controlled. Meanwhile, since the insulators 282 and 283 each having a barrier property against oxygen are provided over the insulator 280, oxygen is not diffused outwardly from the top surface of the insulator 280. Accordingly, oxygen can be prevented from being excessively diffused outwardly from the insulator 280 and thus, oxygen vacancies can be prevented from being formed in the insulator 280. The oxide semiconductor 230 and the conductors 242a and 242b are covered with the insulator 275. This can prevent direct diffusion of an excess amount of oxygen from the insulator 280 to the oxide semiconductor 230 and the conductors 242a and 242b in the above heat treatment.

As described above, in the formation of the insulator 282b, oxygen is added to the insulator 280 through the insulator 282a, whereby the amount of oxygen added to the insulator 280 can be controlled. Furthermore, oxygen is diffused outwardly from the side surface of the insulator 280 by the heat treatment, whereby the amount of oxygen in the insulator 280 can be appropriate. In this manner, oxygen is supplied to the oxide semiconductor 230 from the insulator 280 having an adjusted amount of oxygen, whereby an appropriate amount of oxygen can be supplied to the oxide semiconductor 230. Accordingly, oxygen vacancies in the oxide semiconductor 230 can be reduced, and an excess amount of oxygen can be prevented from being supplied to the oxide semiconductor 230. Thus, the electrical characteristics and reliability of the transistor 200 can be improved. Furthermore, a step of exposing the side surface of the insulator 280 can also serve as a step of forming openings in which the conductor 240a and the conductor 240b are embedded; thus, the manufacturing process of the semiconductor device can be simplified.

By the heat treatment, hydrogen contained in the insulators 280 and 250 and the oxide semiconductor 230 moves to the insulator 282 and is captured in the insulator 282. In other words, hydrogen contained in the insulators 280 and 250 and the oxide semiconductor 230 diffuses into the insulator 282. Accordingly, the hydrogen concentration in the insulator 282 increases, whereas the hydrogen concentrations in the insulators 280 and 250 and the oxide semiconductor 230 decrease. Note that the insulator 283 is provided in contact with the top surface of the insulator 282, which can prevent entry of impurities such as moisture or hydrogen from a component above the insulator 283 in the heat treatment. By the heat treatment, hydrogen contained in the insulators 216 and 224 and the oxide semiconductor 230 moves to the insulator 222 and is captured in the insulator 222. In other words, hydrogen contained in the insulators 216 and 224 and the oxide semiconductor 230 diffuses into the insulator 222. Accordingly, the hydrogen concentration in the insulator 222 increases, whereas the hydrogen concentrations in the insulators 216 and 224 and the oxide semiconductor 230 decrease. Note that the insulator 221 is provided in contact with the bottom surface of the insulator 222, whereby entry of moisture or impurities such as hydrogen from below the insulator 221, which would be caused by the heat treatment, can be prevented.

Next, an insulating film to be the insulators 241a and 241b is formed along the shape of the openings. The insulating film can be formed by a sputtering method, a CVD method, an MBE method, a PLD method, an ALD method, or the like. The insulating film to be the insulators 241a and 241b is formed in the openings having a high aspect ratio, and thus is preferably formed by an ALD method. The insulating film to be the insulators 241a and 241b preferably has a function of inhibiting transmission of oxygen. For example, a silicon nitride film is preferably formed by a PEALD method. Silicon nitride is preferable because of its high hydrogen blocking property.

Next, the insulating film is etched anisotropically to form the insulators 241a and 241b. Here, the insulator 241a is formed to cover a sidewall of the opening over the conductor 242a, and the insulator 241b is formed to cover a sidewall of the opening over the conductor 242b. As anisotropic etching for the insulating film to be the insulators 241a and 241b, a dry etching method is performed, for example. For example, reactive ion etching is preferably performed. Providing the insulators 241a and 241b on the sidewall portions of the openings can inhibit entry of oxygen from the outside and can prevent oxidation of the conductors 240a and 240b formed in the next step. Furthermore, impurities such as water and hydrogen contained in the insulator 280 or the like can be prevented from diffusing into the conductors 240a and 240b. Note that part of each of the top surfaces of the conductors 242a and 242b may have a recess portion because of the anisotropic etching.

Subsequently, a conductive film to be the conductors 240a and 240b is formed. The conductive film desirably has a stacked-layer structure including a conductor with a function of inhibiting transmission of impurities such as water and hydrogen. For example, it is possible to employ a stacked-layer structure of tantalum nitride, titanium nitride, or the like and tungsten, molybdenum, copper, or the like. The conductive film to be the conductors 240a and 240b can be formed by a sputtering method, a CVD method, an MBE method, a PLD method, an ALD method, or the like.

Then, the conductive film to be the conductors 240a and 240b is partly removed by CMP treatment, thereby exposing the top surface of the insulator 285. As a result, the conductive film remains only in the openings, whereby the conductors 240a and 240b each having a flat top surface can be formed (see FIGS. 1A to 1D). The CMP treatment may remove part of the top surface of the insulator 285.

Heat treatment may be further performed after the formation of the conductors 240a and 240b. This heat treatment can be performed under the conditions similar to those for the above heat treatment. By the heat treatment, the amount of oxygen supplied to the oxide semiconductor 230 can be adjusted. Thus, the reliability and electrical characteristics of the transistor 200 can be improved.

Through the above steps, the semiconductor device illustrated in FIGS. 1A to 1D can be manufactured.

The semiconductor device of this embodiment includes an OS transistor. In this embodiment, an indium-containing oxide (e.g., indium oxide, indium gallium oxide, indium zinc oxide, indium gallium zinc oxide, or indium gallium tin zinc oxide) is used for an oxide semiconductor layer of the OS transistor, whereby a semiconductor device with high field-effect mobility can be provided. For example, the electrical characteristics, on-state current, S value, and frequency characteristics of the transistor can be improved. Moreover, a highly reliable semiconductor device can be provided.

This embodiment can be combined with any of the other embodiments as appropriate. In this specification, in the case where a plurality of structure examples are shown in one embodiment, the structure examples can be combined as appropriate.

### Embodiment 2

In this embodiment, an oxide semiconductor that can be used for a semiconductor layer of a transistor will be described. As the oxide semiconductor of one embodiment of the present invention, a single layer or stacked layers including a metal oxide can be used. Note that in an oxide semiconductor having a stacked-layer structure, a boundary between stacked films is sometimes difficult to recognize as described later.

### [Metal Oxide]

The metal oxide of one embodiment of the present invention preferably contains at least indium (In) or zinc (Zn), particularly preferably contains indium as its main component. The metal oxide preferably contains two or three selected from indium, an element M, and zinc, and particularly preferably contains indium and zinc as its main components. Here, the metal oxide contains indium and zinc as its main components, and can further contain the element M. The element M is a metal element or a metalloid element that has a high bonding energy with oxygen, such as a metal element or a metalloid element whose bonding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more of the above elements, further preferably one or more selected from aluminum, gallium, tin, and yttrium, still further preferably one or more selected from gallium and tin. When the element M included in the metal oxide is gallium, the metal oxide of one embodiment of the present invention preferably includes one or more selected from indium, gallium, and zinc. In this specification and the like, a metal element and a metalloid element may be collectively referred to as a “metal element”, and a “metal element” in this specification and the like may include a metalloid element.

Examples of the metal oxide of one embodiment of the present invention include indium zinc oxide (also referred to as In—Zn oxide or IZO (registered trademark)), indium tin oxide (also referred to as In—Sn oxide or ITO), indium titanium oxide (In—Ti oxide), indium gallium oxide (In—Ga oxide), indium gallium aluminum oxide (In—Ga—Al oxide), indium gallium tin oxide (also referred to as In—Ga—Sn oxide or IGTO), indium aluminum zinc oxide (also referred to as In—Al—Zn oxide or IAZO), indium tin zinc oxide (also referred to as In—Sn—Zn oxide), indium titanium zinc oxide (In—Ti—Zn oxide), indium gallium zinc oxide (also referred to as In—Ga—Zn oxide or IGZO), indium tin oxide containing silicon oxide (ITSO), indium gallium tin zinc oxide (also referred to as In—Ga—Sn—Zn oxide or IGZTO), and indium gallium aluminum zinc oxide (also referred to as In—Ga—Al—Zn oxide, IGAZO, or IAGZO). Alternatively, it is possible to use, for example, gallium zinc oxide (also referred to as Ga—Zn oxide or GZO), aluminum zinc oxide (also referred to as Al—Zn oxide or AZO), gallium tin oxide (Ga—Sn oxide), or aluminum tin oxide (Al—Sn oxide). As the metal oxide of one embodiment of the present invention, indium oxide can be used. Alternatively, as the metal oxide of one embodiment of the present invention, gallium oxide, zinc oxide, or the like can be used.

When the indium content in the metal oxide is increased, the transistor can have a high on-state current and excellent frequency characteristics.

Instead of indium, the metal oxide may contain one or more kinds of metal elements having a large period number in the periodic table. Alternatively, in addition to indium, the metal oxide may contain one or more kinds of metal elements having a large period number in the periodic table. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

A metal oxide having a high zinc content has high crystallinity, whereby diffusion of impurities in the metal oxide can be inhibited. Consequently, a change in electrical characteristics of the transistor is suppressed, and the transistor can have high reliability.

A high content of the element M in the metal oxide can inhibit formation of oxygen vacancies in the metal oxide. Accordingly, generation of carriers due to oxygen vacancies is inhibited, which makes the off-state current of the transistor low. Furthermore, changes in the electrical characteristics of the transistor can be reduced to improve the reliability of the transistor.

The description is made on a structure example of an oxide semiconductor that enables the field-effect mobility of a transistor to be increased. For example, a stacked-layer structure of indium oxide and IGZO is preferably used. Specifically, the oxide semiconductor preferably contains indium oxide and IGZO over the indium oxide. Moreover, IGZO containing nitrogen is preferably used as the oxide semiconductor. For example, IGZO containing nitrogen can be formed by performing N₂O plasma treatment during or after the deposition of IGZO. For the oxide semiconductor, at least one of indium oxide, In—Ga oxide, In—Zn oxide, and IGZTO is preferably used.

In this embodiment, In-M-Zn oxide is sometimes described as an example of the metal oxide.

The oxide semiconductor of one embodiment of the present invention preferably includes a metal oxide having crystallinity. Examples of the structure of a metal oxide having crystallinity include a c-axis-aligned crystalline (CAAC) structure, a polycrystalline structure, and a nanocrystalline (nc) structure. By using a metal oxide having crystallinity for the oxide semiconductor, the density of defect states in the oxide semiconductor can be reduced. This can improve the reliability of a transistor including the oxide semiconductor of one embodiment of the present invention, thereby improving the reliability of a semiconductor device including the transistor.

Note that there is no particular limitation on the crystallinity of the metal oxide included in the oxide semiconductor. The oxide semiconductor sometimes includes, for example, at least one of an amorphous semiconductor (a semiconductor having an amorphous structure), a single crystal semiconductor (a semiconductor having a single crystal structure), and a semiconductor having crystallinity other than single crystal (a microcrystalline semiconductor, a polycrystalline semiconductor, or a semiconductor partly including crystal regions). The oxide semiconductor having crystallinity can inhibit deterioration of the transistor characteristics in some cases.

The crystallinity of the oxide semiconductor can be analyzed with an X-ray diffraction (XRD) pattern, a transmission electron microscope (TEM) image, or an electron diffraction (ED) pattern, for example. Alternatively, these methods may be combined to be employed for analysis.

The oxide semiconductor of one embodiment of the present invention preferably includes a metal oxide having a CAAC structure. The CAAC structure is a crystal structure in which a plurality of microcrystals (typically, a plurality of microcrystals each having a hexagonal crystal structure) have c-axis alignment and are connected on the a-b plane without alignment. According to a high-resolution TEM image (also referred to as a multi-wavelength interference image) of a cross section of an oxide semiconductor having the CAAC structure, metal atoms are arranged in a layered manner in crystal parts. Thus, the oxide semiconductor having the CAAC structure can be regarded as having a structure including the layered crystal parts.

The CAAC structure is formed such that the c-axis is perpendicular or substantially perpendicular to a formation surface or the surface of an oxide semiconductor, for example. In the CAAC structure, metal atoms are arranged in a layered manner in a direction parallel or substantially parallel to the formation surface. In a region having the CAAC structure, an angle formed by the c-axis and the formation surface is preferably within 900±200 (greater than or equal to 700 and less than or equal to 1100), further preferably within 900±150 (greater than or equal to 750 and less than or equal to 105°), still further preferably within 900±100 (greater than or equal to 800 and less than or equal to 100°), yet further preferably within 900±5° (greater than or equal to 85° and less than or equal to 95°).

In the case where the oxide semiconductor has the CAAC structure, a group of bright spots (specifically, bright spots arranged in a layered manner) reflecting a layered arrangement of metal atoms is observed in a cross-sectional TEM image of the oxide semiconductor. Specifically, a state where bright spots are arranged in a layered manner in the direction parallel or substantially parallel to the formation surface is observed.

When the oxide semiconductor having the CAAC structure is subjected to electron diffraction, spots indicating c-axis alignment (bright spots) are observed in the electron diffraction pattern.

A fast Fourier transform (FFT) pattern obtained by FFT processing on a TEM image reflects reciprocal lattice space information similar to that of an electron diffraction pattern.

When the cross-sectional TEM image of the oxide semiconductor having the CAAC structure is obtained and each region in the cross-sectional TEM image is subjected to FFT processing to form an FFT pattern, the crystal axis direction in each region can be calculated from the obtained FFT pattern. Specifically, the direction of a line segment connecting two spots that have high luminance and are at substantially the same distance from the center, among spots observed in the obtained FFT pattern, is referred to as a crystal axis direction. A region in which an angle formed by the crystal axis direction calculated from the FFT pattern and the formation surface is preferably greater than or equal to 700 and less than or equal to 1100 (within 90°±20°), further preferably greater than or equal to 750 and less than or equal to 1050 (within 900±15°), still further preferably greater than or equal to 800 and less than or equal to 1000 (within 900° 10°), yet further preferably greater than or equal to 850 and less than or equal to 950 (within 900° 5°) can be regarded as having the CAAC structure.

When the oxide semiconductor having the CAAC structure is observed from the direction perpendicular to the formation surface by using the TEM image, a triangular or hexagonal atomic arrangement and crystallinity are observed in the a-b plane.

### [Composition of Metal Oxide]

The metal oxide of one embodiment of the present invention preferably contains indium (In), and further preferably has a high In content. The use of a metal oxide having a high In content as the oxide semiconductor can increase the on-state current of the transistor and improve the frequency characteristics of the transistor. For example, indium oxide is preferably used as the oxide semiconductor.

Moreover, the metal oxide of one embodiment of the present invention can contain zinc. The metal oxide containing zinc has high crystallinity, e.g., has the CAAC structure. For example, In—Zn oxide can be used as the oxide semiconductor. Specifically, it is possible to use a metal oxide having an atomic ratio of In:Zn=1:1 or a neighborhood thereof, In:Zn=2:1 or a neighborhood thereof, or In:Zn=4:1 or a neighborhood thereof. Note that the neighborhood of the atomic ratio includes ±30% of an intended atomic ratio.

The metal oxide of one embodiment of the present invention can contain the element M. When the metal oxide contains the element M, formation of oxygen vacancies in the metal oxide can be inhibited. Thus, the reliability of the transistor including the oxide semiconductor can be increased.

For example, In—Zn oxide containing a slight amount of the element M can be used as the oxide semiconductor. Specifically, it is possible to use a metal oxide having an atomic ratio of In:Ga:Zn=4:0.1:1 or a neighborhood thereof, In:Ga:Zn=2:0.1:1 or a neighborhood thereof, or In:Ga:Zn=1:0.1:1 or a neighborhood thereof. It is also possible to use a metal oxide having an atomic ratio of In:Sn:Zn=4:0.1:1 or a neighborhood thereof, In:Sn:Zn=2:0.1:1 or a neighborhood thereof, or In:Sn:Zn=1:0.1:1 or a neighborhood thereof.

Moreover, In—Zn oxide containing the element M can be used as the oxide semiconductor. Specifically, it is possible to use a metal oxide having an atomic ratio of In:M:Zn=1:1:1 or a neighborhood thereof, In:M:Zn=1:1:1.2 or a neighborhood thereof, In:M:Zn=1:1:0.5 or a neighborhood thereof, In:M:Zn=1:1:2 or a neighborhood thereof, In:M:Zn=4:2:3 or a neighborhood thereof, In:M:Zn=1:3:2 or a neighborhood thereof, or In:M:Zn=1:3:4 or a neighborhood thereof.

Note that in the case where the metal oxide is deposited by a sputtering method, the composition of the deposited metal oxide may be different from that of a sputtering target. In particular, the zinc content of the deposited metal oxide may be reduced to approximately 50% of that of the sputtering target.

In the case where a film of a metal oxide containing a plurality of kinds of metal elements, such as In—Ga—Zn oxide, is formed by an ALD method, the cycle ratio of precursors containing respective metal elements can be set in accordance with the target composition. For example, to form an In—Ga—Zn oxide film having an atomic ratio of In:Ga:Zn=1:3:2, it is possible to perform one cycle of deposition using a precursor containing In and treatment with an oxidizer, three cycles of deposition using a precursor containing Ga and treatment with an oxidizer, and two cycles of deposition using a precursor containing Zn and treatment with an oxidizer. Note that the atomic ratio of the metal elements in the formed metal oxide film does not sometimes correspond with the cycle ratio of the precursors containing the respective metal elements.

Analysis of the composition of the metal oxide used for the oxide semiconductor can be performed by EDX, XPS, inductively coupled plasma-mass spectrometry (ICP-MS), or inductively coupled plasma-atomic emission spectrometry (ICP-AES), for example. Alternatively, these methods may be combined to be employed for analysis. As for an element whose content is low, the actual content may be different from the content obtained by analysis because of the influence of the analysis accuracy. For example, in the case where the content of the element M is low, the content of the element M obtained by analysis may be lower than the actual content.

The oxide semiconductor of one embodiment of the present invention may have a stacked-layer structure of two or more layers. In the case where the oxide semiconductor has a two-layer structure of a first layer and a second layer over the first layer, the composition of the second layer is preferably different from that of the first layer. In the case where the oxide semiconductor has a three-layer structure of a first layer, a second layer over the first layer, and a third layer over the second layer, the composition of the second layer is preferably different from those of the first and third layers. Note that the composition of the first layer can be the same as that of the third layer. Alternatively, the first and third layers can have different compositions.

For each of the first to third layers, the above-described metal oxide can be used.

For the second layer, indium oxide, In—Zn oxide, or In—Zn oxide containing a slight amount of the element M can be used, for example. Increasing the In content in the second layer can increase the on-state current and frequency characteristics.

The conduction band minimum of each of the first and third layers is preferably positioned closer to the vacuum level than the conduction band minimum of the second layer is. In other words, the energy of the conduction band minimum of each of the first and third layers is preferably lower than the energy of the conduction band minimum of the second layer. In this case, the second layer is sandwiched between the first layer and the third layer, each of which has a conduction band minimum positioned closer to the vacuum level, and can function mainly as a current path (channel).

When the second layer is sandwiched between the first layer and the third layer, carriers trapped at the interfaces between the second layer and the other layers and their vicinities can be reduced. Moreover, the channel can be distanced from the surface of a gate insulating layer, so that the influence of surface scattering can be reduced. Accordingly, a buried-channel transistor where a channel is away from the interface with an insulating layer can be achieved, whereby the field-effect mobility can be increased. Furthermore, the influence of interface states that may be formed on the back channel side is reduced, so that light deterioration (e.g., light negative bias deterioration) of the transistor can be inhibited and the reliability of the transistor can be increased.

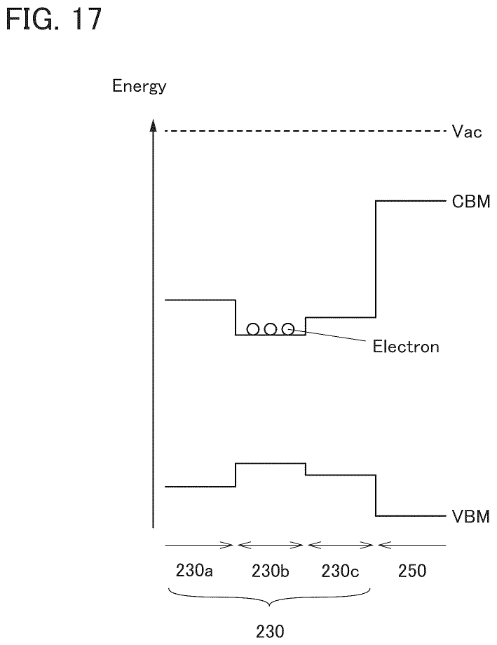

For example, a band diagram of the oxide semiconductor 230 including the oxide semiconductors 230a to 230c and its vicinity illustrated in FIG. 2A is as shown in FIG. 17. In FIG. 17, the vertical axis represents energy, and the horizontal direction represents the thickness direction of a center portion of a channel formation region. FIG. 17 shows a valence band maximum (VBM) and a conduction band minimum (CBM) of each of the oxide semiconductors 230a to 230c and the insulator 250 in a state where no voltage is applied between the gate and the source. In FIG. 17, a vacuum level Vac is denoted by a dashed line.

Note that energy of the valence band maximum and energy of the conduction band minimum change depending on constituent elements and compositions of the oxide semiconductors 230a to 230c and the insulator 250; thus, the relation between energy levels of the valence band maximum and the relation between energy levels of the conduction band minimum are mainly described with reference to the band diagram of FIG. 17.

With certain constituent elements and compositions of the oxide semiconductors 230a to 230c, the oxide semiconductor 230b is sandwiched between the oxide semiconductors 230a and 230c each of which has a conduction band minimum that is positioned closer to the vacuum level than that of the oxide semiconductor 230b is, as shown in FIG. 17. This structure achieves a buried channel. That is, in this structure, a path through which a larger amount of current (electrons are shown as carriers in FIG. 17) flows is formed in the oxide semiconductor 230b. Accordingly, the on-state current or reliability can be increased, for example.

In the case where a buried channel is formed using the first to third layers, a metal oxide having a higher Ga content than the second layer can be used for the first and third layers, for example. Specifically, for each of the first and third layers, a metal oxide having an atomic ratio of In:Ga:Zn=1:1:1 or in the neighborhood thereof, a metal oxide having an atomic ratio of In:Ga:Zn=1:3:2 or in the neighborhood thereof, or a metal oxide having an atomic ratio of In:Ga:Zn=1:3:4 or in the neighborhood thereof can be used. Alternatively, Ga—Zn oxide or gallium oxide can be used. When the Ga content in the first and third layers is increased, the conduction band minimum of each of the first and third layers is sometimes positioned closer to the vacuum level than the conduction band minimum of the second layer is.

Increasing the Ga content in the first and third layers can improve the barrier property against hydrogen in the first and third layers. Thus, diffusion of hydrogen into the second layer from below the first layer or above the third layer can be inhibited. In addition, increasing the Ga content in the first and third layers enables impurities such as hydrogen or water contained in the oxide semiconductor to be reduced by heat applied after the formation of the oxide semiconductor, for example.

Increasing the Ga content in the first and third layers can improve the barrier property against oxygen in the first and third layers. Thus, release of oxygen from the second layer where the channel is formed is inhibited, thereby inhibiting formation of oxygen vacancies in the second layer or an increase in the amount of oxygen vacancies in the second layer. Accordingly, the transistor can have favorable electrical characteristics.

When the Ga content in the first layer is increased, the resistivity of the first layer can be higher than that of the second layer in some cases. In the case where the first layer is provided on the back channel side, providing a layer having high resistivity as the first layer can inhibit a negative shift of the threshold voltage or a decrease in the on-state current. Accordingly, the threshold voltage of the transistor shifts positively, so that the transistor can have normally-off characteristics. In the above manner, the electrical characteristics and reliability of the transistor can be improved.

The band gap of the metal oxide can be evaluated using optical evaluation with a spectrophotometer, spectroscopic ellipsometry, a photoluminescence method, X-ray photoelectron spectroscopy, or an X-ray absorption fine structure (XAFS). Alternatively, these methods can be combined as appropriate to be employed for analysis. The electron affinity or the conduction band minimum can be obtained from a band gap and an ionization potential, which is a difference in energy between the vacuum level and the valence band maximum. The ionization potential can be evaluated by ultraviolet photoelectron spectroscopy (UPS), for example.

Note that a metal oxide having a higher In content than the second layer may be used for the first and third layers. Moreover, a metal oxide having a higher In content than the second layer may be used for one of the first and third layers, and a metal oxide having a higher Ga content than the second layer may be used for the other.

Each of the first to third layers may include a stack of a plurality of layers each having the above-described composition. For example, the first layer may have a structure in which a metal oxide with a high In content is stacked over a metal oxide with a high Ga content. As another example, the third layer may have a structure in which a metal oxide with a high Ga content is stacked over a metal oxide with a high In content.

### [Formation Method of Oxide Semiconductor]

The oxide semiconductor of one embodiment of the present invention can be formed by a sputtering method, a chemical vapor deposition (CVD) method, a vacuum evaporation method, an MBE method, a PLD method, an ALD method, or the like.

The oxide semiconductor of one embodiment of the present invention can be formed by forming metal oxides using two kinds of formation methods. For example, the oxide semiconductor of one embodiment of the present invention can be formed by forming metal oxides using a first formation method and a second formation method.

The oxide semiconductor of one embodiment of the present invention can have a two-layer structure of a first layer and a second layer over the first layer. In the case where the oxide semiconductor has a two-layer structure, the oxide semiconductor can be formed in the following manner: the first layer is formed over a formation surface by a first formation method, and then the second layer is formed over the first layer by a second formation method.

As the first formation method, a film formation method that causes less damage to the formation surface than the second formation method is preferably used. Accordingly, formation of a mixed layer at the interface between the oxide semiconductor and a layer serving as the formation surface of the oxide semiconductor can be inhibited. Moreover, entry of impurities such as silicon into the second layer formed over the first layer can be inhibited, so that the crystallinity of the oxide semiconductor can be further increased in some cases.

Examples of the first formation method include an ALD method, a CVD method, and an MBE method. Examples of a CVD method include a plasma enhanced CVD (PECVD) method, a thermal CVD method, a photo CVD method, and an MOCVD method. An MBE method is a film formation method by which a thin film having a crystal structure reflecting a crystal system of a substrate is grown, and is one of film formation methods that cause less damage to a formation surface. A wet method can be used as the first formation method. A wet method is one of film formation methods that cause less damage to a formation surface. An example of a wet method is a spray coating method.

As the second formation method, a method by which a metal oxide having crystallinity can be formed is preferably used. The metal oxide formed at this time particularly preferably has the CAAC structure. Examples of the second formation method include a sputtering method and a PLD method. A metal oxide deposited by a sputtering method is likely to have crystallinity; thus, a sputtering method is suitable as the second formation method.

When a metal oxide is formed over the formation surface by the second formation method, damage to the formation surface might cause alloying of a component contained in the metal oxide with a component contained in the layer serving as the formation surface. When alloying occurs, a mixed layer is sometimes formed at the interface between the metal oxide and the layer serving as the formation surface. The mixed layer can also be referred to as an alloyed region. The formation of the mixed layer can also be referred to as alloying.

For example, in the case where a sputtering method is used as the second formation method, a mixed layer is sometimes formed owing to particles ejected from a target or the like (also referred to as sputtered particles) or energy applied to the substrate side by sputtered particles or the like, for example. Specifically, in the case where a metal oxide is formed over an insulating layer including silicon, e.g., a silicon oxide film as the formation surface by the second formation method, silicon might enter the metal oxide. There is a concern that the entry of impurities such as silicon into the metal oxide may hinder crystallization of the metal oxide. When an oxide semiconductor into which impurities enter is used for a transistor, the initial characteristics or reliability of the transistor may be adversely affected. It is difficult to increase the crystallinity of an alloyed region even when heat treatment described later is performed.

Accordingly, forming the metal oxide by the first formation method before forming the metal oxide by the second formation method as described above can inhibit entry of impurities into the oxide semiconductor. In addition, alloying with the layer serving as the formation surface can be inhibited. Thus, the initial characteristics and reliability of the transistor can be improved. Moreover, the crystallinity of the oxide semiconductor can be further increased.

Note that a mixed layer is sometimes formed at the interface between the first layer and the second layer. The mixed layer includes a component contained in the first layer and a component contained in the second layer. For example, in the case where gallium oxide is used for the first layer and a metal oxide containing indium is used for the second layer, the mixed layer includes gallium and indium. For example, in the case where the indium content in the second layer is higher than that in the first layer, the indium content in the mixed layer is higher than or equal to that in the first layer and lower than or equal to that in the second layer.

An ALD method is suitable as the first formation method because damage to the formation surface can be inhibited as compared with a sputtering method. An ALD method is a film formation method that gives higher coverage than a sputtering method, and the use of an ALD method as the formation method of the first layer enables the oxide semiconductor to adequately cover a component thereunder. Thus, the oxide semiconductor can suitably cover a step, an opening portion, or the like having a high aspect ratio.

For the first layer, a metal oxide having a microcrystalline structure or an amorphous structure that has lower crystallinity than the CAAC structure is formed in some cases, for example. Forming the second layer having high crystallinity on the first layer having low crystallinity or performing heat treatment after the formation of the second layer can increase the crystallinity of the first layer with the second layer as a nucleus in some cases. Accordingly, in some cases, the crystallinity can be increased in the whole oxide semiconductor including the vicinity of the interface with the formation surface.

The layer serving as the formation surface is an insulating film such as a silicon oxide film, a silicon oxynitride film, a silicon nitride film, a silicon nitride oxide film, an aluminum oxide film, or a hafnium oxide film, for example. Note that the layer serving as the formation surface may be a conductive film such as a titanium nitride film, a tungsten film, or an ITSO film in some transistor structures. The layer serving as the formation surface does not necessarily have crystallinity. In the case of having crystallinity, the layer serving as the formation surface may have a crystal structure with low lattice matching with the metal oxide included in the oxide semiconductor.

The first layer is preferably formed by an ALD method. Here, a method for forming In-M-Zn oxide for the first layer by an ALD method is described.

First, a source gas that contains a precursor containing indium is introduced into a reaction chamber (also referred to as a chamber) so that the precursor is adsorbed on the formation surface. Then, an oxidizer is introduced as a reactant into the reaction chamber to react with the adsorbed precursor, and components other than indium are released while indium is adsorbed on the substrate, whereby a layer in which indium and oxygen are bonded to each other is formed.

Subsequently, a source gas that contains a precursor containing the element M is introduced into the reaction chamber, and the precursor is adsorbed on the layer in which indium and oxygen are bonded to each other. Then, an oxidizer is introduced as a reactant into the reaction chamber to react with the adsorbed precursor, and components other than the element M are released while the element M is adsorbed on the substrate, whereby a layer in which the element M and oxygen are bonded to each other is formed.

Next, a source gas that contains a precursor containing zinc is introduced into the reaction chamber, and the precursor is adsorbed on the layer in which the element M and oxygen are bonded to each other. Then, an oxidizer is introduced as a reactant into the reaction chamber to react with the adsorbed precursor, and components other than zinc are released while zinc is adsorbed on the substrate, whereby a layer in which zinc and oxygen are bonded to each other is formed.

By repeating the above steps, In-M-Zn oxide can be formed by an ALD method as the oxide semiconductor over the layer serving as the formation surface.

When the oxide semiconductor is formed by an ALD method, ozone (O₃), oxygen (O₂), water (H₂O), or the like is used as the oxidizer. The use of an oxidizer without hydrogen, such as ozone (O₃) or oxygen (O₂), can reduce the amount of hydrogen entering the oxide semiconductor.

It is preferable that after the precursor is adsorbed in the above steps, introduction of the source gas containing the precursor be stopped and the reaction chamber be purged so that an excess precursor, a reaction product, and the like are removed from the reaction chamber. Moreover, it is preferable that after the adsorbed precursor reacts with the oxidizer in the above steps, introduction of the oxidizer be stopped and the reaction chamber be purged so that an excess reactant, a reaction product, and the like are removed from the reaction chamber.

In the description of this specification and the like, in the case of using ozone, oxygen, and water as a reactant or an oxidizer, they include not only those in gas or molecular states but also those in plasma, radical, and ion states, unless otherwise specified.

The second layer is preferably formed by a sputtering method.

As a target used in a sputtering method, In-M-Zn oxide can be used. In the case where a metal oxide is formed by a sputtering method, oxygen or a mixed gas of oxygen and a noble gas can be used as a sputtering gas. An increase in the proportion of oxygen in the sputtering gas can increase the amount of excess oxygen contained in the oxide film to be formed.

A higher proportion of the flow rate of an oxygen gas to the flow rate of the whole film formation gas (also referred to as oxygen flow rate ratio) used at the time of forming the metal oxide enables the formed metal oxide to have higher crystallinity in some cases.

When the metal oxide is formed by a sputtering method and the proportion of oxygen in the sputtering gas is higher than 30% and lower than or equal to 100%, preferably higher than or equal to 70% and lower than or equal to 100%, an oxygen-excess metal oxide is formed in some cases. A transistor including an oxygen-excess metal oxide in a channel formation region can have relatively high reliability. However, one embodiment of the present invention is not limited thereto. When the proportion of oxygen in the sputtering gas is higher than or equal to 1% and lower than or equal to 30%, preferably higher than or equal to 5% and lower than or equal to 20%, an oxygen-deficient metal oxide is formed. A transistor including an oxygen-deficient metal oxide in a channel formation region can have relatively high field-effect mobility.

In the formation of the metal oxide by a sputtering method, substrate heating is preferably performed. Increasing the substrate temperature (stage temperature) at the time of forming the metal oxide enables a metal oxide with high crystallinity to be formed in some cases. In the formation of the metal oxide by a sputtering method, the substrate heating temperature is preferably higher than or equal to 100° C. and lower than or equal to 400° C., further preferably higher than or equal to 200° C. and lower than or equal to 300° C., for example.

With the above-described formation method, the thickness of the mixed layer formed at the interface between the layer serving as the formation surface and the metal oxide can be reduced or the thickness of the alloyed region formed at the interface between the layer serving as the formation surface and the metal oxide can be thin enough to be unobserved. For example, the thickness of the alloyed region can be greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm.

Note that the thickness of the alloyed region can sometimes be calculated by performing SIMS or composition line analysis by energy dispersive X-ray spectroscopy (EDX) on the region and its vicinity.

For example, EDX line analysis is performed on the alloyed region and its vicinity with the direction perpendicular to the formation surface of the first layer regarded as the depth direction. Next, in the profile of quantitative values of the elements in the depth direction, which is obtained from the analysis, the depth at which the quantitative value of a metal that is the main component of the first layer and is not the main component of the layer serving as a formation surface (In in the case where the first layer contains In) becomes half is defined as the depth (position) of the interface between the region and the first layer. The depth at which the quantitative value of an element (e.g., Si) that is a main component of the layer serving as the formation surface and that is not a main component of the first layer becomes half is defined as the depth (position) of the interface between the region and the layer serving as the formation surface. In the above manner, the thickness of the alloyed region can be calculated.

When the thickness of the alloyed region in the oxide semiconductor of one embodiment of the present invention is observed by EDX analysis, the thickness is greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm, for example.

For example, when SIMS analysis is performed on the oxide semiconductor formed over a silicon oxide film serving as the formation surface, the depth at which the silicon concentration is 50% of the maximum value of the silicon concentration of the silicon oxide film is defined as an interface, and the distance between the interface and the depth at which the silicon concentration decreases to 1.0×10²¹ atoms/cm³, preferably 5.0×10²⁰ atoms/cm³, further preferably 1.0×10²⁰ atoms/cm³ is defined as a thickness t. The thickness t is preferably less than or equal to 3 nm, further preferably less than or equal to 2 nm.

When the thickness of the alloyed region is reduced, the thickness t can be a value within the above range.

Note that when the thickness of the alloyed region is reduced, the CAAC structure can be formed in the vicinity of the formation surface. Here, the vicinity of the formation surface refers to, for example, a region at a depth greater than 0 nm and less than or equal to 3 nm, preferably greater than 0 nm and less than or equal to 2 nm, further preferably greater than or equal to 1 nm and less than or equal to 2 nm from the formation surface of the oxide semiconductor in the direction substantially perpendicular to the formation surface.

Note that the CAAC structure in the vicinity of the formation surface can be confirmed in TEM observation in some cases. For example, in high-resolution TEM cross-sectional observation of the oxide semiconductor, bright spots arranged in a layered manner in the direction parallel to the formation surface are observed in the vicinity of the formation surface.

The oxide semiconductor of one embodiment of the present invention can have a three-layer structure of a first layer, a second layer over the first layer, and a third layer over the second layer.

In the case where the oxide semiconductor has a three-layer structure, the oxide semiconductor can be formed in the following manner: the first layer is formed over a formation surface by a first formation method, and then the second layer is formed by a second formation method, and the third layer is formed by the first formation method.

Even when the first and third layers in the oxide semiconductor have a composition that is less likely to achieve the CAAC structure in the formation of a single layer, crystal growth occurring with the second layer as a nucleus enables the whole oxide semiconductor including the first and third layers to have the CAAC structure. Alternatively, the oxide semiconductor can have the CAAC structure in a region that includes the second layer and at least part of each of the first and third layers.

In particular, even with a composition where the first and third layers have a high In content, crystallinity suitable for a semiconductor layer of a transistor can be obtained. The oxide semiconductor of one embodiment of the present invention achieves both high on-state characteristics and high reliability of the transistor owing respectively to the increase in the In content and achievement of the CAAC structure with high crystallinity.

The first and third layers may employ a metal oxide having the same composition as the second layer. By using the same composition, the oxide semiconductors may easily have the CAAC structure after heat treatment.

Since the second layer has high crystallinity, the crystal growth of the third layer can be achieved with the use of the crystal of the second layer as a nucleus or a seed. Thus, the third layer can be crystallized even when a film formation method that easily gives crystallinity is not employed as the formation method of the third layer. Here, for example, when a film formation method that gives higher coverage than that of the second layer is used to form the third layer, the whole oxide semiconductor can have both high crystallinity and high coverage.

When influence of the formation surface on the second layer is reduced by provision of the first layer, the crystallinity of the second layer is increased to an extremely high level. Thus, the third layer whose crystal is grown with the second layer as a nucleus or a seed is also expected to have extremely excellent crystallinity.

Note that in the case where the oxide semiconductor is used for a semiconductor layer of a transistor, the third layer, which is the uppermost layer of the oxide semiconductor, is in contact with a gate insulating layer in some cases. Increasing the crystallinity of the layer in contact with the gate insulating layer can increase the carrier mobility in an on state of the transistor.

The crystallinity of the first and third layers is increased with the use of the second layer having high crystallinity as a nucleus or a seed. Specifically, the crystallinity of the first layer may be increased at the time of formation of the second layer or by heat treatment after formation of the third layer. The crystallinity of the third layer may be increased at the time of formation of the third layer or by heat treatment after formation of the third layer. Note that the above heat treatments have a function of assisting in increasing the crystallinity.

As described above, in the method for forming the oxide semiconductor of one embodiment of the present invention, with the use of the second layer including a metal oxide with high crystallinity (i.e., a c-axis-aligned crystal or CAAC) as a nucleus or a seed, the crystallinity of the metal oxides above and below the second layer (here, the first and third layers) can be increased. Accordingly, the crystallinity of the whole oxide semiconductor can be increased. In other words, the second layer serves as a nucleus or a seed to cause solid-phase growth of the metal oxides above and below the second layer, so that the oxide semiconductor with high crystallinity can be formed. An oxide semiconductor formed by such a formation method, here, a CAAC film, can be referred to as an axial growth CAAC (AG CAAC).

A region having the CAAC structure preferably spreads in the whole layer of the oxide semiconductor. Crystals in the region having the CAAC structure in the first layer are connected to crystals in the region having the CAAC structure in the second layer. Crystals in the region having the CAAC structure in the third layer are connected to crystals in the region having the CAAC structure in the second layer. Accordingly, a boundary between the first layer and the second layer is not observed in some cases. In addition, a boundary between the second layer and the third layer is not observed in some cases. The oxide semiconductor may be expressed as one layer where interfaces are not clearly observed. The oxide semiconductor may be expressed as a single layer.

In the region having the CAAC structure in each of the first to third layers, bright spots arranged parallel or substantially parallel to the formation surface are observed in a high-resolution cross-sectional TEM image, for example. The c-axis of the CAAC structure included in each of the first to third layers is preferably parallel or substantially parallel to the normal direction of the formation surface or the surface of the oxide semiconductor.

Part of the first layer or the third layer is not crystallized in some cases.

In the case where the oxide semiconductor has a three-layer structure, the oxide semiconductor can also be formed in the following manner: a first layer is formed over a formation surface by a first formation method, and then a second layer is formed by the first formation method, and a third layer is formed by a second formation method.

As described above, when a metal oxide with a high In content is used for a transistor, the field-effect mobility of the transistor can be increased. On the other hand, a metal oxide with a high In content tends to have a cubic crystal structure. Thus, when a metal oxide with a high In content is used for the second layer in contact with the third layer, crystals reflecting the orientation of crystals included in the third layer can be formed.

It is preferable that the crystals included in the third layer and the crystals included in the second layer have a small lattice mismatch. Thus, crystals reflecting the orientation of the crystals included in the third layer can be formed in the second layer. At this time, for example, in high-resolution cross-sectional TEM observation of the oxide semiconductor, bright spots arranged in a layered manner in the direction parallel to the formation surface are observed in the second layer.

There is no particular limitation on the crystal structure of the second layer as long as the crystals included in the third layer and the crystals included in the second layer have a small lattice mismatch. The crystal structure of the second layer may be any of a cubic crystal structure, a tetragonal crystal structure, an orthorhombic crystal structure, a hexagonal crystal structure, a monoclinic crystal structure, and a trigonal crystal structure.

In the above structure, typically, the first layer can be a layer including a metal oxide having an atomic ratio of In:Ga:Zn=1:3:2 or in the neighborhood thereof or a layer including gallium oxide, the second layer can be a layer including a metal oxide containing a slight amount of the element M or a layer including indium oxide, and the third layer can be a layer including a metal oxide having an atomic ratio of In:Ga:Zn=1:1:1 or in the neighborhood thereof. In this case, the first layer includes gallium. In the case where the first layer includes a metal oxide having an atomic ratio of In:Ga:Zn=1:3:2 or in the neighborhood thereof, the indium content is lower than the gallium content in the first layer. The indium content in the second layer is higher than the indium content in the third layer.

In the case where the first layer and the second layer are formed by the first formation method, the first layer and the second layer are preferably formed successively without exposure to the air. Forming the first layer and the second layer successively without exposure to the air can increase the productivity. Furthermore, impurities (typically, moisture or the like) that would be taken into the interface between the first layer and the second layer and the vicinity thereof can be reduced.

One or more of the first to third layers may include a stack of a plurality of layers with different compositions. For example, the first layer may be formed in the following manner: a layer including a metal oxide with a high Ga content is formed by the first formation method, and then a layer including a metal oxide with a higher In content than the layer is formed by the first formation method.

After the formation of the layer by the first formation method, microwave plasma treatment is preferably performed.

In this specification and the like, a microwave refers to an electromagnetic wave having a frequency greater than or equal to 300 MHz and less than or equal to 300 GHz. Microwave plasma treatment refers to, for example, treatment using an apparatus including a power source for generating high-density plasma using microwaves. Microwave plasma treatment can also be referred to as microwave-excited high-density plasma treatment.

By performing microwave plasma treatment in an oxygen-containing atmosphere, the impurity concentration in the oxide semiconductor 230 can be reduced. Specific examples of impurities include hydrogen and carbon. Although the microwave plasma treatment in an oxygen-containing atmosphere is performed on the metal oxide in the above, one embodiment of the present invention is not limited thereto. For example, microwave plasma treatment in an oxygen-containing atmosphere may be performed on an insulating film, specifically a silicon oxide film, which is positioned in the vicinity of the metal oxide. Furthermore, the crystallinity of the oxide semiconductor is sometimes increased by heat in the microwave plasma treatment.

The microwave plasma treatment is preferably performed under a reduced pressure, and the pressure is preferably higher than or equal to 10 Pa and lower than or equal to 1000 Pa, further preferably higher than or equal to 50 Pa and lower than or equal to 700 Pa, still further preferably higher than or equal to 100 Pa and lower than or equal to 400 Pa. The treatment temperature is preferably higher than or equal to room temperature (25° C.) and lower than or equal to 750° C., further preferably higher than or equal to 300° C. and lower than or equal to 500° C., and can be higher than or equal to 400° C. and lower than or equal to 450° C.

In the microwave plasma treatment, substrate heating may be performed. The substrate heating temperature is preferably higher than or equal to room temperature (e.g., 25° C.), higher than or equal to 100° C., higher than or equal to 200° C., higher than or equal to 300° C., or higher than or equal to 400° C., and lower than or equal to 500° C. or lower than or equal to 450° C.

The microwave plasma treatment can be performed using an oxygen gas and an argon gas, for example. For example, the oxygen flow rate ratio (O₂/(O₂+Ar)) in the microwave plasma treatment is preferably higher than 0% and lower than or equal to 10%, further preferably higher than or equal to 0.5% and lower than or equal to 5%, still further preferably higher than or equal to 0.5% and lower than or equal to 3%, and is typically preferably 1%.

The microwave plasma treatment in an oxygen-containing atmosphere can convert an oxygen gas into plasma by using a high-frequency wave such as a microwave or an RF, and apply, to the oxide semiconductor, oxygen radicals that are generated by conversion of the oxygen gas into plasma. By the effects of plasma, a microwave, oxygen radicals, and the like, a defect that is an oxygen vacancy into which hydrogen has entered (hereinafter sometimes referred to as V_{O}H) in the oxide semiconductor can be divided into an oxygen vacancy and hydrogen, and hydrogen which is an impurity can be removed from the oxide semiconductor. In this manner, V_{O}H contained in the oxide semiconductor can be reduced. At this time, carbon bonded to oxygen, hydrogen, or the like can also be removed in some cases. Performing the microwave plasma treatment in such a manner can reduce impurities such as carbon and hydrogen. Supplying the oxygen radicals to oxygen vacancies formed in the oxide semiconductor can further reduce oxygen vacancies in the oxide semiconductor.

The microwave plasma treatment can increase the crystallinity of the layer formed by the first formation method. Here, the principles of improving the crystallinity of the oxide semiconductor by the microwave plasma treatment will be described. First, active species excited by a microwave, such as oxygen radicals, reach the surface of the oxide semiconductor, and a substitution reaction between the active species and oxygen in the oxide semiconductor occurs. At this time, a nucleus or a seed is formed. In addition, lateral growth of the nucleus or the seed is caused. Note that it is preferable that the active species excited by the microwave contain oxygen (typically, oxygen ions) that is likely to be adsorbed onto a side surface of the nucleus or the seed, in which case the lateral growth is promoted. The microwave plasma treatment causes formation of a nucleus or a seed and lateral growth of the nucleus or the seed, so that the crystallinity of the oxide semiconductor is improved.

Meanwhile, when part of oxygen that has been present in the oxide semiconductor before the microwave plasma treatment reacts with hydrogen in the oxide semiconductor, i.e., a reaction “2H+O→H₂O↓” occurs, the hydrogen can be removed as H₂O (i.e., dehydration or dehydrogenation is achieved). H₂O is a limiting factor in improving crystallinity and thus is preferably removed from the oxide semiconductor. Hydrogen in the oxide semiconductor is removed as H₂O to reduce the hydrogen concentration in the oxide semiconductor, whereby an improvement in crystallinity can be promoted. When the temperature of the microwave plasma treatment is increased, the hydrogen concentration in the oxide semiconductor can be further reduced.

Note that the microwave plasma treatment may be followed successively by heat treatment without exposure to the air. The heat treatment temperature is preferably higher than or equal to 100° C. and lower than or equal to 750° C., further preferably higher than or equal to 300° C. and lower than or equal to 500° C., still further preferably higher than or equal to 400° C. and lower than or equal to 450° C., for example.

Note that the crystallinity can also be improved by performing plasma treatment using an oxygen gas, instead of the microwave plasma treatment.

The increase in the crystallinity of the layer formed by the first formation method can further increase the crystallinity of a layer formed over the layer. Thus, the crystallinity of the whole oxide semiconductor can be increased.

Oxygen supplied to the oxide semiconductor is in any of a variety of forms such as an oxygen atom, an oxygen molecule, an oxygen ion (a charged oxygen atom or a charged oxygen molecule), and an oxygen radical (an oxygen atom, an oxygen molecule, or an oxygen ion having an unpaired electron). Oxygen injected into the oxide semiconductor preferably has one or more of the above forms. An oxygen radical is particularly preferable.

Heat treatment is preferably performed after the formation of the oxide semiconductor. By performing the heat treatment, the crystallinity of the oxide semiconductor can be increased. The heat treatment here is not limited to treatment with application of heat. For example, heat applied during the formation process may be regarded as the heat treatment.

The heat treatment temperature can be higher than or equal to 100° C. and lower than or equal to 800° C., preferably higher than or equal to 250° C. and lower than or equal to 650° C., further preferably higher than or equal to 350° C. and lower than or equal to 550° C., for example. Typically, the temperature can be 400° C.±25° C. (higher than or equal to 375° C. and lower than or equal to 425° C.). The treatment time can be shorter than or equal to 10 hours and can be, for example, longer than or equal to 1 minute and shorter than or equal to 5 hours, or longer than or equal to 1 minute and shorter than or equal to 2 hours. In the case of using an RTA apparatus, the treatment time can be longer than or equal to 1 second and shorter than or equal to 5 minutes, for example. By the heat treatment, the third layer formed by the first formation method (i.e., molecules having crystallinity that are deposited by an ALD method) should fill an atomic-level space between crystal parts of the CAAC structure of the second layer formed by the second formation method.

The heating apparatus used for the heat treatment is not limited to a particular apparatus, and may be an apparatus for heating an object to be processed by heat conduction or heat radiation from a heating element such as a resistance heating element. For example, an electric furnace, or a rapid thermal annealing (RTA) apparatus such as a lamp rapid thermal annealing (LRTA) apparatus or a gas rapid thermal annealing (GRTA) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas.

By the heat treatment step, the crystallinity of the region having the CAAC structure may be increased in the third layer formed by the first formation method. In the case where the region is formed only in the lower portion of the third layer after the deposition by an ALD method, the region may be extended upward by the heat treatment step. That is, by the heat treatment, the region having the CAAC structure may be formed in the whole third layer.

By the heat treatment step, at least part of the first layer or the second layer formed by the first formation method preferably has the CAAC structure. The CAAC structure should be easily generated with a mixed layer that is formed in the first layer or the second layer and serves as a nucleus or a seed at the time of forming the layer by the second formation method. The CAAC region in the first layer or the second layer is preferably large, and the CAAC region preferably extends to the vicinity of the formation surface.

Since the CAAC region extends from the upper portion to the lower portion of the first layer or the second layer, the CAAC region can extend to the vicinity of the layer serving as the formation surface, regardless of the material and crystallinity of the layer serving as the formation surface. For example, even when the layer serving as the formation surface has an amorphous structure, the crystallinity of the first layer or the second layer can be increased. Thus, the method for forming the oxide semiconductor of one embodiment of the present invention is suitable particularly for the case where the layer serving as the formation surface has an amorphous structure.

When one or both of the microwave plasma treatment and the heat treatment are performed as described above, the crystallinity of the whole oxide semiconductor can be increased. Moreover, impurities in the oxide semiconductor can be reduced. Crystal growth of the oxide semiconductor with a low impurity concentration can further make crystallinity higher.

Increasing the crystallinity of the oxide semiconductor can inhibit an increase in the electric resistance of the semiconductor layer of a transistor including the oxide semiconductor or improve the initial characteristics (in particular, the on-state current) of the transistor, and thus a transistor suitable for high-speed operation can be expected. In addition, the reliability and on-state current of the transistor can be increased.

Note that one or both of the microwave plasma treatment and the heat treatment may be performed directly on the oxide semiconductor or performed on an insulating film or the like formed over the oxide semiconductor.

Before the formation of the first layer or after the formation of the first layer or the second layer by the first formation method, treatment for supplying oxygen to the first layer or the second layer may be performed. Accordingly, oxygen can be supplied to the oxide semiconductor by heat applied after this treatment, for example.

Examples of the treatment for supplying oxygen include heat treatment in an oxygen-containing atmosphere and plasma treatment (including microwave plasma treatment) in an oxygen-containing atmosphere. Moreover, an oxide film (preferably a metal oxide film) may be formed in an oxygen-containing atmosphere by a sputtering method, thereby supplying oxygen to the first layer or the second layer formed by the first formation method. The formed oxide film may be removed immediately or left as it is. In the case where the oxide film is left as it is, the oxide film can be used as the layer provided over the first layer or the second layer (i.e., used as the second layer or the third layer). Note that an oxygen-containing atmosphere includes not only an oxygen gas (O₂) but also a gas of an oxygen-containing compound such as ozone (O₃) or dinitrogen monoxide (N₂O). The substrate temperature in the plasma treatment is higher than or equal to room temperature (25° C.) and lower than or equal to 450° C.

The oxide semiconductor of one embodiment of the present invention has high crystallinity throughout the whole layer. Thus, in the oxide semiconductor, boundaries between the stacked first to third layers are not observed in some cases. The boundaries between the stacked layers may be difficult to observe particularly after heat treatment is performed. Whether the boundaries between the stacked layers are present can be checked in cross-sectional observation with a TEM or a scanning transmission electron microscope (STEM), for example.

The oxide semiconductor that is formed by the above-described two kinds of formation methods and has the CAAC structure sometimes has one or more of a higher dielectric constant, a higher film density, and higher film hardness than an oxide semiconductor that is formed by one kind of formation method and has the CAAC structure.

When the oxide semiconductor that is formed by the above two kinds of formation methods and has the CAAC structure is used for a channel formation region of a transistor, the transistor can have excellent characteristics (e.g., a high on-state current, high field-effect mobility, a low S value, high frequency characteristics (also referred to as f characteristics), or high reliability).

The oxide semiconductor of one embodiment of the present invention can sometimes be formed by using the first formation method and one or both of microwave plasma treatment and heat treatment. In other words, the oxide semiconductor of one embodiment of the present invention can be formed without using the second formation method in some cases. For example, after the first layer is formed by the first formation method, one or both of microwave plasma treatment and heat treatment are performed, whereby the crystallinity of the first layer can be increased. Thus, the crystallinity of the second layer that is formed over the first layer by the first formation method can be increased using the first layer as a nucleus or a seed. When one or both of microwave plasma treatment and heat treatment are performed after the formation of the second layer, the crystallinity of the oxide semiconductor can be increased. Accordingly, the CAAC structure can be formed in the oxide semiconductor.

As described above, even in the formation method not using the second formation method, the use of the first layer formed by the first formation method as a nucleus or a seed enables solid-phase growth of the layer above the first layer, whereby an oxide semiconductor with high crystallinity can be formed. An oxide semiconductor formed by such a formation method can also be referred to as an AG CAAC.

Note that in the case where the oxide semiconductor has a stacked-layer structure of two or more layers, the oxide semiconductor can also be formed by forming metal oxides by one kind of formation method. In the case where the oxide semiconductor has a two-layer structure of a first layer and a second layer over the first layer, the oxide semiconductor can be formed by forming the first layer and the second layer in this order by a sputtering method, for example. A sputtering method, which achieves a higher deposition rate than an ALD method, can increase the productivity. As another example, in the case where the oxide semiconductor has a three-layer structure of a first layer, a second layer over the first layer, and a third layer over the second layer, the first to third layers can be formed by a sputtering method. Furthermore, some of the first to third layers can be formed by an ALD method. For example, one or both of the second layer and the third layer may be formed by an ALD method.

### [Oxide Semiconductor of Transistor]

The oxide semiconductor of this embodiment can be used for a semiconductor layer of a transistor.

The oxide semiconductor of this embodiment can be used as the oxide semiconductor 230 or the like included in the transistors described in Embodiment 1. For example, the first layer can be used as the oxide semiconductor 230a, the second layer can be used as the oxide semiconductor 230b, and the third layer can be used as the oxide semiconductor 230c. The layer serving as the formation surface corresponds to the insulator 224 described in Embodiment 1.

The oxide semiconductor of this embodiment preferably has the CAAC structure. In the oxide semiconductor having the CAAC structure, metal atoms are arranged in a crystal part in a layered manner in the direction parallel or substantially parallel to the formation surface.

The oxide semiconductor having the CAAC structure is presumed to exhibit current anisotropy. For example, in an IGZO crystal, current flows more easily in the a-axis direction than in the c-axis direction. That is, in the oxide semiconductor having the CAAC structure, current is presumed to flow easily in the lateral direction rather than in the vertical direction.

In the oxide semiconductor 230 of the semiconductor device described in the foregoing embodiment, metal atoms are arranged in a layered manner in the direction parallel or substantially parallel to the formation surface. This can also be expressed that “the a-b plane of the CAAC structure is provided to be parallel or substantially parallel to the formation surface”. With such a structure, the a-b plane of the CAAC structure can be provided along a current flow direction in a channel of the transistor. Accordingly, the transistor can have a high on-state current.

In the case where the oxide semiconductor of this embodiment is used for a semiconductor layer of a transistor, the thickness of the oxide semiconductor is preferably greater than or equal to 3 nm and less than or equal to 200 nm, further preferably greater than or equal to 3 nm and less than or equal to 100 nm, further preferably greater than or equal to 5 nm and less than or equal to 100 nm, still further preferably greater than or equal to 10 nm and less than or equal to 100 nm, still further preferably greater than or equal to 10 nm and less than or equal to 70 nm, yet further preferably greater than or equal to 15 nm and less than or equal to 70 nm, yet further preferably greater than or equal to 15 nm and less than or equal to 50 nm, yet still further preferably greater than or equal to 20 nm and less than or equal to 50 nm, for example. In a transistor used for a further downsized semiconductor device, the thickness of the oxide semiconductor is preferably greater than or equal to 1 nm and less than or equal to 20 nm, further preferably greater than or equal to 3 nm and less than or equal to 15 nm, still further preferably greater than or equal to 5 nm and less than or equal to 12 nm, yet further preferably greater than or equal to 5 nm and less than or equal to 10 nm. The average thickness of the oxide semiconductor in a channel formation region of the transistor is particularly preferably greater than or equal to 2 nm and less than or equal to 15 nm, for example.

The thickness of the first layer is preferably greater than or equal to 0.5 nm and less than or equal to 50 nm, further preferably greater than or equal to 0.5 nm and less than or equal to 30 nm, further preferably greater than or equal to 0.5 nm and less than or equal to 20 nm, still further preferably greater than or equal to 1 nm and less than or equal to 50 nm, still further preferably greater than or equal to 1 nm and less than or equal to 30 nm, yet further preferably greater than or equal to 1 nm and less than or equal to 20 nm, yet still further preferably greater than or equal to 2 nm and less than or equal to 20 nm, for example. The thickness of the first layer is further preferably greater than or equal to 0.5 nm and less than or equal to 3 nm.

The first layer preferably includes a region with a thickness greater than or equal to 0.1 nm and less than or equal to 3 nm, and further preferably includes a region with a thickness greater than or equal to 0.1 nm and less than or equal to 2 nm. Alternatively, the first layer preferably includes a region with a thickness greater than or equal to 0.5 nm and less than or equal to 3 nm, and further preferably includes a region with a thickness greater than or equal to 0.5 nm and less than or equal to 2 nm.

The thickness of the second layer is preferably less than or equal to 200 nm, for example. In the case where the second layer is in the form of layer, the thickness of the second layer is preferably greater than or equal to 1 nm and less than or equal to 200 nm, further preferably greater than or equal to 1 nm and less than or equal to 100 nm, still further preferably greater than or equal to 2 nm and less than or equal to 100 nm, for example.

Alternatively, in some cases, the second layer is not in the form of layer but is an aggregate of island-shaped regions as long as the second layer can function as a crystal nucleus. In such a case, the island-shaped regions of the second layer are present discretely, for example.

The description of the thickness of the first layer can be referred to for the preferred range of the thickness of the third layer.

### [Impurities in Oxide Semiconductor]

The influence of impurities in the oxide semiconductor is described here.

As has been described in the foregoing embodiment, in a transistor using the oxide semiconductor for a semiconductor layer, the electrical characteristics may vary easily and the reliability may be decreased when oxygen vacancies (V_{O}) and impurities are present in a channel formation region in the oxide semiconductor. Accordingly, in order to obtain stable electrical characteristics of the OS transistor, reducing the impurity concentration in the oxide semiconductor is effective. In order to reduce the impurity concentration in the oxide semiconductor, it is preferable that the impurity concentration in an adjacent film be also reduced. Examples of impurities include hydrogen, carbon, and nitrogen. Note that impurities in an oxide semiconductor refer to, for example, elements other than the main components of an oxide semiconductor. For example, an element with a concentration of lower than 0.1 atomic % is an impurity.

When an oxide semiconductor contains silicon or carbon, which is a Group 14 element, defect states are formed in the oxide semiconductor. Accordingly, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

When the oxide semiconductor contains nitrogen, the oxide semiconductor easily becomes n-type by generation of electrons serving as carriers and an increase in carrier concentration. As a result, a transistor including, as a semiconductor, an oxide semiconductor that contains nitrogen tends to have normally-on characteristics. Alternatively, when the oxide semiconductor contains nitrogen, a trap state is sometimes formed. This may make the electrical characteristics of the transistor unstable. Accordingly, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, still further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom generates an electron serving as a carrier. Thus, a transistor including an oxide semiconductor that contains hydrogen tends to have normally-on characteristics. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, still further preferably lower than 1×10¹⁸ atoms/cm³, yet still further preferably lower than 1×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for a channel formation region in a transistor, the transistor can have stable electrical characteristics.

This embodiment can be combined with any of the other embodiments as appropriate. In this specification, in the case where a plurality of structure examples are shown in one embodiment, the structure examples can be combined as appropriate.

### Embodiment 3

In this embodiment, an example of a method for operating a memory device of one embodiment of the present invention will be described. In a memory cell described below as an example, the transistor including the ferroelectric described in Embodiment 1 can be used.

### [Hysteresis Properties of Ferroelectric]

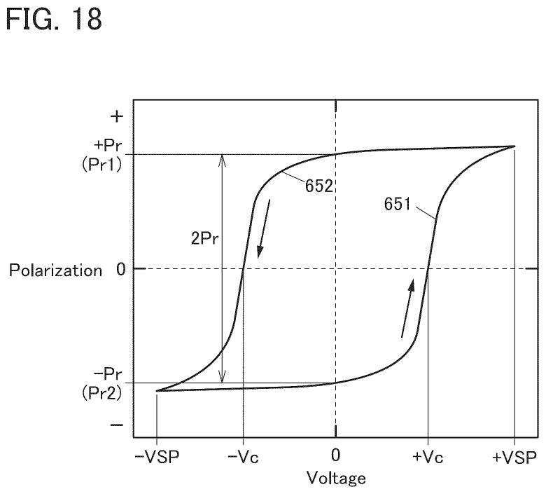

A ferroelectric has hysteresis properties. FIG. 18 is a graph showing an example of hysteresis properties of a ferroelectric. The hysteresis properties can be measured using a capacitor including a ferroelectric (a ferroelectric capacitor). In FIG. 18, the horizontal axis represents voltage (electric field) applied to the ferroelectric. The voltage is a potential difference between one electrode and the other electrode of the ferroelectric capacitor. The electric field strength can be obtained by dividing the potential difference by the thickness of the ferroelectric.

In FIG. 18, the vertical axis represents polarization of the ferroelectric. Positive polarization indicates that positive charge in the ferroelectric is concentrated on the one electrode side of the capacitor and negative charge is concentrated on the other electrode side of the capacitor. By contrast, negative polarization indicates that negative charge in the ferroelectric is concentrated on the one electrode side of the capacitor and positive charge is concentrated on the other electrode side of the capacitor.

Alternatively, the polarization represented by the vertical axis of the graph in FIG. 18 may be regarded as being positive when negative charge is concentrated on the one electrode side of the capacitor and positive charge is concentrated on the other electrode side of the capacitor, and regarded as being negative when positive charge is concentrated on the one electrode side of the capacitor and negative charge is concentrated on the other electrode side of the capacitor.

As shown in FIG. 18, the hysteresis properties of the ferroelectric can be represented by a curve 651 and a curve 652. Voltages at the intersections of the curve 651 and the curve 652 are referred to as a saturated polarization voltage +VSP (also referred to as “+VSP”) and a saturated polarization voltage −VSP (also referred to as “−VSP”). It can be said that +VSP and −VSP have different polarities.

When a voltage lower than or equal to −VSP is applied to the ferroelectric and then the voltage applied to the ferroelectric is increased, the polarization of the ferroelectric is increased along the curve 651. On the other hand, when a voltage higher than or equal to +VSP is applied to the ferroelectric and then the voltage applied to the ferroelectric is decreased, the polarization of the ferroelectric is decreased along the curve 652. Note that +VSP is sometimes referred to as a positive saturated polarization voltage or a first saturated polarization voltage. Moreover, −VSP is sometimes referred to as a negative saturated polarization voltage or a second saturated polarization voltage. The absolute value of the first saturation polarization voltage may be the same as or different from the absolute value of the second saturation polarization voltage.

The voltage at the time when the polarization of the ferroelectric changes along the curve 651 to reach 0 is referred to as a coercive voltage +Vc. The voltage at the time when the polarization of the ferroelectric changes along the curve 652 to reach 0 is referred to as a coercive voltage −Vc. The value of +Vc and the value of −Vc are each a value between +VSP and −VSP. In some cases, +Vc is referred to as a positive coercive voltage or a first coercive voltage, and −Vc is referred to as a negative coercive voltage or a second coercive voltage. The absolute value of the first coercive voltage may be the same as or different from the absolute value of the second coercive voltage.

The maximum value of polarization when voltage is not applied to the ferroelectric (when voltage is 0 V) is referred to as remanent polarization +Pr or remanent polarization Pr1, and the minimum value thereof is referred to as remanent polarization −Pr or remanent polarization Pr2. The absolute value of the difference between the remanent polarization +Pr and the remanent polarization −Pr is referred to as remanent polarization 2Pr. Larger remanent polarization 2Pr increases the range of a change in the capacitance of the ferroelectric capacitor due to polarization reversal. The remanent polarization 2Pr is preferably as large as possible.

### [Relation Between Polarization of Ferroelectric and Id-Vg Characteristics]

Next, a structure where a transistor is provided with a capacitor including a ferroelectric will be described. The relation between polarization of a ferroelectric included in a capacitor 620 and the Id-Vg characteristics of a transistor 610 will be described below.

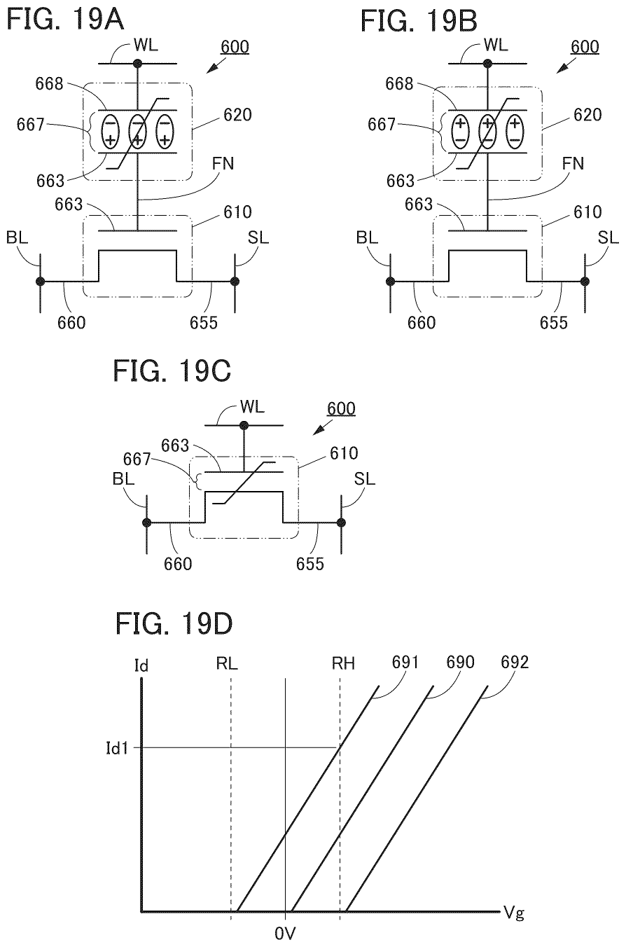

FIGS. 19A and 19B are equivalent circuit diagrams of a semiconductor device 600 including the transistor 610 and the capacitor 620 that is a ferroelectric capacitor. The capacitor 620 includes an electrode 663 serving also as a gate of the transistor 610, an electrode 668 connected to a wiring WL, and an insulating layer 667 between the electrodes 663 and 668. The transistor 610 includes the electrode 663, an electrode 660 connected to a wiring BL, and an electrode 655 connected to a wiring SL. The electrode 660 functions as one of a source electrode and a drain electrode, and the electrode 655 functions as the other of the source electrode and the drain electrode. The insulating layer 667 functions as a ferroelectric layer. FIGS. 19A and 19B schematically illustrate the polarization of the insulating layer 667. The electrode 663 can also be referred to as a node FN.

The semiconductor device 600 corresponds to a semiconductor device including the insulator 250 and the conductor 252 illustrated in FIG. 3E in Embodiment 1, and the insulating layer 667 of the capacitor 620 corresponds to the insulator 250d2 illustrated in FIG. 3E. Although the structure where the capacitor 620, which is a ferroelectric capacitor, is connected to the gate of the transistor 610 is described below, the present invention is not limited to this structure. A structure can be employed in which the insulating layer 667, which is a ferroelectric, is provided as a gate insulating layer of the transistor 610 without providing the capacitor 620 in the semiconductor device 600 as illustrated in FIG. 19C (such a structure can be referred to as an FeFET). Here, the electrode 663 of the transistor 610 is connected to the wiring WL. The semiconductor device 600 illustrated in FIG. 19C corresponds to the transistor 200 including the insulator 250 illustrated in FIGS. 3A to 3D in Embodiment 1. The operation principles and the operation method described below can also apply to the semiconductor device 600 illustrated in FIG. 19C.

FIG. 19D is a diagram showing the Id-Vg characteristics of the transistor 610 at the time when the voltage between the source and the drain (also referred to as drain voltage or Vd) is constant. In FIG. 19D, the horizontal axis represents a voltage between the source and the gate (also referred to as a gate voltage or Vg), and the vertical axis represents a current flowing between the source and the drain (also referred to as a drain current or Id).

In FIG. 19D, characteristics 690 indicate Id-Vg characteristics of the transistor 610 at the time when polarization is not caused in the insulating layer 667 included in the capacitor 620.

In FIG. 19D, characteristics 691 indicate Id-Vg characteristics of the transistor 610 at the time when the polarization of the insulating layer 667 is the remanent polarization Pr1. FIG. 19A schematically illustrates the polarization of the insulating layer 667 included in the capacitor 620 when the transistor 610 has the characteristics 691.

Since the remanent polarization Pr1 is positive polarization, a positive voltage is generated at the node FN. Thus, the Id-Vg characteristics 690 shift in the negative direction of Vg to be the characteristics 691. In other words, the threshold voltage of the transistor 610 shifts in the negative direction of Vg.

In FIG. 19D, characteristics 692 indicate Id-Vg characteristics of the transistor 610 at the time when the polarization of the insulating layer 667 is the remanent polarization Pr2. FIG. 19B schematically illustrates the polarization of the insulating layer 667 included in the capacitor 620 when the transistor 610 has the characteristics 692.

Since the remanent polarization Pr2 is negative polarization, a negative voltage is generated at the node FN. Thus, the Id-Vg characteristics 690 shift in the positive direction of Vg to be the characteristics 692. In other words, the threshold voltage of the transistor 610 shifts in the positive direction of Vg.

As illustrated in FIGS. 19A to 19C, the Id-Vg characteristics of the transistor 610 can be changed in accordance with the polarization of the insulating layer 667, which is a ferroelectric layer. In other words, the threshold voltage of the transistor 610 can be controlled by controlling the polarization of the insulating layer 667. Thus, the semiconductor device 600 including the transistor 610 and the capacitor 620 can function as a memory cell capable of retaining binary data.

For example, when binary data of data “0” or “1” is written to the semiconductor device 600 functioning as a memory cell, the polarization of the insulating layer 667 is changed to the remanent polarization Pr1 to write the data “1”, and the polarization of the insulating layer 667 is changed to the remanent polarization Pr2 to write the data “0”. The Id-Vg characteristics of the semiconductor device 600 to which the data “1” has been written become the characteristics 691. The Id-Vg characteristics of the semiconductor device 600 to which the data “0” has been written become the characteristics 692.

Next, erasing operation, writing operation, retention operation, and reading operation of the semiconductor device 600 will be described.

### <Erasing Operation>

Before data is written to the semiconductor device 600 functioning as a memory cell, data in the semiconductor device 600 needs to be erased. In this embodiment, operation of writing data “0” to the semiconductor device 600 is performed as the erasing operation. That is, the polarization of the insulating layer 667 is changed to the remanent polarization Pr2.

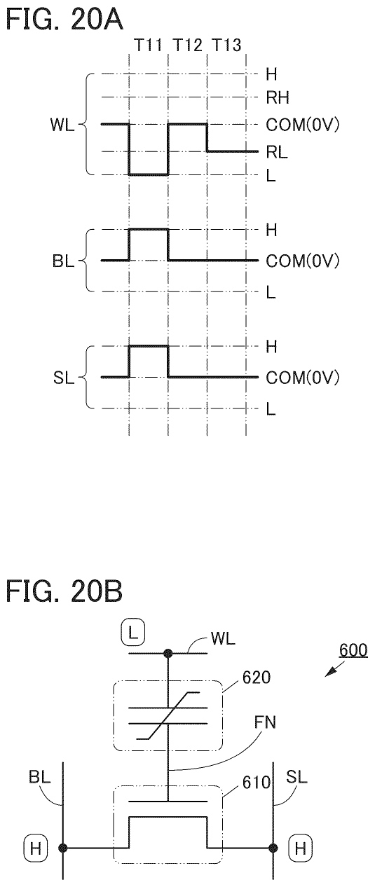

FIG. 20A is a timing chart for describing the erasing operation. FIG. 20B is a circuit diagram illustrating a state of the semiconductor device 600 in Period T11. Note that in a circuit diagram and the like, for easy understanding of a potential of a wiring or the like, a symbol showing the potential of the wiring is sometimes illustrated adjacent to the wiring or the like. Furthermore, an enclosed letter is sometimes written near a wiring or the like whose potential has changed.

In Period T11, a potential L is supplied to the wiring WL, and a potential H is supplied to the wiring BL and the wiring SL.

Note that the gate capacitance of the transistor 610 and the capacitor 620 are connected in series between the wirings WL and BL and between the wirings WL and SL. A voltage applied to the capacitor 620 is determined by the ratio of the gate capacitance of the transistor 610 to the capacitance of the capacitor 620. In this embodiment, the ratio of the gate capacitance of the transistor 610 to the capacitance of the capacitor 620 is 1:1. Accordingly, the difference between the potential H and the potential L is set to twice or more the absolute value of VSP. In order to change the polarization of the insulating layer 667 to the remanent polarization Pr2, the potential H is supplied to the wiring BL and the wiring SL, and the potential L is supplied to the wiring WL. The potential H is higher than the potential L.

For example, in the case where a potential COM is a reference potential (0 V), the potential H is higher than the potential COM and is different from the potential COM by +VSP. Similarly, the potential L is lower than the potential COM and is different from the potential COM by −VSP.

Under the above conditions, the potential L is supplied to the wiring WL and the potential H is supplied to the wiring BL and the wiring SL, whereby −VSP is applied to the capacitor 620. Next, in Period T12, 0 V is supplied to the wiring WL, the wiring BL, and the wiring SL. That is, the wiring WL, the wiring BL, and the wiring SL are made to have the same potential.

In Period T12, the polarization of the insulating layer 667 becomes the remanent polarization Pr2 (see FIG. 18). Since the remanent polarization Pr2 is negative polarization as described above, a negative voltage is generated at the node FN. Thus, the Id-Vg characteristics 690 shift in the positive direction of Vg to be the characteristics 692. That is, the threshold voltage of the transistor 610 shifts in the positive direction of Vg (see FIG. 19D).

In Period T13, a potential RL is supplied to the wiring WL. The potential RL will be described in detail in the description of the retention operation. Note that Period T12 may be omitted and Period T11 may be followed by Period T13. A negative voltage is generated at the node FN through Period T11 even when Period T12 is omitted.

### <Writing Operation>

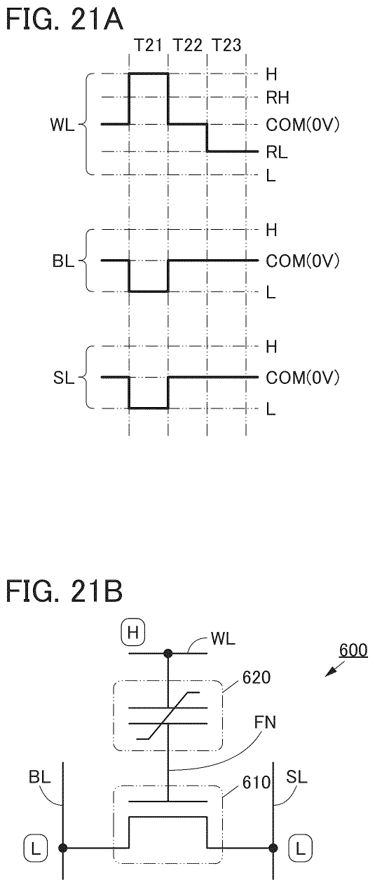

Next, operation of writing data “1” to the semiconductor device 600 functioning as a memory cell will be described. FIG. 21A is a timing chart for describing the writing operation. FIG. 21B is a circuit diagram illustrating a state of the semiconductor device 600 in Period T21.

After the erasing operation is performed in Period T11, the potential H is supplied to the wiring WL and the potential L is supplied to the wiring BL and the wiring SL in Period T21. Thus, +VSP is applied to the capacitor 620, and the polarization of the insulating layer 667 changes along the curve 651 (see FIG. 18). Then, in Period T22, 0 V is supplied to the wiring WL, the wiring BL, and the wiring SL. That is, the wiring WL, the wiring BL, and the wiring SL are made to have the same potential.

In Period T22, the polarization of the insulating layer 667 becomes the remanent polarization Pr1 (see FIG. 18). Since the remanent polarization Pr1 is positive polarization as described above, a positive voltage is generated at the node FN. Thus, the Id-Vg characteristics 690 shift in the negative direction of Vg to be the characteristics 691. That is, the threshold voltage of the transistor 610 shifts in the negative direction of Vg (see FIG. 19D).

In this manner, the data “1” can be written to the semiconductor device 600. Since the capacitor 620 is a ferroelectric capacitor, polarization of the insulating layer 667, which is a ferroelectric, is maintained even when power supply to the semiconductor device 600 stops. Thus, data written to the semiconductor device 600 is maintained even when power supply to the semiconductor device 600 stops. Accordingly, the semiconductor device 600 functions as a nonvolatile memory cell.

The operation of writing data “0” to the semiconductor device 600 is the same as the above-described erasing operation. Accordingly, there is no need to perform the operation of writing data “0” after the erasing operation.

### <Retention Operation>

After data is written to the semiconductor device 600, the potential RL is supplied to the wiring WL in Period T23. The potential RL is a potential at which the transistor 610 is turned off even when the Id-Vg characteristics of the transistor 610 are the characteristics 691 (see FIG. 19D). Thus, the potential RL is set to a potential lower than the threshold voltage of the characteristics 691. Moreover, in order to hardly cause a change in polarization of the insulating layer 667, the potential RL is set to a voltage with which a voltage applied to the capacitor 620 is higher than or equal to the coercive voltage −Vc.

After the writing operation, the potential of the wiring WL is preferably the potential RL until the reading operation is performed. When the potential of the wiring WL remains as the potential RL, the transistor 610 is surely brought into an off state; thus, power consumption of the semiconductor device 600 is reduced. Moreover, in the case where the semiconductor devices 600 are arranged in a matrix to form a memory cell array, interference in the reading operation of another memory cell (semiconductor device 600) can be prevented. Consequently, the memory cell array can have higher reliability.

Note that Period T22 may be omitted and Period T21 may be may be followed by Period T23.

### <Reading Operation>

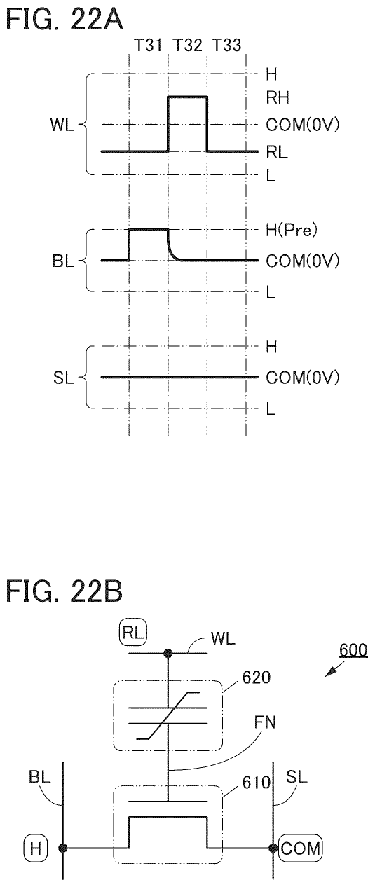

Next, operation of reading data retained in the semiconductor device 600 functioning as a memory cell will be described. FIG. 22A is a timing chart for describing the reading operation. FIG. 22B is a circuit diagram illustrating a state of the semiconductor device 600 in Period T31.

In this embodiment, the reading operation of the semiconductor device 600 that retains data “1” is described.

In Period T31, the wiring BL is precharged to the potential H. That is, after the potential of the wiring BL is set to the potential H, the wiring BL is brought into a floating state (a state where electric power is supplied from nowhere). In addition, the potential COM is supplied to the wiring SL.

Next, in Period T32, a potential RH that is a reading potential is supplied to the wiring WL. The potential RH is a potential higher than or equal to the threshold voltage of the characteristic 691 and lower than the threshold voltage of the characteristic 692. Moreover, in order to hardly cause a change in polarization of the insulating layer 667, the potential RH is set to a voltage with which the voltage applied to the capacitor 620 is lower than or equal to the coercive voltage +Vc.

In the case where the data “1” is retained in the semiconductor device 600, when the potential RH is supplied to the wiring WL, the transistor 610 is turned on, and a current Id1 flows between the source and the drain (see FIG. 19D). Thus, electrical continuity is established between the wiring BL and the wiring SL, and the potential of the wiring BL that is in a floating state changes toward the potential COM.

The case where the potential of the wiring BL changes after the potential RH is supplied to the wiring WL can be determined that the data “1” has been written to the semiconductor device 600. The case where it is judged that the potential of the wiring BL does not change even when the potential RH is supplied to the wiring WL can be determined that the data “0” has been written to the semiconductor device 600.

After the reading operation, the potential RL is supplied to the wiring WL in Period T33. Since the potential RH is set to a voltage with which the voltage applied to the capacitor 620 is lower than or equal to the coercive voltage +Vc, the polarization of the insulating layer 667 included in the capacitor 620 is less likely to change. Thus, non-destructive reading of the semiconductor device 600 can be achieved.

Note that the hysteresis properties of the ferroelectric change depending on the material, the structure, and the formation method. Accordingly, the potential RH is preferably a voltage with which the voltage applied to the capacitor 620 is 0.8 times or less, preferably 0.6 times or less the coercive voltage +Vc. Moreover, the potential RL is preferably a voltage with which the voltage applied to the capacitor 620 is 0.8 times or more, preferably 0.6 times or more the coercive voltage −Vc.

The above is the description of the method for operating the memory device.

At least part of this embodiment can be implemented as appropriate in combination with any of the other embodiments described in this specification.

### Embodiment 4

In this embodiment, a semiconductor device 900 of one embodiment of the present invention will be described. The semiconductor device 900 can function as a memory device.

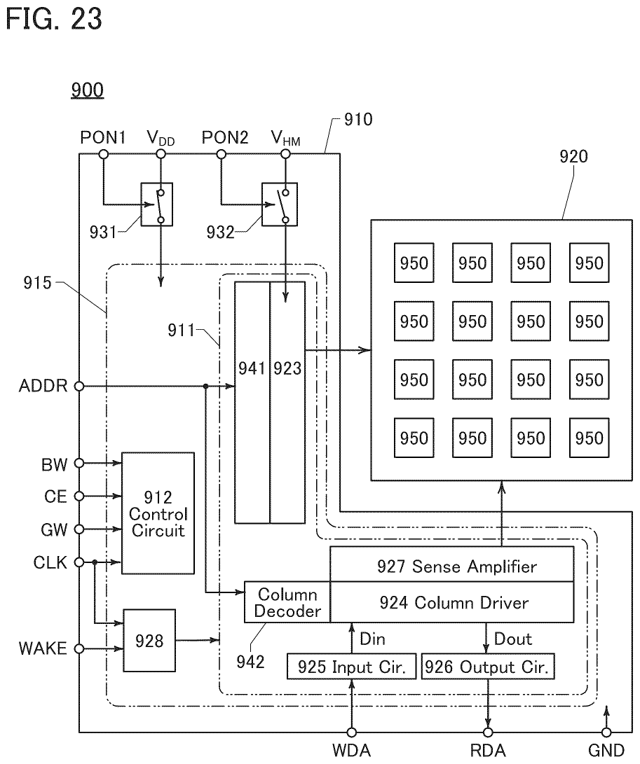

FIG. 23 is a block diagram illustrating a structure example of the semiconductor device 900. The semiconductor device 900 illustrated in FIG. 23 includes a driver circuit 910 and a memory array 920. The memory array 920 includes at least one memory cell 950. FIG. 23 illustrates an example in which the memory array 920 includes a plurality of the memory cells 950 arranged in a matrix.

The transistor exemplified in Embodiment 1 can be used for the memory cell 950. With the use of the transistor, the operating speed of the memory device can be increased. This also enables further miniaturization and higher integration of the memory device. In addition, the capacity per area of the memory device can be increased.

The driver circuit 910 includes a power switch (PSW) 931, a PSW 932, and a peripheral circuit 915. The peripheral circuit 915 includes a peripheral circuit 911, a control circuit 912, and a voltage generator circuit 928.

In the semiconductor device 900, whether to provide or use each circuit, each signal, and each voltage can be selected as appropriate. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., writing operation or reading operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is applied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925 (Input Cir.), an output circuit 926 (Output Cir.), and a sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has functions of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling the supply of V_{DD} to the peripheral circuit 915. The PSW 932 has a function of controlling the supply of V_{HM} to the row driver 923. Here, in the semiconductor device 900, a high power supply voltage is V_{DD} and a low power supply voltage is GND (ground potential). In addition, V_{HM} is a high power supply voltage used to set the word line to the H level and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 23 but can be more than one. In that case, a power switch is provided for each power domain.

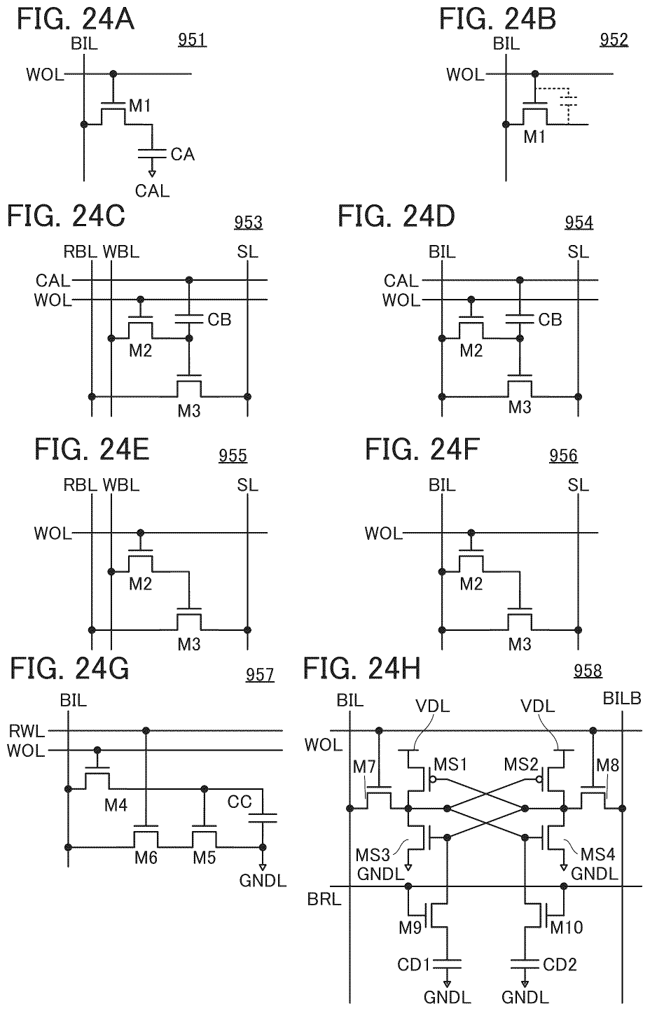

Structure examples of other memory cells each of which can be used as the memory cell 950 will be described with reference to FIGS. 24A to 24H.

### [DOSRAM]

FIG. 24A illustrates a circuit structure example of a memory cell for a DRAM. In this specification and the like, a DRAM using an OS transistor is referred to as a dynamic oxide semiconductor random access memory (DOSRAM). A memory cell 951 includes a transistor M1 and a capacitor CA.

Note that the transistor M1 may include a front gate (simply referred to as a gate in some cases) and a back gate. The back gate may be connected to a wiring supplied with a constant potential or a signal. The front gate and the back gate may be connected to each other.

A first terminal of the transistor M1 is connected to a first terminal of the capacitor CA. A second terminal of the transistor M1 is connected to a wiring BIL. The gate of the transistor M1 is connected to a wiring WOL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. At the time of data writing and reading, a low-level potential (sometimes referred to as a reference potential) is preferably applied to the wiring CAL.

Data writing and data reading are performed as follows: a high-level potential is applied to the wiring WOL to turn on the transistor M1, and thus the wiring BIL is connected to the first terminal of the capacitor CA.

The memory cell that can be used as the memory cell 950 is not limited to the memory cell 951, and the circuit structure can be changed. For example, the structure of a memory cell 952 illustrated in FIG. 24B may be employed. The memory cell 952 is an example including neither the capacitor CA nor the wiring CAL. The first terminal of the transistor M1 is in an electrically floating state.

In the memory cell 952, a potential written through the transistor M1 is retained in a capacitor (also referred to as parasitic capacitance) between the first terminal and the gate, which is shown by a dashed line. Thus, the structure of the memory cell can be greatly simplified.

Note that the transistor M1 is preferably the OS transistor described in Embodiment 1. The use of the OS transistor described in Embodiment 1 enables an increase in the operating speed of the memory device. It also enables a reduction in the area occupied by the memory cell. An OS transistor has a characteristic of an extremely low off-state current. The use of an OS transistor as the transistor M1 enables an extremely low leakage current of the transistor M1. That is, with the use of the transistor M1, written data can be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cells 951 and 952.

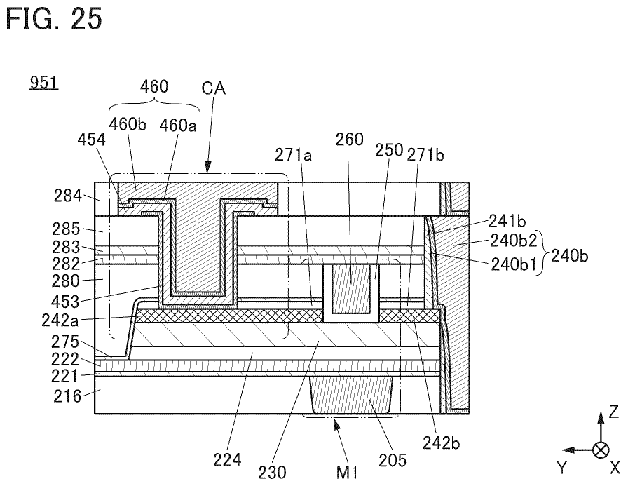

Here, an example of the structure of a DOSRAM is described with reference to FIG. 25. In FIG. 25, the X direction is parallel to the channel width direction of an illustrated transistor, the Y direction is perpendicular to the X direction, and the Z direction is perpendicular to the X direction and the Y direction.

As illustrated in FIG. 25, the memory cell 951 includes the transistor M1 and the capacitor CA. An insulator 284 is provided over the transistor M1. Any of the insulators that can be used as the insulator 216 is used as the insulator 284. Note that the transistor M1 has the same structure as the transistor 200 described in Embodiment 1, and the same components are denoted by the same reference numerals. Embodiment 1 can be referred to for the details of the transistor 200. The conductor 240b (conductors 240b1 and 240b2) is provided in contact with one of a source electrode and a drain electrode (the conductor 242b) of the transistor M1. The conductor 240b extends in the Z direction and functions as the wiring BIL. The conductor 260 of the transistor 200 extends in the X direction and functions as the wiring WOL.

The capacitor CA includes a conductor 453 over the conductor 242a, an insulator 454 over the conductor 453, and a conductor 460 (conductors 460a and 460b) over the insulator 454.

At least parts of the conductor 453, the insulator 454, and the conductor 460 are positioned inside an opening portion formed in the insulators 271a, 275, 280, 282, 283, and 285. End portions of the conductor 453, the insulator 454, and the conductor 460 are positioned at least over the insulator 283, and preferably positioned over the insulator 285. The insulator 454 is provided to cover the end portion of the conductor 453. This enables the conductors 453 and 460 to be electrically insulated from each other.

The deeper the opening portion formed in the insulators 271a, 275, 280, 282, 283, and 285 is (i.e., the larger the thickness of at least one of the insulators 271a, 275, 280, 282, 283, and 285 is), the larger the electrostatic capacitance of the capacitor CA can be. Increasing the electrostatic capacitance per unit area of the capacitor CA enables further miniaturization and higher integration of the memory device.

The conductor 453 includes a region functioning as the one electrode (a lower electrode) of the capacitor CA. The insulator 454 includes a region functioning as a dielectric of the capacitor CA. The conductor 460 includes a region functioning as the other electrode (an upper electrode) of the capacitor CA. An upper portion of the conductor 460 can be extended to function as the wiring CAL. The capacitor CA is a metal-insulator-metal (MIM) capacitor.

The conductor 242a provided to overlap the oxide semiconductor 230 functions as an electrode that is electrically connected to the lower electrode of the capacitor CA.

Each of the conductors 453 and 460 included in the capacitor CA can be formed using any of the conductors that can be used for the conductor 205 or the conductor 260. The conductors 453 and 460 are preferably deposited by a formation method that enables excellent coverage, such as an ALD method or a CVD method. For example, titanium nitride or tantalum nitride deposited by an ALD method or a CVD method can be used for the conductor 453.

The top surface of the conductor 242a is in contact with the bottom surface of the conductor 453. Here, the contact resistance between the conductor 453 and the conductor 242a can be reduced when the conductor 242a is formed using a conductive material with high conductivity.

Titanium nitride deposited by an ALD method or a CVD method can be used for the conductor 460a, and tungsten deposited by a CVD method can be used for the conductor 460b. In the case where the adhesion of tungsten to the insulator 454 is sufficiently high, the conductor 460 may have a single-layer structure of tungsten deposited by a CVD method.

For the insulator 454 included in the capacitor CA, the high dielectric constant (high-k) material described in the above embodiment is preferably used. Using such a high-k material allows the insulator 454 to be thick enough to inhibit a leakage current and a sufficiently high capacitance of the capacitor CA to be ensured. The insulator 454 is preferably deposited by a formation method that enables excellent coverage, such as an ALD method or a CVD method.

It is preferable to use stacked insulators each formed of any of the above-described materials. A stacked-layer structure including a high dielectric constant (high-k) material and a material having higher dielectric strength than the high dielectric constant (high-k) material is preferably used. For example, as the insulator 454, an insulator in which zirconium oxide, aluminum oxide, and zirconium oxide are stacked in this order can be used. For another example, an insulator in which zirconium oxide, aluminum oxide, zirconium oxide, and aluminum oxide are stacked in this order can be used. For another example, an insulator in which hafnium zirconium oxide, aluminum oxide, hafnium zirconium oxide, and aluminum oxide are stacked in this order can be used. The stacking of such an insulator having relatively high dielectric strength, such as aluminum oxide, can increase the dielectric strength and inhibit electrostatic breakdown of the capacitor CA.

A material that can show ferroelectricity may be used for the insulator 454. Examples of the material that can show ferroelectricity include metal oxides such as hafnium oxide, zirconium oxide, and hafnium zirconium oxide (HfZrO_{X} (X is a real number greater than 0)). Another example of the material that can show ferroelectricity is a material in which an element J1 (the element J1 here is one or more of zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 is, for example, 1:1 or the neighborhood thereof. Another example of the material that can show ferroelectricity is a material in which an element J2 (the element J2 here is one or more of hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or the neighborhood thereof. Note that in the above material, lanthanoid may be used instead of lanthanum. As the material that can show ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Another example of the material that can show ferroelectricity is a metal nitride containing an element M1, an element M2, and nitrogen. Here, the element M1 is one or more of aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen shows ferroelectricity in some cases even though the metal oxide does not contain the element M2. Another example of the material that can show ferroelectricity is the above metal nitride to which an element M3 is added. Note that the element M3 is one or more of magnesium, calcium, strontium, zinc, cadmium, and the like. Here, the atomic ratio between the element M1, the element M2, and the element M3 can be set as appropriate.

Other examples of the material that can show ferroelectricity include perovskite-type oxynitrides such as SrTaO₂N and BaTaO₂N, and GaFeO₃ with a κ-alumina-type structure.

Although metal oxides and metal nitrides are described above as examples, one embodiment of the present invention is not limited thereto. For example, a metal oxynitride obtained by adding nitrogen to any of the above-described metal oxides, a metal nitride oxide obtained by adding oxygen to any of the above-described metal nitrides, or the like may be used.

As the material that can show ferroelectricity, a mixture or compound containing a plurality of materials selected from the above-listed materials can be used, for example. Alternatively, the insulator 454 can have a stacked-layer structure of a plurality of materials selected from the above-listed materials. Since the above-listed materials and the like may change their crystal structures (characteristics) according to a variety of processes and the like as well as deposition conditions, a material that exhibits ferroelectricity is referred to not only as a ferroelectric but also as a material that can show ferroelectricity in this specification and the like.

The ferroelectric refers to an insulator having properties of causing internal polarization by application of an electric field from the outside and maintaining the polarization even after the electric field is made zero. Thus, with the use of a capacitor that includes this material as a dielectric (hereinafter, such a capacitor is sometimes referred to as a ferroelectric capacitor), a nonvolatile memory element can be formed. A nonvolatile memory element including a ferroelectric capacitor is sometimes referred to as a ferroelectric random access memory (FeRAM), a ferroelectric memory, or the like. For example, a ferroelectric memory includes a transistor and a ferroelectric capacitor, and one of a source and a drain of the transistor is electrically connected to one terminal of the ferroelectric capacitor. Thus, in the case of using a ferroelectric capacitor as the capacitor CA, the memory device described in this embodiment functions as a ferroelectric memory.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulator 454 can exhibit ferroelectricity, the insulator 454 needs to include a crystal. It is particularly preferable that the insulator 454 include a crystal having an orthorhombic crystal structure, in which case ferroelectricity is exhibited. A crystal included in the insulator 454 may have one or more of crystal structures selected from cubic, tetragonal, orthorhombic, monoclinic, and hexagonal crystal structures. Alternatively, the insulator 454 may have an amorphous structure. In that case, the insulator 454 may have a composite structure including an amorphous structure and a crystal structure.

The deeper the opening portion formed in the insulators 271a, 275, 280, 282, 283, and 285 is (i.e., the larger the thickness of at least one of the insulators 271a, 275, 280, 282, 283, and 285 is), the larger the electrostatic capacitance of the capacitor CA can be. For example, the electrostatic capacitance of the capacitor CA can be set by adjusting the thickness of the insulator 285. Specifically, the thickness of the insulator 285 is set within the range from 50 nm to 250 nm, and the depth of the opening is approximately greater than or equal to 150 nm and less than or equal to 350 nm. When the capacitor CA is formed with the thickness of the insulator 285 and the depth of the opening within the above ranges, the capacitor CA can have adequate electrostatic capacitance, and the height of one layer can be prevented from being excessively large in a semiconductor device in which a plurality of memory cell layers are stacked. Note that capacitors provided in memory cells may have different electrostatic capacitances between the plurality of memory cell layers. In this structure, the insulators 285 provided in the memory cell layers may have different thicknesses, for example.

Note that the sidewall of the opening portion in which the capacitor CA is positioned and which is formed in the insulator 285 and the like may be substantially perpendicular to the top surface of the insulator 222 or may be tapered. The tapered shape of the sidewall can improve the coverage with the conductor 453 and the like provided in the opening formed in the insulator 285 and the like; as a result, the number of defects such as voids can be reduced.

The conductor 242b provided over the oxide semiconductor 230 functions as a wiring electrically connected to the conductor 240b. For example, in FIG. 25, the top surface and a side end portion of the conductor 242b are electrically connected to the conductor 240b extending the Z direction.

When the conductor 240b is directly in contact with at least one of the top surface and the side end portion of the conductor 242b, a separate electrode for connection does not need to be provided, so that the area occupied by the memory array can be reduced. In addition, the integration degree of the memory cells is increased, so that the memory capacity of the memory device can be increased. Note that the conductor 240b is preferably in contact with the side end portion and part of the top surface of the conductor 242b. When the conductor 240b is in contact with a plurality of surfaces of the conductor 242b, the contact resistance between the conductors 240b and 242b can be reduced.

The conductor 240b is provided in an opening formed in the insulators 216, 221, 222, 224, 271b, 275, 280, 282, 283, 285, and 284.

As illustrated in FIG. 25, the insulator 241b is preferably provided in contact with a side surface of the conductor 240b. Specifically, the insulator 241b is provided in contact with an inner wall of the opening portion formed in the insulators 216, 221, 222, 224, 271b, 275, 280, 282, 283, 285, and 284. The insulator 241b is formed also on a side surface of the oxide semiconductor 230 protruding in the opening. Note that at least part of the conductor 242b is exposed from the insulator 241b and is in contact with the conductor 240b. That is, the conductor 240b is provided to fill the opening portion with the insulator 241b between the inner wall of the opening portion and the conductor 240b.

Note that as illustrated in FIG. 25, an uppermost portion of the insulator 241b formed below the conductor 242b is preferably positioned below the top surface of the conductor 242b. With such a structure, the conductor 240b can be in contact with at least part of the side end portion of the conductor 242b. The insulator 241b formed below the conductor 242b preferably includes a region in contact with the side surface of the oxide semiconductor 230. This structure can inhibit impurities contained in the insulator 280 and the like, such as water and hydrogen, from entering the oxide semiconductor 230 through the conductor 240b.

The sidewall of the opening in which the conductor 240b and the insulator 241b are provided may be perpendicular or substantially perpendicular to the top surface of the insulator 222 or may be tapered. The tapered sidewall can improve the coverage with the insulator 241b and the like provided in the opening portion.

### [NOSRAM]

FIG. 24C illustrates a circuit structure example of a gain memory cell including two transistors and one capacitor. A memory cell 953 includes a transistor M2, a transistor M3, and a capacitor CB. In this specification and the like, a memory device including a gain memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to a wiring WBL. A gate of the transistor M2 is connected to the wiring WOL. A second terminal of the capacitor CB is connected to the wiring CAL. A first terminal of the transistor M3 is connected to a wiring RBL. A second terminal of the transistor M3 is connected to the wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing, data retention, and data reading, a low-level potential (sometimes referred to as a reference potential) is preferably applied to the wiring CAL.

Data writing is performed by applying a high-level potential to the wiring WOL to turn on the transistor M2, thereby connecting the wiring WBL to the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. A current flowing between the source and the drain of the transistor M3 and the potential of the first terminal of the transistor M3 are determined by the potential of the gate of the transistor M3 and the potential of the second terminal of the transistor M3. Accordingly, by reading a potential of the wiring RBL connected to the first terminal of the transistor M3, a potential retained at the first terminal of the capacitor CB (or the gate of the transistor M3) can be read. That is, data written to the memory cell can be read on the basis of the potential retained at the first terminal of the capacitor CB (or the gate of the transistor M3).

As another example, one wiring BIL may be provided instead of the wiring WBL and the wiring RBL. A circuit structure example of the memory cell is illustrated in FIG. 24D. In a memory cell 954, one wiring BIL is provided instead of the wiring WBL and the wiring RBL in the memory cell 953, and the second terminal of the transistor M2 and the first terminal of the transistor M3 are connected to the wiring BIL. In other words, one wiring BIL operates as the write bit line and the read bit line in the memory cell 954.

A memory cell 955 illustrated in FIG. 24E is an example in which the capacitor CB and the wiring CAL in the memory cell 953 are omitted. A memory cell 956 illustrated in FIG. 24F is an example in which the capacitor CB and the wiring CAL in the memory cell 954 are omitted. Such structures enable high integration of memory cells.

Note that at least the transistor M2 is preferably the OS transistor described in Embodiment 1. It is particularly preferable that the transistor M2 and the transistor M3 each be the OS transistor described in Embodiment 1. The use of the OS transistor described in Embodiment 1 enables an increase in the operating speed of the memory device. It also enables a reduction in the area occupied by the memory cell.

Since the OS transistor has a characteristic of an extremely low off-state current, written data can be retained for a long time with the use of the transistor M2, and thus the frequency of refresh operation for the memory cell can be decreased. Alternatively, refresh operation for the memory cell can be omitted. In addition, owing to an extremely low leakage current, multilevel data or analog data can be retained in the memory cells 953, 954, 955, and 956.

The memory cells 953, 954, 955, and 956 each using the OS transistor as the transistor M2 are embodiments of the NOSRAM.

Note that the transistor M3 may be a Si transistor. The Si transistor can have high field-effect mobility and can be formed as a p-channel transistor, so that circuit design flexibility can be increased.

When the OS transistor is used as the transistor M3, the memory cell can be configured with the transistors having the same conductivity type.

FIG. 24G illustrates an example of a gain memory cell 957 including three transistors and one capacitor. The memory cell 957 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed by applying a high-level potential to the wiring WOL to turn on the transistor M4, thereby connecting the wiring BIL to the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL to a predetermined potential, and then making the wiring BIL in an electrically floating state and applying a high-level potential to the wiring RWL. Since the wiring RWL has the high-level potential, the transistor M6 is turned on, so that the wiring BIL is electrically connected to the second terminal of the transistor M5. At this time, the potential of the wiring BIL is applied to the second terminal of the transistor M5; the potential of the second terminal of the transistor M5 and the potential of the wiring BIL change depending on the potential retained at the first terminal of the capacitor CC (or the gate of the transistor M5). Here, the potential retained at the first terminal of the capacitor CC (or the gate of the transistor M5) can be read by reading the potential of the wiring BIL. That is, data written to the memory cell can be read on the basis of the potential retained at the first terminal of the capacitor CC (or the gate of the transistor M5).

Note that at least the transistor M4 is preferably the OS transistor described in Embodiment 1. The use of the OS transistor described in Embodiment 1 enables a reduction in the area occupied by the memory cell.

Note that the transistors M5 and M6 may be Si transistors. As described above, a Si transistor may have higher field-effect mobility than the OS transistor depending on the crystal state of silicon used in a semiconductor layer, for example.

When OS transistors are used as the transistors M5 and M6, the memory cell can be configured with the transistors having the same conductivity type.

### [OS-SRAM]

FIG. 24H illustrates an example of a static random access memory (SRAM) using an OS transistor. In this specification and the like, an SRAM using an OS transistor is referred to as an oxide semiconductor SRAM (OS-SRAM). A memory cell 958 illustrated in FIG. 24H is a memory cell of an SRAM capable of backup operation.

The memory cell 958 includes transistors M7 to M10, transistors MS1 to MS4, a capacitor CD1, and a capacitor CD2. The transistors MS1 and MS2 are p-channel transistors, and the transistors MS3 and MS4 are n-channel transistors.

A first terminal of the transistor M7 is connected to the wiring BIL. A second terminal of the transistor M7 is connected to a first terminal of the transistor MS1, a first terminal of the transistor MS3, a gate of the transistor MS2, a gate of the transistor MS4, and a first terminal of the transistor M10. Agate of the transistor M7 is connected to the wiring WOL. A first terminal of the transistor M8 is connected to a wiring BILB. A second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is electrically connected to a wiring VDL. A second terminal of the transistor MS2 is electrically connected to the wiring VDL. A second terminal of the transistor MS3 is electrically connected to the wiring GNDL. A second terminal of the transistor MS4 is electrically connected to the wiring GNDL.

A second terminal of the transistor M9 is connected to a first terminal of the capacitor CD1. A gate of the transistor M9 is connected to a wiring BRL. A second terminal of the transistor M10 is connected to a first terminal of the capacitor CD2. A gate of the transistor M10 is connected to the wiring BRL.

A second terminal of the capacitor CD1 is connected to the wiring GNDL. A second terminal of the capacitor CD2 is connected to the wiring GNDL.

The wiring BIL and the wiring BILB function as bit lines. The wiring WOL functions as a word line. The wiring BRL controls the on/off states of the transistors M9 and M10.

The wiring VDL supplies a high-level potential. The wiring GNDL supplies a low-level potential.

Data writing is performed by applying a high-level potential to the wiring WOL and the wiring BRL. Specifically, when the transistor M10 is on, a potential corresponding to data to be stored is applied to the wiring BIL, and the potential is written to the second terminal side of the transistor M10.

In the memory cell 958, the transistors MS1 and MS2 form an inverter loop; hence, an inversion signal of a data signal corresponding to the potential is input to the second terminal side of the transistor M8. Since the transistor M8 is on, an inversion signal of the potential applied to the wiring BIL (i.e., the signal input to the wiring BIL) is output to the wiring BILB. Since the transistor M9 and the transistor M10 are on, the potential of the second terminal of the transistor M7 is retained at the first terminal of the capacitor CD2, and the potential of the second terminal of the transistor M8 is retained at the first terminal of the capacitor CD1. After that, a low-level potential is applied to the wiring WOL and the wiring BRL to turn off the transistors M7 to M10, whereby the potential of the first terminal of the capacitor CD1 and the potential of the first terminal of the capacitor CD2 are retained.

Data reading is performed by precharging the wiring BIL and the wiring BILB with a predetermined potential, and then applying a high-level potential to the wiring WOL and the wiring BRL, whereby the potential of the first terminal of the capacitor CD1 is refreshed by the inverter loop in the memory cell 958 and output to the wiring BILB. Furthermore, the potential of the first terminal of the capacitor CD2 is refreshed by the inverter loop in the memory cell 958 and output to the wiring BIL. Since the potentials of the wiring BIL and the wiring BILB are changed from the precharged potentials to the potentials of the first terminal of the capacitor CD2 and the first terminal of the capacitor CD1, the potential retained in the memory cell can be read on the basis of the potentials of the wiring BIL and the wiring BILB.

Note that the transistors M7 to M10 are preferably OS transistors. In this case, with the use of the transistors M7 to M10, written data can be retained for a long time, and thus the frequency of refresh operation for the memory cell can be decreased. Alternatively, refresh operation for the memory cell can be omitted. The use of the OS transistors described in Embodiment 1 as the transistors M7 to M10 enables an increase in the operating speed of the memory device. It also enables a reduction in the area occupied by the memory cell.

Note that the transistors MS1 to MS4 may be Si transistors.

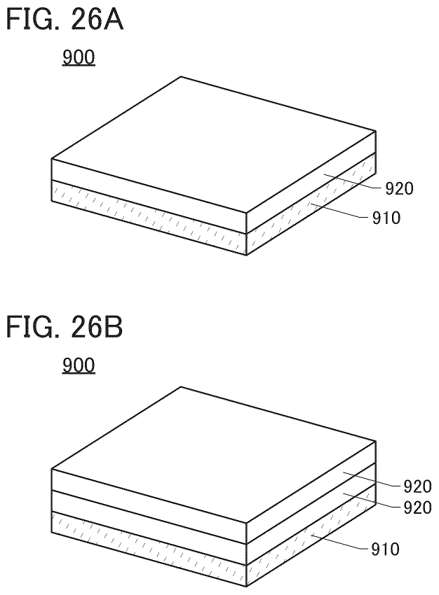

The driver circuit 910 and the memory array 920 included in the semiconductor device 900 may be provided on the same plane. Alternatively, as illustrated in FIG. 26A, the driver circuit 910 and the memory array 920 may be provided to overlap with each other. Overlapping the driver circuit 910 and the memory array 920 can shorten a signal transmission distance. As illustrated in FIG. 26B, a plurality of memory arrays 920 may be stacked over the driver circuit 910.

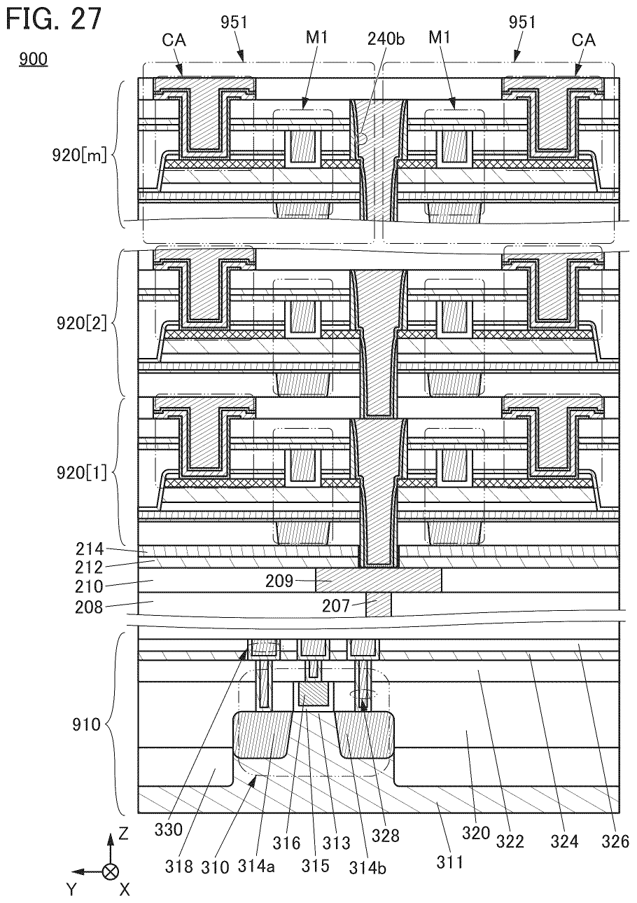

Here, a structure example of the semiconductor device 900 in which a plurality of memory arrays 920 are stacked is described with reference to FIG. 27.

The semiconductor device 900 illustrated in FIG. 27 includes a driver circuit 910 that is a layer including a transistor 310 and the like and memory arrays 920[1] to 920[m] over the driver circuit 910. Here, FIG. 27 illustrates the memory array 920[1] as the layer provided in the first layer (the bottom layer), the memory array 920[2] as the layer provided in the second layer, and the memory array 920[m] as the layer provided in the m-th layer (the top layer). In other words, the memory device of one embodiment of the present invention may include a plurality of layers including memory cells and have a structure in which the plurality of layers are stacked.

FIG. 27 illustrates an example of the transistor 310 included in the driver circuit 910. The transistor 310 is provided on a substrate 311 and includes a conductor 316 functioning as a gate, an insulator 315 functioning as a gate insulator, a semiconductor region 313 that includes part of the substrate 311, and a low-resistance region 314a and a low-resistance region 314b each functioning as a source region or a drain region. An element isolation layer 318 is preferably provided between adjacent transistors 310. The transistor 310 may be a p-channel transistor or an n-channel transistor. As the substrate 311, a single crystal silicon substrate can be used, for example.

In the transistor 310, the semiconductor region 313 (part of the substrate 311) where a channel is formed has a protruding shape. The conductor 316 is provided to cover the side and top surfaces of the semiconductor region 313 with the insulator 315 therebetween. Note that the conductor 316 may be formed using a material for adjusting the work function. The transistor 310 is also referred to as a FIN-type transistor because it utilizes a projecting portion of a semiconductor substrate. An insulator functioning as a mask for forming the projecting portion may be provided in contact with the top surface of the projecting portion. Although the case where the projecting portion is formed by processing part of the semiconductor substrate is described here, a semiconductor film having a projecting shape may be formed by processing an SOI substrate.

Note that the transistor 310 illustrated in FIG. 27 is an example and the structure is not limited thereto; an appropriate transistor can be used in accordance with a circuit structure or a driving method.

A wiring layer including an interlayer film, a wiring, a plug, and the like may be provided between components. A plurality of wiring layers can be provided in accordance with the design. Note that a plurality of conductors functioning as plugs or wirings are collectively denoted by the same reference numeral in some cases. In this specification and the like, a wiring and a plug electrically connected to the wiring may be a single component. That is, in some cases, part of a conductor functions as a wiring or part of a conductor functions as a plug.

For example, an insulator 320, an insulator 322, an insulator 324, and an insulator 326 are sequentially stacked over the transistor 310 as interlayer films. A conductor 328 and the like are embedded in the insulators 320 and 322. A conductor 330 and the like are embedded in the insulators 324 and 326. Note that the conductor 328 and the conductor 330 function as a contact plug or a wiring.

The insulators functioning as an interlayer film may function as a planarization film that covers a roughness thereunder. For example, the top surface of the insulator 322 may be planarized by planarization treatment using a CMP method to improve the planarity.

Examples of an insulator that can be used for an interlayer film include an insulating oxide, an insulating nitride, an insulating oxynitride, an insulating nitride oxide, an insulating metal oxide, an insulating metal oxynitride, and an insulating metal nitride oxide.

For example, when a material having a low dielectric constant is used for the insulator functioning as an interlayer film, the parasitic capacitance between wirings can be reduced. Thus, a material is preferably selected depending on the function of an insulator.

An insulator 208 is provided over the driver circuit 910, and a conductor 207 is provided in an opening formed in the insulator 208. An insulator 210 is provided over the insulator 208, and a conductor 209 is provided in an opening formed in the insulator 210. The insulator 212 is provided over the insulator 210, and the insulator 214 is provided over the insulator 212. Part of the conductor 240b provided in the memory array 920[1] is embedded in an opening formed in the insulators 212 and 214. Here, for the insulators 208 and 210, an insulator that can be used for the insulator 216 can be used.

The conductor 207 functions as a wiring electrically connected to the driver circuit 910. The top surface of the conductor 207 is provided in contact with the bottom surface of the conductor 209. The top surface of the conductor 209 is provided in contact with the bottom surface of the conductor 240b provided in the memory array 920[1]. With this structure, the conductor 240b corresponding to the wiring BIL can be electrically connected to the driver circuit 910.

Each of the memory arrays 920[1] to 920[m] includes a plurality of the memory cells 951. The conductor 240b of each of the memory cells 951 is electrically connected to the conductor 240b in an upper layer and to the conductor 240b in a lower layer.

As illustrated in FIG. 27, the conductor 240b is shared between the adjacent memory cells 951. The structures of the adjacent memory cells 951 are symmetrical with respect to the conductor 240b.

In the above memory array 920, the plurality of memory arrays 920[1] to 920[m] can be stacked. The memory arrays 920[1] to 920[m] included in the memory array 920 are provided in a direction perpendicular to the surface of a substrate on which the driver circuit 910 is provided, in which case the memory density of the memory cells 951 can be increased. The memory array 920 can be formed by repeating the same manufacturing process in the perpendicular direction. The manufacturing cost of the memory array 920 in the semiconductor device 900 can be reduced.

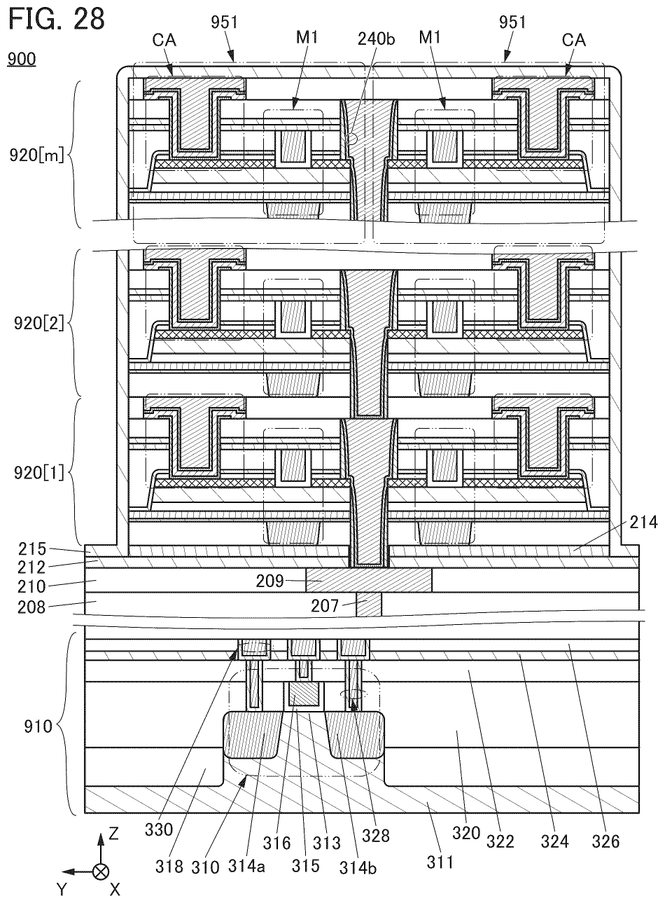

As illustrated in FIG. 28, an insulator 215 can be provided to cover the memory arrays 920[1] to 920[m]. Here, for the insulator 215, an insulating material similar to that for the insulator 212 can be used, and the above-described insulator having a function of inhibiting diffusion of hydrogen is preferably used. For example, silicon nitride is preferably used for the insulator 215.

As illustrated in FIG. 28, the insulator 215 is preferably provided in contact with the top surface of the insulator 212. With this structure, the memory arrays 920[1] to 920[m] can be sealed with the insulator 215 and the insulator 212. This can inhibit entry of hydrogen into the memory arrays 920[1] to 920[m] from the outside. It is thus possible to inhibit deterioration of the electrical characteristics and reliability of the OS transistors included in the memory arrays 920[1] to 920[m].

Although FIG. 28 illustrates a structure in which the memory arrays 920[1] to 920[m] are collectively covered with the insulator 215, the present invention is not limited thereto. For example, the memory arrays 920[1] to 920[m] may be individually covered with different insulators 215.

Next, description is made on an example of an arithmetic processing device that can include a semiconductor device such as the memory device described above.

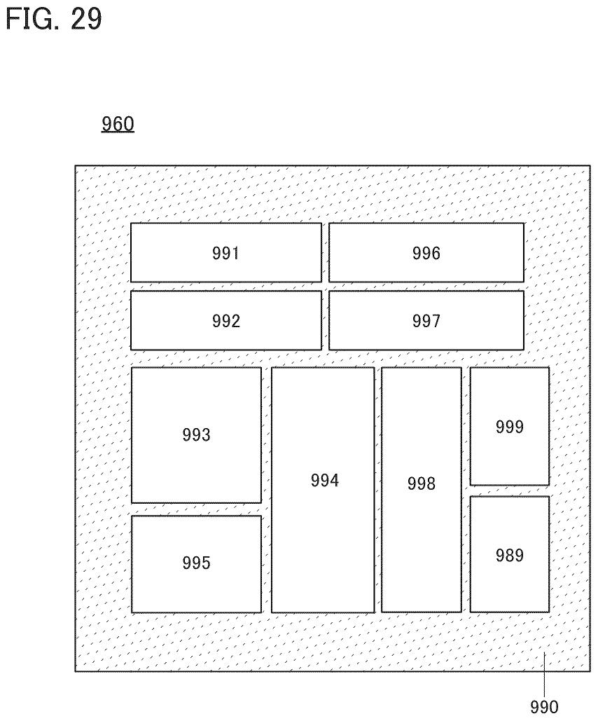

FIG. 29 is a block diagram of an arithmetic device 960. The arithmetic device 960 illustrated in FIG. 29 can be used for a central processing unit (CPU), for example. The arithmetic device 960 can also be used for a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 29 includes, over a substrate 990, an arithmetic logic unit (ALU) 991, an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. In that case, the cache interface 989 may have a function of supplying data retained in the memory array 920 to the cache 999. Moreover, in that case, the driver circuit 910 is preferably included in part of the cache interface 989.

Note that it is also possible that the cache 999 is not provided and only the memory array 920 is used as a cache.

The arithmetic device 960 illustrated in FIG. 29 is only an example with a simplified structure, and the actual arithmetic device 960 has a variety of structures depending on the application. For example, it is preferable to employ what is called a multicore structure in which a plurality of cores each including the arithmetic device 960 in FIG. 29 operate in parallel. The larger number of cores can further enhance the arithmetic performance. The number of cores is preferably larger; for example, the number is preferably 2, further preferably 4, further preferably 8, still further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 998 is input to the instruction decoder 993 and decoded, which is then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 judges and processes an interrupt request from an external input/output device, a peripheral circuit, or the like on the basis of its priority, a mask state, or the like while the arithmetic device 960 is executing a program. The register controller 997 generates the address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above circuits.

In the arithmetic device 960 in FIG. 29, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, a power supply voltage is supplied to the memory cell in the register 996. When data retention by the capacitor is selected, the data is rewritten into the capacitor, and supply of the power supply voltage to the memory cell in the register 996 can be stopped.

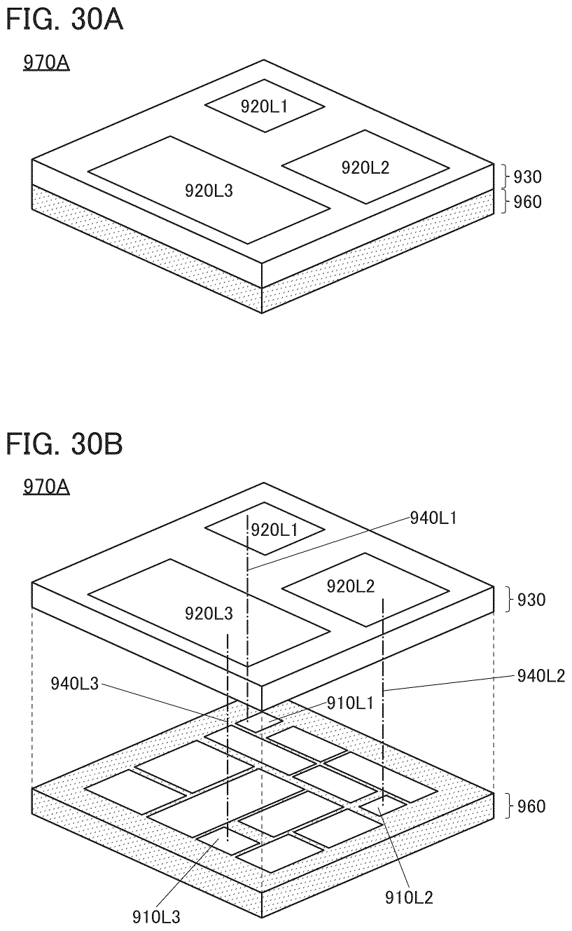

The memory array 920 and the arithmetic device 960 can be provided to overlap with each other. FIGS. 30A and 30B are perspective views of a semiconductor device 970A. The semiconductor device 970A includes, over the arithmetic device 960, a layer 930 provided with memory arrays. A memory array 920L1, a memory array 920L2, and a memory array 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 30B.

Overlapping the arithmetic device 960 and the layer 930 including the memory arrays can shorten the connection distance therebetween. Accordingly, the communication speed therebetween can be increased. Moreover, a short connection distance leads to lower power consumption.

As a method for stacking the layer 930 including the memory arrays and the arithmetic device 960, either of the following methods may be employed: a method in which the layer 930 including the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are electrically connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In this case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 30B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

In this example, the three memory arrays function as caches; however, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuits 910L2 and 910L3 may function as part of the cache interface 989 or be connected to the cache interface 989.

Whether the memory array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

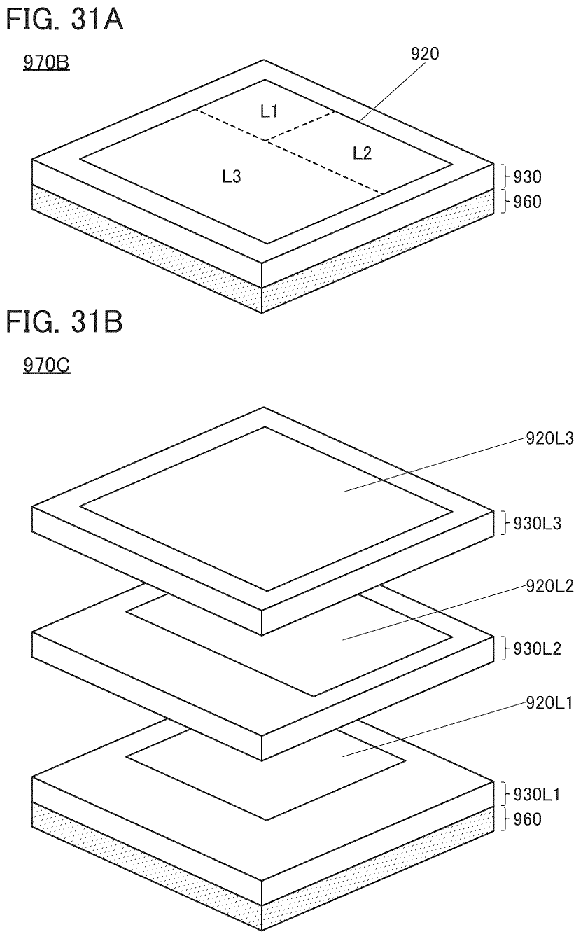

The layer 930 including one memory array 920 may be provided to overlap with the arithmetic device 960. FIG. 31A is a perspective view of a semiconductor device 970B.

In the semiconductor device 970B, one memory array 920 can be divided into a plurality of areas having different functions. FIG. 31A illustrates an example in which a region L1, a region L2, and a region L3 are used as the L1 cache, the L2 cache, and the L3 cache, respectively.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be increased.

Alternatively, a plurality of memory arrays may be stacked. FIG. 31B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

Note that this embodiment can be combined with any of the other embodiments in this specification as appropriate.

### Embodiment 5

In this embodiment, application examples of the memory device of one embodiment of the present invention will be described.

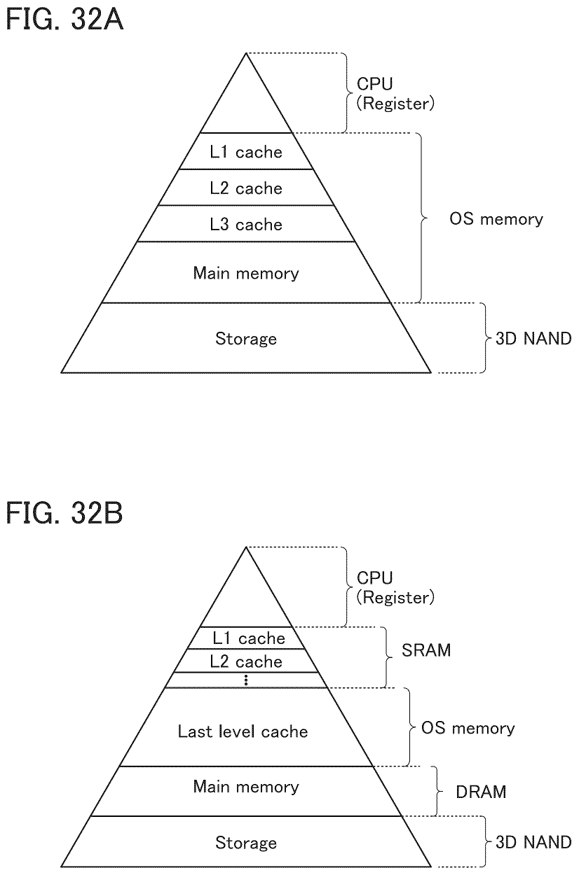

In general, a variety of memory devices are used in semiconductor devices such as computers in accordance with the intended use. FIG. 32A illustrates the hierarchy of various memory devices used in semiconductor devices. The memory devices at the upper levels require higher operating speed, whereas the memory devices at the lower levels require higher memory capacity and higher memory density. FIG. 32A illustrates, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may further be included.

A memory included as a register in an arithmetic processing device such as a CPU is used for temporary storage of arithmetic operation results, for example, and thus is very frequently accessed by the arithmetic processing device. Accordingly, rapid operation is more important than the memory capacity. The register also has a function of retaining settings of the arithmetic processing device, for example.

The cache has a function of duplicating and retaining part of data retained in the main memory. Duplicating frequently used data and retaining the duplicated data in the cache facilitates rapid data access. The cache requires a smaller memory capacity than the main memory but a higher operating speed than the main memory. Data that is rewritten in the cache is duplicated, and the duplicated data is supplied to the main memory.

The main memory has a function of retaining a program, data, and the like that are read from the storage.

The storage has a function of retaining data that needs to be stored for a long time and programs used in the arithmetic processing device, for example. Therefore, the storage needs to have a large memory capacity and a high memory density rather than operating speed. For example, a high-capacity nonvolatile memory device such as a 3D NAND memory device can be used.

The memory device including an oxide semiconductor (the OS memory) of one embodiment of the present invention operates at high speed and can retain data for a long time. Thus, as illustrated in FIG. 32A, the memory device of one embodiment of the present invention can be suitably used for devices at both the level including the cache and the level including the main memory. The memory device of one embodiment of the present invention can also be used at the level including the storage.

FIG. 32B illustrates an example in which an SRAM is used as at least one of the caches and the OS memory of one embodiment of the present invention is used as the other cache.

The lowest-level cache can be referred to as a last level cache (LLC). The LLC does not require a higher operating speed than a higher-level cache, but desirably has a large memory capacity. The OS memory of one embodiment of the present invention operates at high speed and can retain data for a long time, and thus can be suitably used as the LLC. Note that the OS memory of one embodiment of the present invention can also be used as a final level cache (FLC).

For example, as illustrated in FIG. 32B, an SRAM can be used as the higher-level caches (the L1 cache, the L2 cache, and the like), and the OS memory of one embodiment of the present invention can be used as the LLC. Moreover, instead of the OS memory, a DRAM can be used as the main memory as illustrated in FIG. 32B.

Note that this embodiment can be combined with any of the other embodiments in this specification as appropriate.

### Embodiment 6

This embodiment will describe an electronic appliance, a large computer, space equipment, and a data center (also referred to as DC) that can include any of the semiconductor devices described in the above embodiments. The use of the semiconductor device of one embodiment of the present invention in an electronic appliance, a large computer, space equipment, and a data center is effective in improving performance, for example, reducing power consumption.

### [Electronic Appliance]

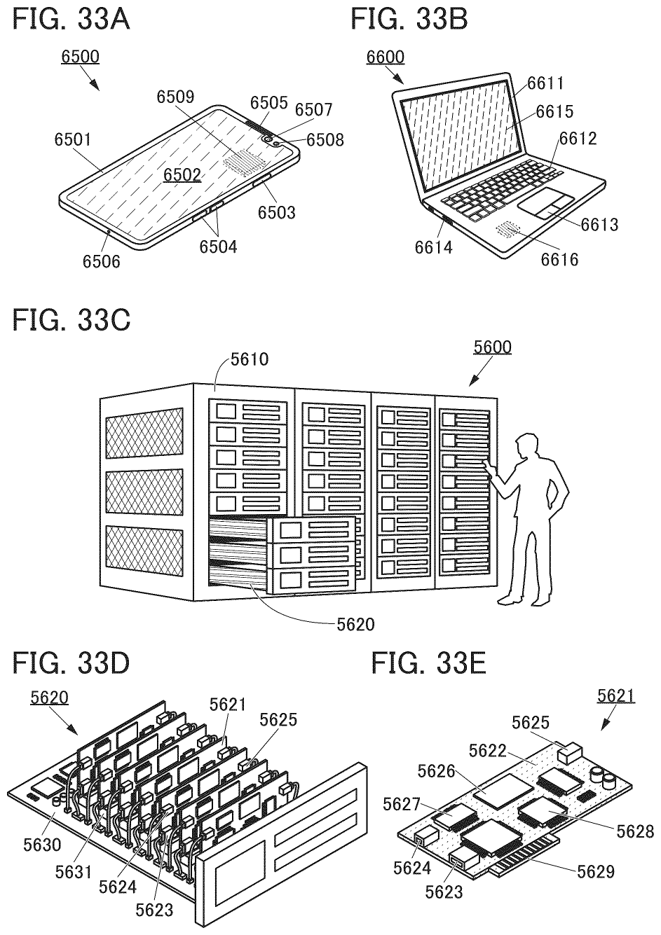

FIG. 33A is a perspective view of an electronic appliance 6500. The electronic appliance 6500 illustrated in FIG. 33A is a portable information terminal that can be used as a smartphone. The electronic appliance 6500 includes a housing 6501, a display portion 6502, a power button 6503, buttons 6504, a speaker 6505, a microphone 6506, a camera 6507, a light source 6508, a control device 6509, and the like. Note that as the control device 6509, for example, one or more selected from a CPU, a GPU, and a memory device are included. The semiconductor device of one embodiment of the present invention can be used for the display portion 6502, the control device 6509, and the like.

An electronic appliance 6600 illustrated in FIG. 33B is an information terminal that can be used as a laptop personal computer. The electronic appliance 6600 includes a housing 6611, a keyboard 6612, a pointing device 6613, an external connection port 6614, a display portion 6615, a control device 6616, and the like. Note that as the control device 6616, for example, one or more selected from a CPU, a GPU, and a memory device are included. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

FIG. 33C is a perspective view of a large computer 5600. In the large computer 5600 illustrated in FIG. 33C, a plurality of rack mount computers 5620 are stored in a rack 5610. Note that the large computer 5600 may be referred to as a supercomputer.

The computer 5620 can have a structure in a perspective view of FIG. 33D, for example. In FIG. 33D, the computer 5620 includes a motherboard 5630, and the motherboard 5630 includes a plurality of slots 5631 and a plurality of connection terminals. A PC card 5621 is inserted in the slot 5631. The PC card 5621 includes a connection terminal 5623, a connection terminal 5624, and a connection terminal 5625, each of which is connected to the motherboard 5630.

The PC card 5621 illustrated in FIG. 33E is an example of a processing board provided with a CPU, a GPU, a memory device, and the like. The PC card 5621 includes a board 5622. The board 5622 includes the connection terminals 5623, 5624, and 5625, semiconductor devices 5626, 5627, and 5628, and a connection terminal 5629. Note that FIG. 33E also illustrates semiconductor devices other than the semiconductor devices 5626, 5627, and 5628, and the following description of the semiconductor devices 5626, 5627, and 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminals 5623, 5624, and 5625 can serve as, for example, an interface for performing power supply, signal input, or the like to the PC card 5621. As another example, they can serve as an interface for outputting a signal calculated by the PC card 5621. Examples of the standard for each of the connection terminals 5623, 5624, and 5625 include USB, Serial ATA (SATA), and Small Computer System Interface (SCSI). In the case where video signals are output from the connection terminals 5623, 5624, and 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used for space equipment, such as devices processing and storing information.

The semiconductor device of one embodiment of the present invention can include an OS transistor. A change in electrical characteristics of the OS transistor due to exposure to radiation is small. That is, the OS transistor is highly resistant to radiation, and thus can be suitably used in an environment where radiation can enter. For example, the OS transistor can be suitably used in outer space.

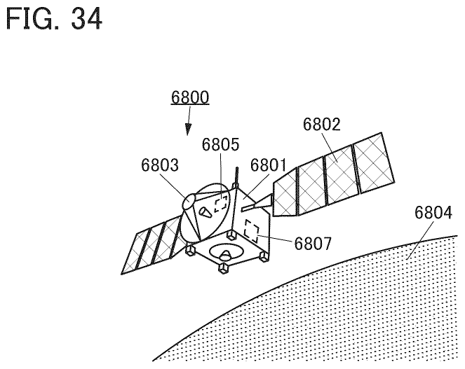

FIG. 34 illustrates an artificial satellite 6800 as an example of space equipment. The artificial satellite 6800 includes a body 6801, a solar panel 6802, an antenna 6803, a secondary battery 6805, and a control device 6807. In FIG. 34, a planet 6804 in outer space is illustrated as an example. Note that outer space refers to, for example, space at an altitude greater than or equal to 100 km, and outer space in this specification may also include the thermosphere, mesosphere, and stratosphere.

Although not illustrated in FIG. 34, a battery management system (also referred to as BMS) or a battery control circuit may be provided in the secondary battery 6805. The battery management system or the battery control circuit preferably includes an OS transistor, in which case low power consumption and high reliability even in outer space are achieved.

The amount of radiation in outer space is more than 100 times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device of one embodiment of the present invention is suitably used for the control device 6807. A change in electrical characteristics due to exposure to radiation is smaller in an OS transistor than in a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited to this example. The semiconductor device of one embodiment of the present invention can be suitably used for space equipment such as a spacecraft, a space capsule, and a space probe, for example.

As described above, an OS transistor has excellent effects of achieving a wide memory bandwidth and high radiation tolerance as compared with a Si transistor.

### [Data Center]

The semiconductor device of one embodiment of the present invention can be suitably used for, for example, a storage system in a data center or the like. The data center is required to perform long-term data management, such as guarantee of data immutability. For long-term data management, it is necessary to increase the scale of the data center for installation of storages and servers for storing an enormous amount of data, stable electric power for data retention, cooling equipment for data retention, or the like.

With the use of the semiconductor device of one embodiment of the present invention for a storage system in a data center, electric power used for retaining data can be reduced and a semiconductor device for retaining data can be downsized. Accordingly, downsizing of the storage system and the power supply for retaining data, downscaling of the cooling equipment, and the like can be achieved. Therefore, the space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

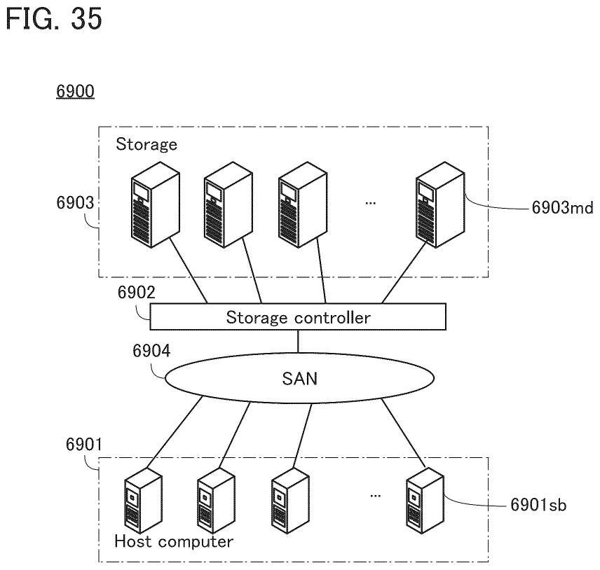

FIG. 35 illustrates a storage system that can be used in a data center. A storage system 6900 illustrated in FIG. 35 includes a plurality of servers 6901sb as a host 6901 (indicated as “Host computer” in the diagram). The storage system 6900 includes a plurality of memory devices 6903md as a storage 6903 (indicated as “Storage” in the diagram). In the illustrated example, the host 6901 and the storage 6903 are connected to each other through a storage area network 6904 (indicated as “SAN” in the diagram) and a storage control circuit 6902 (indicated as “Storage Controller” in the diagram).

The host 6901 corresponds to a computer that accesses data stored in the storage 6903. The host 6901 may be connected to another host 6901 through a network.

The data access speed, i.e., the time taken for storing and outputting data, of the storage 6903 is shortened by using a flash memory, but is still considerably longer than the data access speed of a DRAM that can be used as a cache memory in the storage 6903. In the storage system, in order to solve the problem of low access speed of the storage 6903, a cache memory is normally provided in the storage to shorten the time taken for data storage and output.

The above-described cache memory is used in the storage control circuit 6902 and the storage 6903. The data transmitted between the host 6901 and the storage 6903 is stored in the cache memories in the storage control circuit 6902 and the storage 6903 and then output to the host 6901 or the storage 6903.

The use of an OS transistor as a transistor for storing data in the cache memory to retain a potential based on data can reduce the frequency of refreshing, so that power consumption can be reduced. Furthermore, downscaling is possible by stacking memory cell arrays.

The use of the semiconductor device of one embodiment of the present invention for one or more selected from an electronic appliance, a large computer, space equipment, and a data center will produce an effect of reducing power consumption. Although there is a growing demand for more energy accompanying with higher performance and higher integration degree of semiconductor devices, the use of the semiconductor device of one embodiment of the present invention can thus reduce the emission amount of greenhouse gas typified by carbon dioxide (CO₂). Furthermore, the semiconductor device of one embodiment of the present invention has low power consumption and thus is effective as a global warming countermeasure.

The configurations, structures, methods, and the like described in this embodiment can be used in an appropriate combination with any of the configurations, structures, methods, and the like described in the other embodiments and the like.

### Embodiment 7

This embodiment will describe structure examples of a display apparatus that can include the transistor of one embodiment of the present invention.

Since the transistor of one embodiment of the present invention can be extremely minute, a display apparatus including the transistor of one embodiment of the present invention can have extremely high resolution. For example, the display apparatus of one embodiment of the present invention can be used for display portions of information terminals (wearable devices) such as watch-type and bracelet-type information terminals and display portions of devices capable of being worn on a head, such as a VR device like a head-mounted display (HMD) and a glasses-type AR device.

### [Display Module]

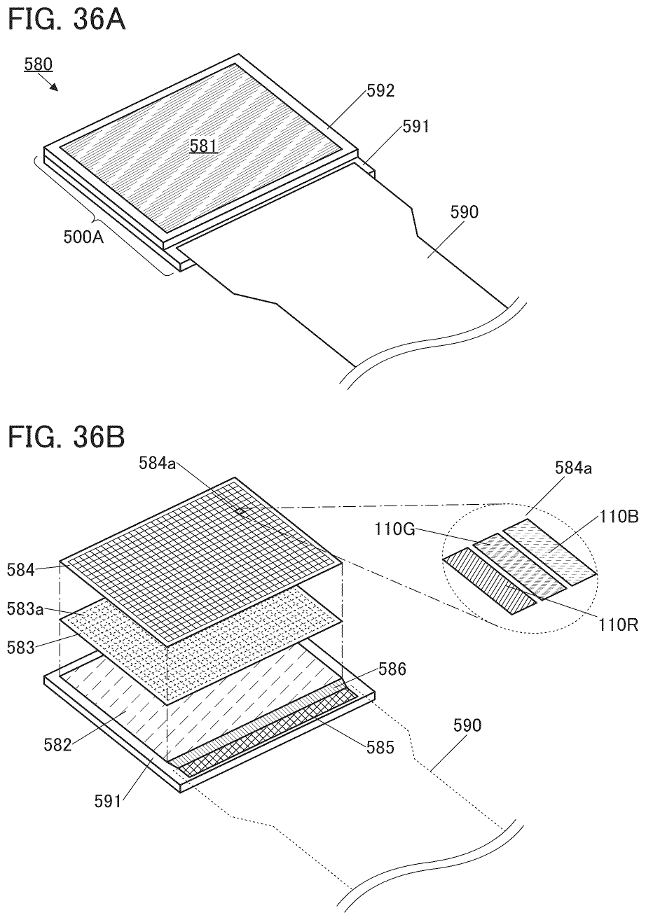

FIG. 36A is a perspective view of a display module 580. The display module 580 includes a display apparatus 500A and an FPC 590. Note that a display panel included in the display module 580 is not limited to the display apparatus 500A and may be a display apparatus 500B or a display apparatus 500C each of which will be described later.

The display module 580 includes a substrate 591 and a substrate 592. The display module 580 includes a display portion 581. The display portion 581 is a region where an image is displayed.

FIG. 36B is a perspective view schematically illustrating the structure on the substrate 591 side. Over the substrate 591, a circuit portion 582, a pixel circuit portion 583 over the circuit portion 582, and a pixel portion 584 over the pixel circuit portion 583 are stacked. A terminal portion 585 for connection to the FPC 590 is included in a portion not overlapping with the pixel portion 584 over the substrate 591. The terminal portion 585 and the circuit portion 582 are electrically connected to each other through a wiring portion 586 formed of a plurality of wirings.

The pixel portion 584 includes a plurality of pixels 584a arranged periodically. An enlarged view of one pixel 584a is illustrated on the right side in FIG. 36B. The pixel 584a includes a light-emitting element 110R that emits red light, a light-emitting element 110G that emits green light, and a light-emitting element 110B that emits blue light.

The pixel circuit portion 583 includes a plurality of pixel circuits 583a arranged periodically. One pixel circuit 583a controls light emission from three light-emitting devices included in one pixel 584a. One pixel circuit 583a may include three circuits each of which controls light emission from one light-emitting device. For example, the pixel circuit 583a can include at least one selection transistor, one current control transistor (driving transistor), and a capacitor for one light-emitting device. In this case, a gate signal is input to a gate of the selection transistor, and a source signal is input to a source of the selection transistor. Thus, an active matrix display panel is achieved.

The circuit portion 582 includes a circuit for driving the pixel circuits 583a in the pixel circuit portion 583. For example, the circuit portion 582 preferably includes one or both of a gate line driver circuit and a source line driver circuit. The circuit portion 582 may also include at least one of an arithmetic circuit, a memory circuit, a power supply circuit, and the like. A transistor included in the circuit portion 582 may constitute part of the pixel circuit 583a. That is, the pixel circuit 583a may be constituted by a transistor included in the pixel circuit portion 583 and a transistor included in the circuit portion 582.

The FPC 590 functions as a wiring for supplying a video signal, a power supply potential, and the like to the circuit portion 582 from the outside. An IC may be mounted on the FPC 590.

The display module 580 can have a structure in which one or both of the pixel circuit portion 583 and the circuit portion 582 are stacked below the pixel portion 584; thus, the aperture ratio (effective display area ratio) of the display portion 581 can be significantly high. For example, the aperture ratio of the display portion 581 can be higher than or equal to 40% and lower than 100%, preferably higher than or equal to 50% and lower than or equal to 95%, further preferably higher than or equal to 60% and lower than or equal to 95%. Furthermore, the pixels 584a can be arranged extremely densely and thus the display portion 581 can have significantly high resolution. For example, the pixels 584a are preferably arranged in the display portion 581 with a resolution greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi.

Such a display module 580 has extremely high resolution, and thus can be suitably used for a device for VR, such as a head-mounted display, or a glasses-type device for AR. For example, even with a structure in which the display portion of the display module 580 is viewed through a lens, pixels of the extremely-high-resolution display portion 581 included in the display module 580 are not recognized even when the display portion is magnified by the lens; hence, display providing a high sense of immersion can be performed. Without being limited thereto, the display module 580 can be suitably used for electronic appliances including a relatively small display portion. For example, the display module 580 can be suitably used in a display portion of a wearable electronic appliance, such as a wrist watch.

### [Display Apparatus 500A]

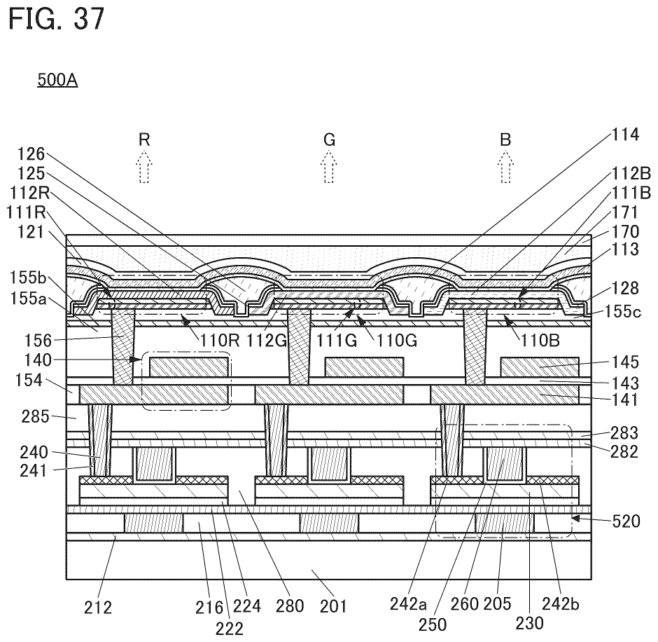

The display apparatus 500A illustrated in FIG. 37 includes a substrate 201, the light-emitting elements 110R, 110G, and 110B, a capacitor 140, and a transistor 520.

The substrate 201 corresponds to the substrate 591 in FIG. 36A.

The transistor 520 includes an oxide semiconductor in a semiconductor layer where a channel is formed. The transistor 520 includes the oxide semiconductor 230, the conductor 205, the insulator 222, the insulator 224, the conductor 242a, the conductor 242b, the insulator 250, the conductor 260, and the like. Over the substrate 201, interlayer films are formed in the order of the insulators 212, 216, 222, 280, 282, 283, and 285. The conductor 240 and the insulator 241 are formed in an opening formed in the insulators 280, 282, 283, and 285.

As the transistor 520, a variety of transistors described in Embodiment 1 can be used. Although simplified in FIG. 37, the transistor 520 can also employ the structure of the transistor 200 and the vicinity thereof illustrated in FIG. 2A and the like. For example, as illustrated in FIG. 2A, an insulator having a barrier property against impurities such as hydrogen can be provided above and below the transistor. This can prevent diffusion of hydrogen contained in and around the substrate and the light-emitting element into the transistor 520. With the insulator 241 provided to cover the side surface of the conductor 240, hydrogen contained in and around the light-emitting element can be prevented from diffusing into the insulator 280 through the conductor 240. Accordingly, a highly reliable display apparatus can be provided.

The capacitor 140 is provided over the insulator 285. The capacitor 140 includes a conductive layer 141, a conductive layer 145, and an insulating layer 143 between the conductive layers 141 and 145. The conductive layer 141 functions as one electrode of the capacitor 140, the conductive layer 145 functions as the other electrode of the capacitor 140, and the insulating layer 143 functions as a dielectric of the capacitor 140.

The conductive layer 141 is provided over the insulator 285 and is embedded in an insulating layer 154. The conductive layer 141 is electrically connected to the conductor 242a of the transistor 520 through the conductor 240. The insulating layer 143 is provided to cover the conductive layer 141. The conductive layer 145 is provided in a region overlapping with the conductive layer 141 with the insulating layer 143 therebetween.

As illustrated in FIG. 37, the capacitor 140 can have a planar structure. Here, it is possible to provide an insulator having a barrier property against impurities such as hydrogen to cover the capacitor 140. This can prevent hydrogen contained in and around the light-emitting element from diffusing into the transistor 520 in the lower layer. Thus, a highly reliable display apparatus can be provided.

In addition, a structure in which a wiring layer is further provided over the capacitor 140 can be employed. The connection relation between the circuit elements, wirings, vias, and the like of the display apparatus of this embodiment is not limited to the connection relation illustrated in FIG. 37. The connection relation between the circuit elements, wirings, vias, and the like can be set as appropriate in accordance with the pixel circuit of the display apparatus.

An insulating layer 155a is provided to cover the capacitor 140, an insulating layer 155b is provided over the insulating layer 155a, and an insulating layer 155c is provided over the insulating layer 155b.

An inorganic insulating film can be suitably used as each of the insulating layers 155a, 155b, and 155c. For example, it is preferable to use a silicon oxide film as the insulating layers 155a and 155c and use a silicon nitride film as the insulating layer 155b. This enables the insulating layer 155b to function as an etching protective film. Although this embodiment describes an example in which part of the insulating layer 155c is etched to form a recess portion, the recess portion is not necessarily provided in the insulating layer 155c.

The light-emitting elements 110R, 110G, and 110B are provided over the insulating layer 155c.

The light-emitting element 110R includes a pixel electrode 111R, an organic layer 112R, a common layer 114, and a common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are shared by the light-emitting elements 110R, 110G, and 110B.

The organic layer 112R of the light-emitting element 110R includes at least a light-emitting organic compound that emits red light. The organic layer 112G of the light-emitting element 110G includes at least a light-emitting organic compound that emits green light. The organic layer 112B of the light-emitting element 110B includes at least a light-emitting organic compound that emits blue light. Each of the organic layers 112R, 112G, and 112B can also be referred to as an EL layer, and includes at least a layer including a light-emitting organic compound (a light-emitting layer).

In the display apparatus 500A, since the light-emitting devices of different colors are separately formed, the difference between the chromaticity at low luminance emission and that at high luminance emission is small. Furthermore, since the organic layers 112R, 112G, and 112B are separated from each other, crosstalk generated between adjacent subpixels can be inhibited while the display panel has high resolution. Accordingly, the display panel can have high resolution and high display quality.

In the region between adjacent light-emitting elements, an insulating layer 125, a resin layer 126, and a layer 128 are provided.

The pixel electrodes 111R, 111G, and 111B of the light-emitting elements are each electrically connected to the conductor 242a of the transistor 520 through a plug 156 embedded in the insulating layers 155a, 155b, and 155c, the conductive layer 141 embedded in the insulating layer 154, and the conductor 240. The top surface of the insulating layer 155c and the top surface of the plug 156 are level with or substantially level with each other. Any of a variety of conductive materials can be used for the plug.

A protective layer 121 is provided over the light-emitting elements 110R, 110G, and 110B. A substrate 170 is attached above the protective layer 121 with an adhesive layer 171.

An insulating layer covering an end portion of the top surface of the pixel electrode 111 is not provided between two adjacent pixel electrodes 111. Thus, the interval between adjacent light-emitting elements can be extremely shortened. Accordingly, the display apparatus can have high resolution or high definition.

### [Display Apparatus 500B]

A display apparatus having a structure partly different from the above-described structure will be described below. Note that the description of the display apparatus 500A is referred to for common portions and the description thereof is omitted in some cases.

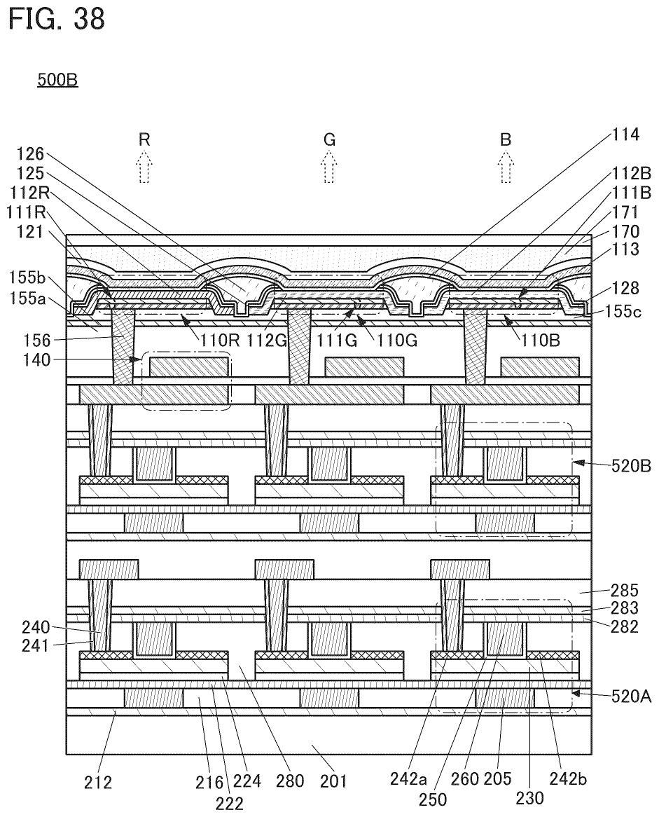

In the display apparatus 500B illustrated in FIG. 38, a transistor 520A over the substrate 201 and a transistor 520B over the transistor 520A are stacked. Here, the transistors 520A and 520B have the same structure as the transistor 520. In other words, the display apparatus 500B has a structure in which another layer including the transistor 520 is provided between the substrate 201 and the layer including the transistor 520 in the display apparatus 500A illustrated in FIG. 37.

As in the display apparatus 500A, a variety of transistors described in Embodiment 1 can be used as the transistors 520A and 520B. For example, in the layer including the transistor 520A and the layer including the transistor 520B, an insulator having a barrier property against impurities such as hydrogen can be provided above and below the transistor as illustrated in FIG. 2A. This can prevent diffusion of hydrogen contained in and around the substrate and the light-emitting element into the transistors 520A and 520B. With the insulator 241 provided to cover the side surface of the conductor 240, hydrogen contained in and around the light-emitting element can be prevented from diffusing into the insulator 280 through the conductor 240. Accordingly, a highly reliable display apparatus can be provided.

Although the structure is simplified in FIG. 38, connecting a wiring and a via allows the transistor 520A and the transistor 520B to be electrically connected to each other. The connection relation between the circuit elements, wirings, vias, and the like of the display apparatus of this embodiment is not limited to the connection relation illustrated in FIG. 38. The connection relation between the circuit elements, wirings, vias, and the like can be set as appropriate in accordance with the pixel circuit of the display apparatus.

### [Display Apparatus 500C]

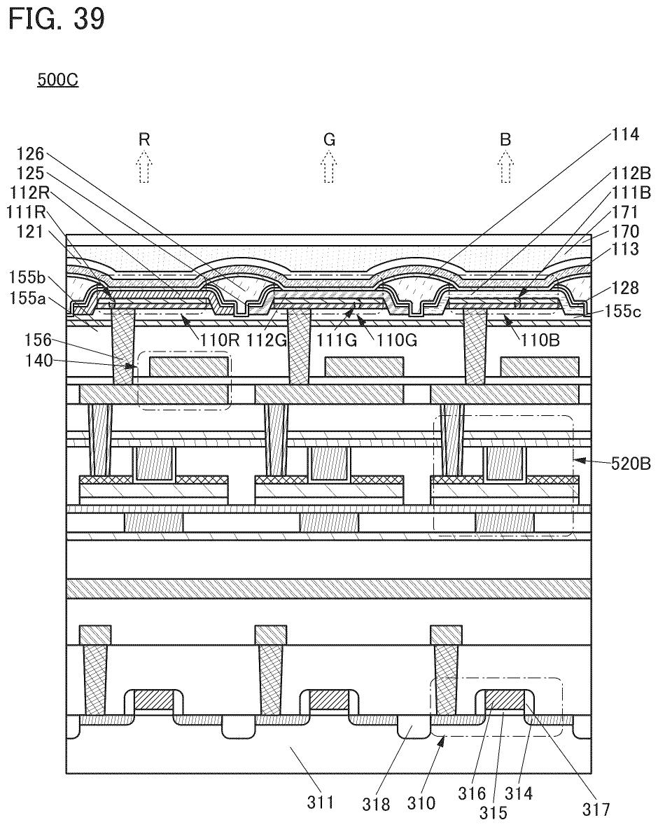

In the display apparatus 500C illustrated in FIG. 39, the transistor 310 in which a channel is formed in a semiconductor substrate and the transistor 520B over the transistor 310 are stacked. Here, the transistor 520B has the same structure as the transistor 520. In other words, the display apparatus 500C has a structure in which a layer including the transistor 310 is provided instead of the layer including the transistor 520A in the display apparatus 500B illustrated in FIG. 38.

The transistor 310 includes a channel formation region in the substrate 311. As the substrate 311, a semiconductor substrate such as a single crystal silicon substrate can be used, for example. The transistor 310 includes part of the substrate 311, the conductor 316, low-resistance regions 314, the insulator 315, and insulators 317. The conductor 316 functions as a gate electrode. The insulator 315 is positioned between the substrate 311 and the conductor 316 and functions as a gate insulating layer. The low-resistance regions 314 are regions where the substrate 311 is doped with an impurity, and function as a source and a drain. The insulators 317 are provided to cover side surfaces of the conductor 316.

The element isolation layer 318 is provided between two adjacent transistors 310 to be embedded in the substrate 311.

As in the display apparatus 500A, a variety of transistors described in Embodiment 1 can be used as the transistor 520B. For example, in the layer including the transistor 520B, an insulator having a barrier property against impurities such as hydrogen can be provided above and below the transistor as illustrated in FIG. 2A. Thus, hydrogen contained in and around the light-emitting element can be prevented from diffusing into the transistor 520B. Furthermore, hydrogen contained in and around the transistor 310 can be prevented from diffusing into the transistor 520B. With the insulator 241 provided to cover the side surface of the conductor 240, hydrogen contained in and around the light-emitting element can be prevented from diffusing into the insulator 280 through the conductor 240. Accordingly, a highly reliable display apparatus can be provided.

Although the structure is simplified in FIG. 39, connecting a wiring and a via allows the transistor 520B and the transistor 310 to be electrically connected to each other. The connection relation between the circuit elements, wirings, vias, and the like of the display apparatus of this embodiment is not limited to the connection relation illustrated in FIG. 39. The connection relation between the circuit elements, wirings, vias, and the like can be set as appropriate in accordance with the pixel circuit of the display apparatus.

At least part of this embodiment can be implemented as appropriate in combination with any of the other embodiments described in this specification.

### Embodiment 8

This embodiment will describe examples of a structure applicable to a display apparatus that is manufactured using the transistor of one embodiment of the present invention. A display apparatus exemplified below can be used for the pixel portion 584 in Embodiment 7, for example.

One embodiment of the present invention is a display apparatus including a light-emitting element (also referred to as a light-emitting device). The display apparatus includes at least two pixels that emit light of different colors. Each of the pixels includes a light-emitting element. The light-emitting elements each include a pair of electrodes and an EL layer therebetween. The light-emitting elements are preferably organic electroluminescent elements (organic EL elements). Two or more light-emitting elements that emit light of different colors include respective EL layers including different light-emitting materials. For example, three kinds of light-emitting elements that emit red (R), green (G), and blue (B) light achieves a full-color display apparatus.

In the case of manufacturing a display apparatus including a plurality of light-emitting elements that emit light of different colors, at least layers including light-emitting materials (i.e., light-emitting layers) each need to be formed in an island shape. In a known method for separately forming part or the whole of an EL layer, an island-shaped organic film is formed by an evaporation method using a shadow mask such as a metal mask. However, this method has difficulty in achieving high resolution and a high aperture ratio of a display apparatus because in this method, a deviation from the designed shape and position of the island-shaped organic film is caused by various influences such as low accuracy of the metal mask position, positional deviation between the metal mask and a substrate, a warp of the metal mask, and the vapor-scattering-induced expansion of the outline of the formed film. In addition, the outline of a layer may blur during vapor deposition, whereby the thickness of its end portion may be small. That is, the thickness of an island-shaped light-emitting layer may vary from area to area. In the case of manufacturing a display panel with a large size, high definition, or high resolution, the manufacturing yield might be reduced because of low dimensional accuracy of the metal mask and deformation due to heat or the like. Thus, a measure has been taken for pseudo improvement in resolution (also referred to pixel density). As a specific measure, unique pixel arrangement such as a PenTile pattern has been employed.

Note that in this specification and the like, the term “island shape” refers to a state where two or more layers formed using the same material in the same step are physically separated from each other. For example, “island-shaped light-emitting layer” means that the light-emitting layer and its adjacent light-emitting layer are physically separated from each other.

In one embodiment of the present invention, fine patterning of an EL layer is performed by photolithography without a shadow mask such as a fine metal mask (FMM). Thus, it is possible to obtain a display apparatus having high resolution and a high aperture ratio, which has been difficult to achieve. Moreover, EL layers can be formed separately, enabling the display apparatus to perform extremely clear display with high contrast and high display quality. Note that fine patterning of an EL layer may be performed using both a metal mask and photolithography, for example.

Part or the whole of the EL layer can be physically divided, inhibiting leakage current flowing between adjacent light-emitting elements through a layer shared by the light-emitting element (also referred to as a common layer). This can prevent crosstalk-induced unintended light emission, so that the display apparatus can achieve extremely high contrast. Specifically, a display apparatus having high current efficiency at low luminance can be obtained.

The display apparatus of one embodiment of the present invention can also be obtained by combining white-light-emitting elements with a color filter. In that case, the light-emitting elements having the same structure can be provided in pixels (subpixels) that emit light of different colors, allowing all the layers to be common layers. Furthermore, part or the whole of the EL layer may be divided by photolithography. Thus, leakage current through a common layer is suppressed; accordingly, a high-contrast display apparatus is achieved. In particular, when an element has a tandem structure in which a plurality of light-emitting layers are stacked with a highly conductive intermediate layer therebetween, a leakage current through the intermediate layer can be effectively prevented, achieving a display apparatus with high luminance, high resolution, and high contrast.

In the case where the EL layer is processed by a photolithography method, part of the light-emitting layer is sometimes exposed to cause deterioration. For this reason, an insulating layer covering at least a side surface of the island-shaped light-emitting layer is preferably provided. The insulating layer may cover part of the top surface of the island-shaped EL layer. For the insulating layer, a material having a barrier property against water and oxygen is preferably used. For example, an inorganic insulating film that is less likely to diffuse water and oxygen can be used. Thus, the deterioration of the EL layer is inhibited, and a highly reliable display apparatus can be achieved.

Between two adjacent light-emitting elements, there is a region (a depressed portion) where the EL layers of the light-emitting elements are not provided. In the case where a common electrode or a common electrode and a common layer are formed to cover the depressed portion, the common electrode might be disconnected by a step at an end portion of the EL layer (“disconnection” might occur), thereby causing insulation of the common electrode over the EL layer. In view of this, a local gap between the two adjacent light-emitting elements is preferably filled with a resin layer serving as a planarization film (such a structure is also referred to as local filling planarization, or LFP). The resin layer has a function of a planarization film. This structure can inhibit disconnection of the common layer or the common electrode, obtaining a highly reliable display apparatus.

More specific structure examples of the display apparatus of one embodiment of the present invention will be described below with reference to drawings.

### Structure Example 1

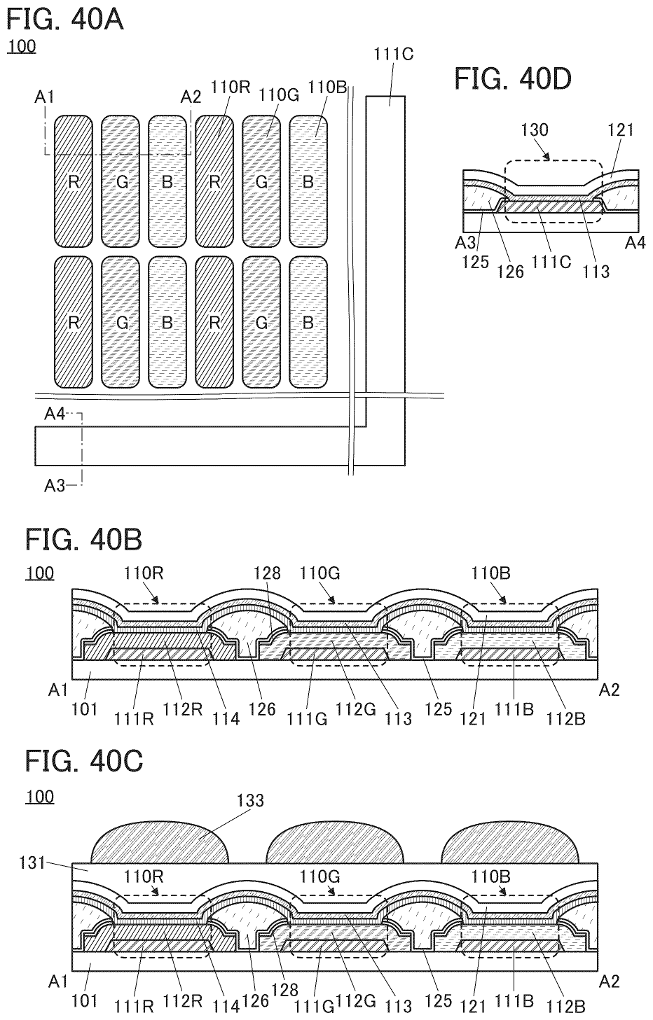

FIG. 40A is a schematic top view of a display apparatus 100 of one embodiment of the present invention. The display apparatus 100 includes, over a substrate 101, a plurality of the light-emitting elements 110R that exhibit red, a plurality of the light-emitting elements 110G that exhibit green, and a plurality of the light-emitting elements 110B that exhibit blue. In FIG. 40A, light-emitting regions of the light-emitting elements are denoted by R, G, and B to easily differentiate the light-emitting elements.

The light-emitting elements 110R, 110G, and 110B are arranged in a matrix. FIG. 40A shows what is called a stripe arrangement, in which the light-emitting elements of the same color are arranged in one direction. Note that the arrangement of the light-emitting elements is not limited thereto; another arrangement such as S stripe, delta, Bayer, zigzag, PenTile, or diamond pattern may also be used.

As each of the light-emitting elements 110R, 110G, and 110B, an organic light-emitting diode (OLED) or a quantum-dot light-emitting diode (QLED) is preferably used, for example. Examples of a light-emitting substance contained in the EL element include a substance exhibiting fluorescence (fluorescent material), a substance exhibiting phosphorescence (phosphorescent material), and a substance exhibiting thermally activated delayed fluorescence (thermally activated delayed fluorescent (TADF) material). Examples of the light-emitting substance contained in the EL element include not only organic compounds but also inorganic compounds (e.g., quantum dot materials).

FIG. 40A also illustrates a connection electrode 111C that is electrically connected to the common electrode 113. The connection electrode 111C is supplied with a potential (e.g., an anode potential or a cathode potential) that is to be supplied to the common electrode 113. The connection electrode 111C is provided outside a display region where the light-emitting elements 110R and the like are arranged.

The connection electrode 111C can be provided along the outer periphery of the display 30 region. For example, the connection electrode 111C may be provided along one side of the outer periphery of the display region or two or more sides of the outer periphery of the display region. That is, in the case where the display region has a rectangular top surface, the top surface of the connection electrode 111C can have a band shape (rectangular shape), an L shape, a square bracket shape, a quadrangular shape, or the like.

FIGS. 40B and 40D are schematic cross-sectional views along the dashed-dotted line A1-A2 and the dashed-dotted line A3-A4 in FIG. 40A. FIG. 40B is a schematic cross-sectional view of the light-emitting element 110R, the light-emitting element 110G, and the light-emitting element 110B. FIG. 40C illustrates a variation example of the structure illustrated in FIG. 40B. FIG. 40D is a schematic cross-sectional view of a connection portion 130 where the connection electrode 111C and the common electrode 113 are connected to each other.

The light-emitting element 110R includes the pixel electrode 111R, the organic layer 112R, the common layer 114, and the common electrode 113. The light-emitting element 110G includes the pixel electrode 111G, the organic layer 112G, the common layer 114, and the common electrode 113. The light-emitting element 110B includes the pixel electrode 111B, the organic layer 112B, the common layer 114, and the common electrode 113. The common layer 114 and the common electrode 113 are shared by the light-emitting elements 110R, 110G, and 110B.

The organic layer 112R of the light-emitting element 110R includes at least a light-emitting organic compound that emits red light. The organic layer 112G of the light-emitting element 110G includes at least a light-emitting organic compound that emits green light. The organic layer 112B of the light-emitting element 110B includes at least a light-emitting organic compound that emits blue light. Each of the organic layers 112R, 112G, and 112B can also be referred to as an EL layer, and includes at least a layer including a light-emitting organic compound (a light-emitting layer).

Hereafter, the term “light-emitting element 110” is sometimes used to describe matters common to the light-emitting elements 110R, 110G, and 110B. Likewise, in the description of matters common to the components that are distinguished using alphabets, such as the organic layers 112R, 112G, and 112B, reference numerals without such alphabets are sometimes used.

The organic layer 112 and the common layer 114 can each independently include one or more of an electron-injection layer, an electron-transport layer, a hole-injection layer, and a hole-transport layer. For example, the organic layer 112 can include a hole-injection layer, a hole-transport layer, a light-emitting layer, and an electron-transport layer that are stacked from the pixel electrode 111 side, and the common layer 114 can include an electron-injection layer.

The pixel electrode 111R, the pixel electrode 111G, and the pixel electrode 111B are provided for the respective light-emitting elements. Each of the common electrode 113 and common layer 114 is provided as a continuous layer shared by the light-emitting elements. A conductive film that has a property of transmitting visible light is used for either the pixel electrodes or the common electrode 113, and a reflective conductive film is used for the other. When the pixel electrodes are light-transmitting electrodes and the common electrode 113 is a reflective electrode, a bottom-emission display apparatus is obtained. Meanwhile, when the pixel electrodes are reflective electrodes and the common electrode 113 is a light-transmitting electrode, a top-emission display apparatus is obtained. Note that when both the pixel electrodes and the common electrode 113 have a property of transmitting light, a dual-emission display apparatus is obtained.

The protective layer 121 is provided over the common electrode 113 to cover the light-emitting element 110. The protective layer 121 has a function of preventing diffusion of impurities such as water into the light-emitting elements from above.

The pixel electrode 111 preferably has an end portion with a tapered shape. In the case where the pixel electrode 111 has an end portion with a tapered shape, the organic layer 112 that is provided along the end portion of the pixel electrode 111 can also have a tapered shape. When the end portion of the pixel electrode 111 is tapered, coverage with the organic layer 112 provided to cover the end portion of the pixel electrode 111 can be improved. The tapered side surface of the pixel electrode 111 is preferable, in which case a foreign matter (such as dust or particles) mixed during the manufacturing process is easily removed by treatment such as cleaning.

The organic layer 112 has an island shape as a result of processing by a photolithography method. Thus, the angle formed between the top surface and a side surface of an end portion of the organic layer 112 is approximately 90°. By contrast, an organic film formed using an FMM or the like has a thickness that tends to gradually decrease with decreasing distance to an end portion, and has a top surface forming a slope in an area extending from 1 μm to 10 μm from the end portion, for example; thus, such an organic film sometimes has a shape whose top surface and side surface cannot be easily distinguished from each other.

The insulating layer 125, the resin layer 126, and the layer 128 are included between two adjacent light-emitting elements.

Between two adjacent light-emitting elements, a side surface of the organic layer 112 of one light-emitting element faces a side surface of the organic layer 112 of the other light-emitting element with the resin layer 126 therebetween. The resin layer 126 is positioned between two adjacent light-emitting elements so as to fill the region between the end portions of their organic layers 112 and the region between the two organic layers 112. The resin layer 126 has a top surface with a smooth convex shape. The top surface of the resin layer 126 is covered with the common layer 114 and the common electrode 113.

The resin layer 126 functions as a planarization film that fills a step between two adjacent light-emitting elements. Providing the resin layer 126 can prevent a phenomenon in which the common electrode 113 is divided by a step at an end portion of the organic layer 112 (also referred to as disconnection) from occurring and the common electrode 113 over the organic layer 112 from being insulated. The resin layer 126 can also be referred to as a local filling planarization (LFP) layer.

An insulating layer including an organic material can be suitably used as the resin layer 126. For the resin layer 126, it is possible to use, for example, an acrylic resin, a polyimide resin, an epoxy resin, an imide resin, a polyamide resin, a polyimide-amide resin, a silicone resin, a siloxane resin, a benzocyclobutene-based resin, a phenol resin, or precursors of these resins. The resin layer 126 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin.

A photosensitive resin can also be used for the resin layer 126. A photoresist may be used as the photosensitive resin. As the photosensitive resin, a positive photosensitive material or a negative photosensitive material can be used.

The resin layer 126 may include a material absorbing visible light. For example, the resin layer 126 itself may be made of a material absorbing visible light, or the resin layer 126 may include a pigment absorbing visible light. For example, the resin layer 126 can be formed using a resin that can be used as a color filter that transmits red, blue, or green light and absorbs light of the other colors; or a resin that contains carbon black as a pigment and functions as a black matrix.

The insulating layer 125 is provided in contact with a side surface of the organic layer 112. Moreover, the insulating layer 125 is provided to cover a top end portion of the organic layer 112. Part of the insulating layer 125 is in contact with the top surface of the substrate 101.

The insulating layer 125 is positioned between the resin layer 126 and the organic layer 112 to function as a protective film for preventing contact between the resin layer 126 and the organic layer 112. In the case of bringing the resin layer 126 into contact with the organic layer 112, the organic layer 112 might be dissolved by an organic solvent or the like used in formation of the resin layer 126. In view of this, the insulating layer 125 is provided between the organic layer 112 and the resin layer 126 to protect the side surface of the organic layer 112.

The insulating layer 125 can be an insulating layer including an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is used for the insulating layer 125, the insulating layer 125 has a small number of pin holes and excels in a function of protecting the EL layer.

Note that in this specification and the like, an oxynitride refers to a material that contains more oxygen than nitrogen, and a nitride oxide refers to a material that contains more nitrogen than oxygen. For example, silicon oxynitride refers to a material that contains more oxygen than nitrogen, and silicon nitride oxide refers to a material that contains more nitrogen than oxygen.

The insulating layer 125 can be formed by a sputtering method, a CVD method, a PLD method, an ALD method, or the like. The insulating layer 125 is preferably formed by an ALD method achieving good coverage.

Between the insulating layer 125 and the resin layer 126, a reflective film (e.g., a metal film including one or more of silver, palladium, copper, titanium, aluminum, and the like) may be provided to reflect light that is emitted from the light-emitting layer. In this case, the light extraction efficiency can be increased.

Part of a protective layer (also referred to as a mask layer or a sacrificial layer) for protecting the organic layer 112 during etching of the organic layer 112 survives the etching to become the layer 128. For the layer 128, the material that can be used for the insulating layer 125 can be used. In particular, the layer 128 and the insulating layer 125 are preferably formed using the same material, in which case an apparatus or the like for processing can be used in common.

In particular, a metal oxide film such as an aluminum oxide film or a hafnium oxide film or an inorganic insulating film such as a silicon oxide film that is formed by an ALD method has a small number of pinholes, and thus excels in the function of protecting the EL layer and is preferably used for the insulating layer 125 and the layer 128.

The protective layer 121 can have, for example, a single-layer structure or a stacked-layer structure at least including an inorganic insulating film. Examples of the inorganic insulating film include oxide films and nitride films such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

As illustrated in FIG. 40C, a protective layer 131 can be provided over the protective layer 121. For the protective layer 131, an organic insulating film is preferably used. Furthermore, the organic insulating film preferably functions as a planarization film. Accordingly, the top surface of the protective layer 131 can be flat, thereby reducing the influence of an uneven shape caused by the components below. Examples of an organic material that can be used for the protective layer 131 include organic insulating materials that can be used for the resin layer 126.

Providing the protective layer 131 functioning as a planarization film makes it relatively easy to form a lens array 133 over the protective layer 131 as illustrated in FIG. 40C. The lens array 133 can be provided to overlap the light-emitting elements 110. When the lens array 133 is directly formed over the substrate provided with the light-emitting elements 110, the accuracy of positional alignment of the light-emitting elements 110 and the lens array 133 can be enhanced.

The lens array 133 can be formed using at least one of an inorganic material and an organic material. For example, a material containing a resin can be used for the lens. Moreover, a material containing at least one of an oxide and a sulfide can be used for the lens. As the lens array 133, a microlens array can be used, for example.

Note that the lens array 133 can be provided in contact with the top surface of the protective layer 121 without providing the protective layer 131. Alternatively, another component (e.g., a color filter or an electrode of a touch sensor) as well as to the lens array 133 can be provided over the protective layer 131.

FIG. 40D illustrates the connection portion 130 in which the connection electrode 111C is electrically connected to the common electrode 113. In the connection portion 130, an opening portion is provided in the insulating layer 125 and the resin layer 126 over the connection electrode 111C. In the opening portion, the connection electrode 111C and the common electrode 113 are electrically connected to each other.

Although FIG. 40D illustrates the connection portion 130 in which the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, the common layer 114 can be formed to be thin using a material with sufficiently low electrical resistivity and thus can be in the connection portion 130 almost without causing any problem. Accordingly, the common electrode 113 and the common layer 114 can be formed using the same shielding mask, whereby manufacturing costs can be reduced.

### Structure Example 2

A display apparatus partly different from Structure example 1 will be described below. Note that Structure example 1 is referred to for the same portions and the description is skipped here in some cases.

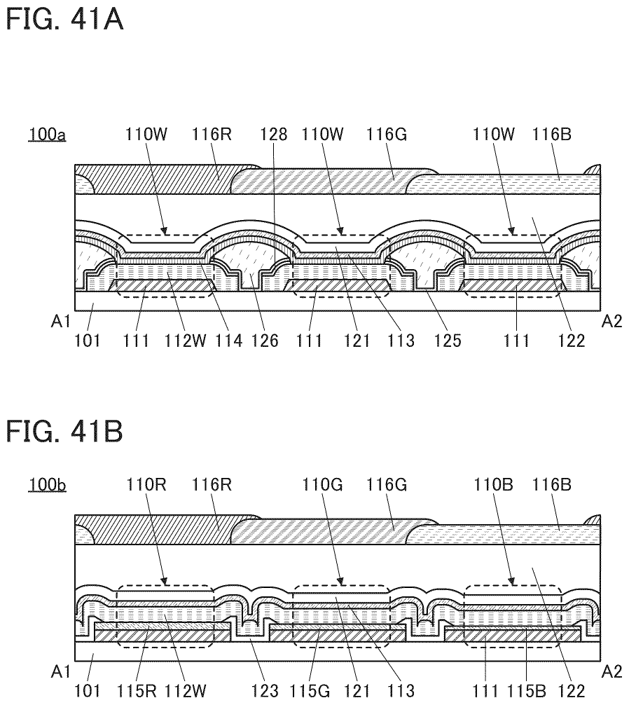

FIG. 41A is a schematic cross-sectional view of a display apparatus 100a. The display apparatus 100a is different from the display apparatus 100 mainly in the structure of the light-emitting element and in including a coloring layer.

The display apparatus 100a includes a light-emitting element 110W that emits white light. The light-emitting element 110W includes the pixel electrode 111, an organic layer 112W, the common layer 114, and the common electrode 113. The organic layer 112W emits white light. For example, the organic layer 112W can include two or more kinds of light-emitting materials that emit light of complementary colors. For example, the organic layer 112W can include a light-emitting organic compound that emits red light, a light-emitting organic compound that emits green light, and a light-emitting organic compound that emits blue light. Alternatively, the organic layer 112W may include a light-emitting organic compound that emits blue light and a light-emitting organic compound that emits yellow light.

The organic layer 112W is divided between two adjacent light-emitting elements 110W. Thus, leakage current that might flow between the adjacent light-emitting elements 110W through the organic layer 112W can be inhibited, and crosstalk due to the leakage current can be inhibited. Accordingly, the display apparatus can have high contrast and high color reproducibility.

An insulating layer 122 functioning as a planarization film is provided over the protective layer 121, and a coloring layer 116R, a coloring layer 116G, and a coloring layer 116B are provided over the insulating layer 122.

An organic resin film or an inorganic insulating film with a flat top surface can be used as the insulating layer 122. The insulating layer 122 serves as a formation surface of the coloring layers 116R, 116G, and 116B. Accordingly, with a flat top surface of the insulating layer 122, the thickness of the coloring layer 116R and the like can be uniform and thus color purity can be increased. Note that if the thickness of the coloring layer 116R and the like is not uniform, the amount of light absorption varies depending on a region in the coloring layer 116R, which might decrease color purity.

### Structure Example 3

FIG. 41B is a schematic cross-sectional view of a display apparatus 100b.

The light-emitting element 110R includes the pixel electrode 111, a conductive layer 115R, the organic layer 112W, and the common electrode 113. The light-emitting element 110G includes the pixel electrode 111, a conductive layer 115G, the organic layer 112W, and the common electrode 113. The light-emitting element 110B includes the pixel electrode 111, a conductive layer 115B, the organic layer 112W, and the common electrode 113. The conductive layers 115R, 115G, and 115B each have a light-transmitting property and function as an optical adjustment layer.

A film reflecting visible light is used for the pixel electrode 111 and a film having properties of reflecting and transmitting visible light is used for the common electrode 113, whereby a micro optical resonator (microcavity) structure can be obtained. In this case, by adjusting the thicknesses of the conductive layers 115R, 115G, and 115B to obtain optimal optical path lengths, light with different wavelengths and increased intensities can be extracted from the light-emitting elements 110R, 110G, and 110B even when the organic layer 112 that emits white light is used.

Furthermore, the coloring layers 116R, 116G, and 116B are provided on the optical paths of the light-emitting elements 110R, 110G, and 110B, respectively, whereby light with high color purity can be extracted.

An insulating layer 123 that covers an end portion of the pixel electrode 111 and an end portion of the conductive layer 115 is provided. The insulating layer 123 preferably has an end portion with a tapered shape. The insulating layer 123 can increase coverage with the organic layer 112W, the common electrode 113, the protective layer 121, and the like provided over the insulating layer 123.

The organic layer 112W and the common electrode 113 are each provided as one continuous film shared by the light-emitting elements. Such a structure is preferable because the manufacturing process of the display apparatus can be greatly simplified.

Here, the end portion of the pixel electrode 111 preferably has a substantially perpendicular shape. In this manner, a steep portion can be formed on the surface of the insulating layer 123, and thus part of the organic layer 112W covering the steep portion can have a small thickness or part of the organic layer 112W can be separated. Accordingly, a leakage current generated between adjacent light-emitting elements through the organic layer 112W can be inhibited without processing the organic layer 112W by a photolithography method or the like.

The above is the description of the structure examples of the display apparatus.

At least part of this embodiment can be implemented as appropriate in combination with any of the other embodiments described in this specification.

### Embodiment 9

This embodiment will describe structure examples of a pixel circuit that can be used in the display apparatus of one embodiment of the present invention.

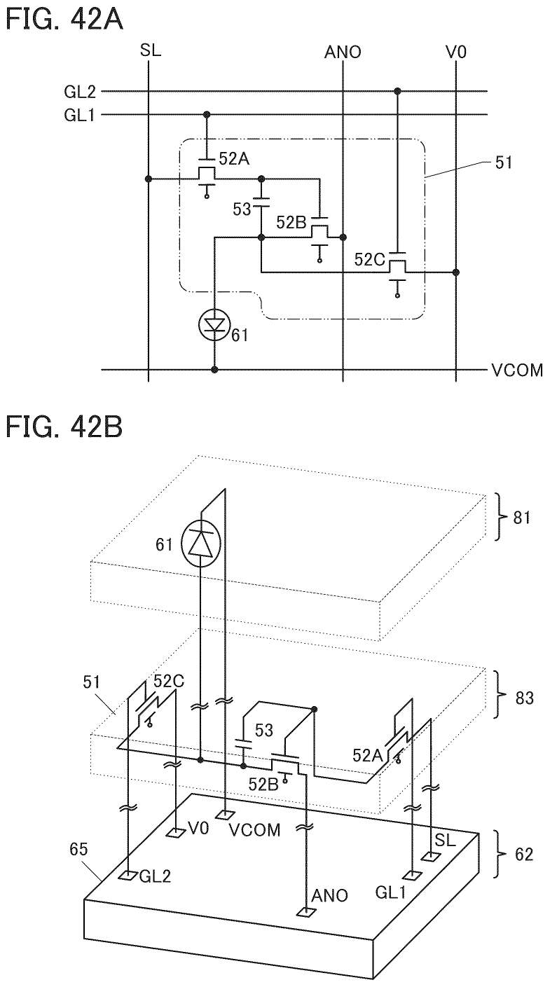

FIGS. 42A and 42B illustrate a structure example of a pixel circuit 51 and a light-emitting device 61 connected to the pixel circuit 51. FIG. 42A schematically illustrates the connection relation of the elements. FIG. 42B schematically illustrates the vertical position relation of a layer 62 including a driver circuit, a layer 83 including a plurality of transistors of the pixel circuit, and a layer 81 including the light-emitting device. For example, in the display apparatus 500C illustrated in FIG. 39, the layer 62 corresponds to a layer including the transistor 310, the layer 83 corresponds to a layer including the transistor 520B and the capacitor 140, and the layer 81 corresponds to a layer including the light-emitting elements 110R, 110G, and 110B.

The pixel circuit 51 illustrated as an example in FIGS. 42A and 42B includes a transistor 52A, a transistor 52B, a transistor 52C, and a capacitor 53. The transistors 52A, 52B, and 52C can be OS transistors. Each of the OS transistors that are the transistors 52A, 52B, and 52C preferably includes a back gate electrode, in which case the back gate electrode and a gate electrode can be supplied with the same signals or different signals.

The transistor 52B includes the gate electrode electrically connected to the transistor 52A, a first electrode electrically connected to the light-emitting device 61, and a second electrode electrically connected to a wiring ANO. The wiring ANO supplies a potential for supplying current to the light-emitting device 61. The transistor 52B has a function of controlling the amount of current flowing through the light-emitting device 61. That is, the transistor 52B has a function of controlling the amount of light emitted from the light-emitting device 61. Thus, the transistor 52B can be referred to as a driving transistor.

The transistor 52A includes a first electrode electrically connected to the gate electrode of the transistor 52B, a second electrode electrically connected to the wiring SL functioning as a source line, and the gate electrode having a function of controlling the on/off state on the basis of the potential of a wiring GL1 functioning as a gate line.

The transistor 52C includes a first electrode electrically connected to a wiring V0, a second electrode electrically connected to the light-emitting device 61, and the gate electrode having a function of controlling the on/off state on the basis of the potential of a wiring GL2 functioning as a gate line. The wiring V0 supplies a reference potential and outputs a current flowing in the pixel circuit 51 to a driver circuit 65 or a functional circuit formed in the layer 62.

The capacitor 53 includes a conductive film electrically connected to the gate electrode of the transistor 52B and a conductive film electrically connected to the second electrode of the transistor 52C.

The light-emitting device 61 includes an anode electrically connected to the first electrode of the transistor 52B and a cathode electrically connected to a wiring VCOM. The wiring VCOM supplies a potential for supplying a current to the light-emitting device 61.

Accordingly, the intensity of light emitted from the light-emitting device 61 can be controlled in accordance with an image signal supplied to the gate electrode of the transistor 52B. Furthermore, variations in the gate-source voltage of the transistor 52B can be reduced by the reference potential of the wiring V0 supplied through the transistor 52C.

A current value that can be used for setting of pixel parameters can be output from the wiring V0. Specifically, the wiring V0 can function as a monitor line for outputting a current flowing in the transistor 52B or a current flowing in the light-emitting device 61 to the outside. A current output to the wiring V0 is converted into a voltage by a source follower circuit or the like, and the voltage is output to the outside. Alternatively, a current output to the wiring V0 can be converted into a digital signal by an A-D converter or the like and the digital signal can be output to the functional circuit or the like formed in the layer 62.

A light-emitting device described in one embodiment of the present invention refers to a self-luminous display element such as an organic EL element (also referred to as an organic light-emitting diode (OLED)). Note that the light-emitting device electrically connected to a pixel circuit can be a self-luminous light-emitting device such as a light-emitting diode (LED), a micro LED, a quantum-dot light-emitting diode (QLED), or a semiconductor laser.

In the structure illustrated as an example in FIG. 42B, the wirings electrically connecting the pixel circuit 51 and the driver circuit 65 can be made short, so that the wiring resistance of the wirings can be reduced. Thus, data writing can be performed at high speed, leading to high-speed operation of the display apparatus. Therefore, even when the display apparatus includes a large number of pixel circuits 51, a sufficiently long frame period can be ensured and thus the pixel density of the display apparatus can be increased. In addition, the increased pixel density of the display apparatus can increase the resolution of an image displayed by the display apparatus. For example, the pixel density of the display apparatus can be 1000 ppi or higher, 5000 ppi or higher, or 7000 ppi or higher. Thus, the display apparatus of this embodiment can be, for example, a display apparatus for VR or AR and can be suitably used in an electronic appliance with a short distance between the display portion and the user, such as an HMD.

Although FIGS. 42A and 42B illustrate, as an example, the pixel circuit 51 including three transistors in total, one embodiment of the present invention is not limited thereto. Structure examples and a driving method example of a pixel circuit that can be used for the pixel circuit 51 will be described below.

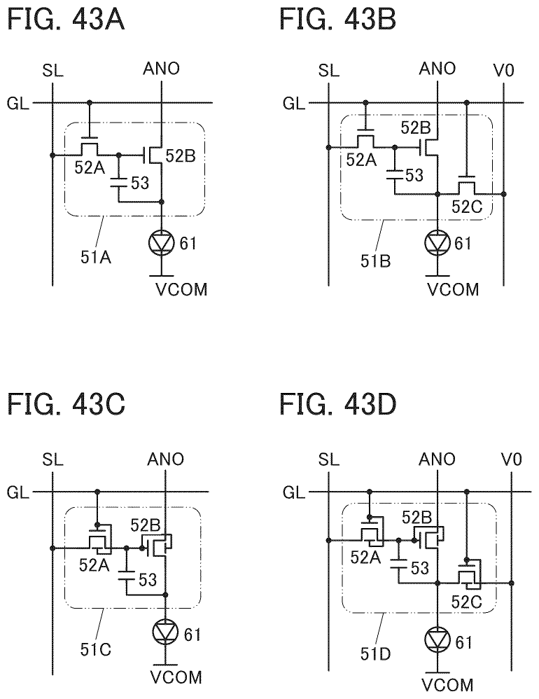

A pixel circuit 51A illustrated in FIG. 43A includes the transistor 52A, the transistor 52B, and the capacitor 53. FIG. 43A also illustrates the light-emitting device 61 connected to the pixel circuit 51A. The wiring SL, a wiring GL, the wiring ANO, and the wiring VCOM are electrically connected to the pixel circuit 51A. The pixel circuit 51A has a structure in which the transistor 52C is removed from the pixel circuit 51 in FIG. 42A and the wirings GL1 and GL2 in FIG. 42A are replaced with the wiring GL.

The gate of the transistor 52A is electrically connected to the wiring GL, one of the source and the drain of the transistor 52A is electrically connected to the wiring SL, and the other of the source and the drain of the transistor 52A is electrically connected to the gate of the transistor 52B and one electrode of the capacitor 53. One of the source and the drain of the transistor 52B is electrically connected to the wiring ANO, and the other of the source and the drain of the transistor 52B is electrically connected to an anode of the light-emitting device 61. The other electrode of the capacitor 53 is electrically connected to the anode of the light-emitting device 61. A cathode of the light-emitting device 61 is electrically connected to the wiring VCOM.

A pixel circuit 51B illustrated in FIG. 43B has a structure in which the transistor 52C is added to the pixel circuit 51A. The wiring V0 is electrically connected to the pixel circuit 51B.

A pixel circuit 51C illustrated in FIG. 43C is an example in which a transistor including a pair of gates electrically connected to each other is used as each of the transistor 52A and the transistor 52B of the pixel circuit 51A. A pixel circuit 51D illustrated in FIG. 43D is an example in which such transistors are used in the pixel circuit 51B. With these structures, a current that can flow through the transistors can be increased. Although a transistor including a pair of gates electrically connected to each other is used as every transistor here, one embodiment of the present invention is not limited thereto. A transistor that includes a pair of gates electrically connected to different wirings may be used. For example, with use of a transistor in which one of gates is electrically connected to a source, the reliability can be increased.

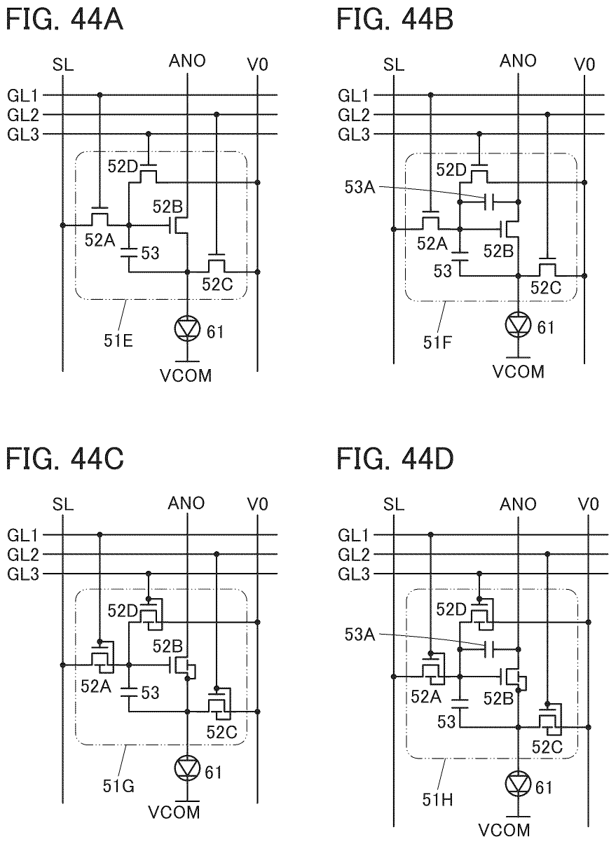

A pixel circuit 51E illustrated in FIG. 44A has a structure in which a transistor 52D is added to the pixel circuit 51B. The wiring GL1, the wiring GL2, and a wiring GL3 serving as gate lines are electrically connected to the pixel circuit 51E. In this embodiment and the like, the wirings GL1, GL2, and GL3 are collectively referred to as the wiring GL in some cases. Thus, the wiring GL may be one wiring or a plurality of wirings.

A gate of the transistor 52D is electrically connected to the wiring GL3, one of a source and a drain of the transistor 52D is electrically connected to the gate of the transistor 52B, and the other of the source and the drain of the transistor 52D is electrically connected to the wiring V0. The gate of the transistor 52A is electrically connected to the wiring GL1, and the gate of the transistor 52C is electrically connected to the wiring GL2.

When the transistors 52C and 52D are turned on at the same time, the source and the gate of the transistor 52B have the same potential, so that the transistor 52B can be turned off. Thus, a current flowing to the light-emitting device 61 can be blocked forcibly. Such a pixel circuit is suitable for the case of using a display method in which a display period and an off period are alternately provided.

A pixel circuit 51F illustrated in FIG. 44B is an example in which a capacitor 53A is added to the pixel circuit 51E. The capacitor 53A functions as a storage capacitor.

A pixel circuit 51G illustrated in FIG. 44C and a pixel circuit 51H illustrated in FIG. 44D are each an example of the case where a transistor including a pair of gates is used in the pixel circuit 51E or the pixel circuit 51F. A transistor in which a pair of gates are electrically connected to each other is used as each of the transistors 52A, 52C, and 52D, and a transistor in which one of gates is electrically connected to a source is used as the transistor 52B.

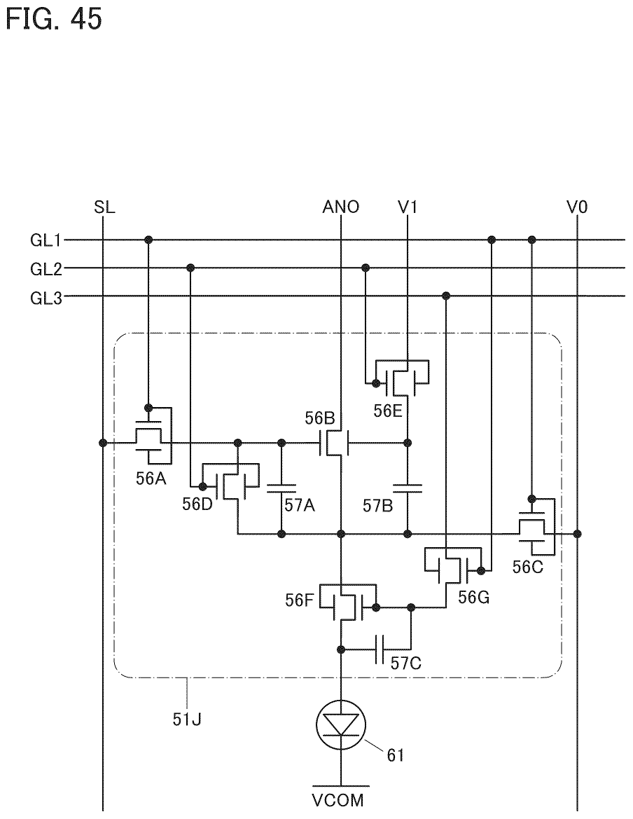

A pixel circuit 51J illustrated in FIG. 45 includes transistors 56A to 56G and capacitors 57A to 57C. The transistors 56A, 56B, and 56C and the capacitor 57A of the pixel circuit 51J can be respectively regarded as corresponding to the transistors 52A, 52B, and 56C and the capacitor 53 of the pixel circuit 51 illustrated in FIG. 42A. Although FIG. 45 illustrates an example in which a gate and a back gate are electrically connected to each other in the transistors 56A, 56C, 56D, 56E, 56F, and 56G, the back gate may be supplied with a given potential without being electrically connected to the gate. Potentials supplied to the back gates are not limited to a fixed potential. The potentials supplied to the back gates of the transistors included in the pixel circuit 51J may be different from each other or may be the same. Not all the transistors included in the pixel circuit 51J necessarily have back gates. The pixel circuit 51J may include transistors having back gates and transistors not having back gates.

In the transistor 56A, the gate is electrically connected to the wiring GL1, a first electrode is electrically connected to the wiring SL, and a second electrode is electrically connected to the gate of the transistor 56B. In the transistor 56B, a first electrode is electrically connected to the wiring ANO, and a second electrode is electrically connected to a first electrode of the transistor 56F. In the transistor 56C, the gate is electrically connected to the wiring GL1, a first electrode is electrically connected to the second electrode of the transistor 56B, and a second electrode is electrically connected to the wiring V0. In the transistor 56D, the gate is electrically connected to the wiring GL2, a first electrode is electrically connected to the gate of the transistor 56B, and a second electrode is electrically connected to the second electrode of the transistor 56B. In the transistor 56E, the gate is electrically connected to the wiring GL2, a first electrode is electrically connected to a wiring V1, and a second electrode is electrically connected to the back gate of the transistor 56B. In the transistor 56F, the gate is electrically connected to a first electrode of the transistor 56G, and a second electrode is electrically connected to an anode of the light-emitting device 61. In the transistor 56G, the gate is electrically connected to the wiring GL1, and a second electrode is electrically connected to the wiring GL2. The capacitor 57A is formed between the gate and the second electrode of the transistor 56B. The capacitor 57B is formed between the back gate and the second electrode of the transistor 56B. The capacitor 57C is formed between the gate and the second electrode of the transistor 56F. A cathode of the light-emitting device 61 is electrically connected to the wiring VCOM. Note that the wiring V1 is a wiring for supplying a potential to the back gate of the transistor 56B.

Electric charge corresponding to image data retained in the capacitors 57A and 57B greatly affects the display quality; hence, the influence of external noise is preferably small. When the capacitors 57A and 57B have a large capacitance, the influence of external noise can be reduced, so that a display apparatus with high display quality can be achieved. The capacitor 57A preferably retains electric charge corresponding to image data in a period longer than one frame period. Similarly, the capacitor 57B preferably retains electric charge corresponding to image data in a period longer than one frame period, preferably longer than or equal to 1 second, further preferably longer than or equal to 1 minute, still further preferably longer than or equal to 1 hour. Thus, the capacitance of the capacitor 57B may be larger than that of the capacitor 57A. Meanwhile, the capacitor 57C may have a smaller capacitance than the capacitors 57A and 57B as long as the capacitor 57C can retain a voltage that can adequately make the transistor 56F in the on state.

Furthermore, when OS transistors are used in the pixel circuit 51J, electric charge corresponding to image data in the capacitors 57A and 57B can be retained for a long time. For example, in the case of displaying a still image for which rewriting per frame is not required, the image can be continuously displayed even when the operation of a peripheral driver circuit is stopped. Such a driving method in which the operation of a peripheral driver circuit is stopped during still image display is also referred to as “idling stop driving”. Power consumption of the display apparatus can be reduced by performing idling stop driving.

Note that a multi-channel transistor may be used in the above pixel circuit. A multi-channel transistor includes a plurality of gates electrically connected to each other and includes, between a source and a drain, a plurality of regions where a semiconductor layer and the gates overlap with each other. That is, a multi-channel transistor includes a plurality of gates electrically connected to each other and a plurality of channel formation regions between a source and a drain. A multi-channel transistor can be regarded as a transistor in which a plurality of single-gate transistors are connected in series such that gates of the transistor are connected to each other.

For example, in the case where a driving transistor or the like operates in a saturation region, the channel length of the transistor may be increased to improve its electrical characteristics in the saturation region. A multi-gate transistor may be used as a transistor having a large channel length.

At least part of this embodiment can be implemented as appropriate in combination with any of the other embodiments described in this specification.

### Embodiment 10

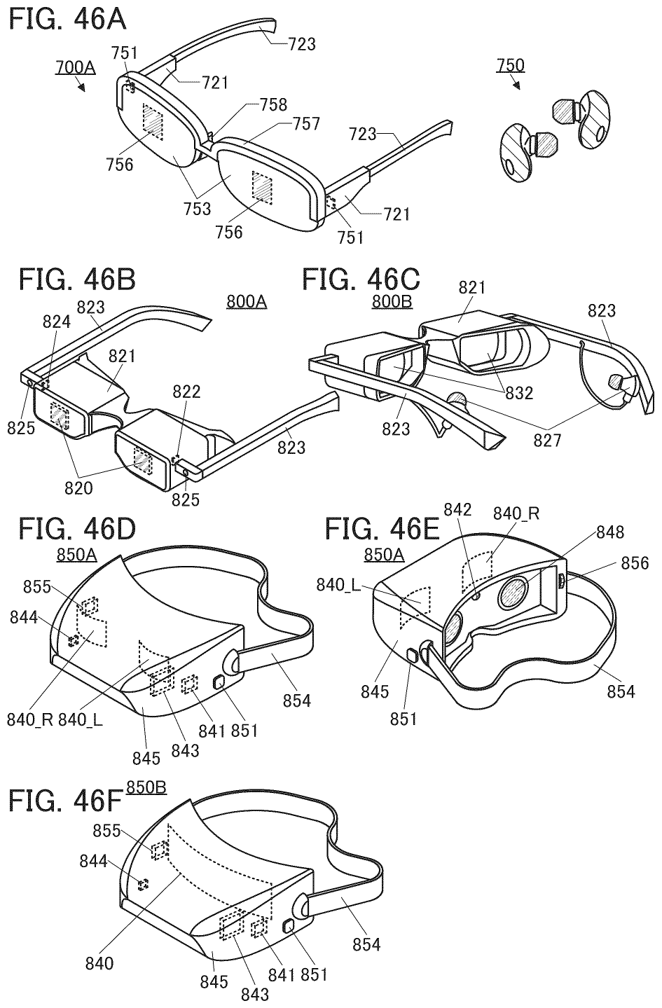

In this embodiment, electronic appliances of embodiments of the present invention will be described with reference to FIGS. 46A to 46F, FIGS. 47A to 47F, and FIGS. 48A to 48G.

A display portion of an electronic appliance in this embodiment includes a display panel (display apparatus) including the transistor of one embodiment of the present invention. The display apparatus of one embodiment of the present invention can be easily increased in resolution and definition and achieve high display quality. Thus, the display apparatus of one embodiment of the present invention can be used for display portions of a variety of electronic appliances.

Examples of electronic appliances include a digital camera, a digital video camera, a digital photo frame, a mobile phone, a portable game console, a portable information terminal, and an audio reproducing device, in addition to electronic appliances with a relatively large screen, such as a television device, desktop and laptop personal computers, a monitor of a computer and the like, digital signage, and a large game machine such as a pachinko machine.

In particular, the display panel of one embodiment of the present invention can have high resolution, and thus can be favorably used for an electronic appliance having a relatively small display portion. Examples of such an electronic appliance include watch-type and bracelet-type information terminals (wearable devices) and wearable devices capable of being worn on a head, such as a VR device like a head-mounted display, a glasses-type AR device, and an MR device.

The definition of the display panel of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display panel of one embodiment of the present invention is preferably higher than or equal to 100 ppi, further preferably higher than or equal to 300 ppi, further preferably higher than or equal to 500 ppi, further preferably higher than or equal to 1000 ppi, further preferably higher than or equal to 2000 ppi, still further preferably higher than or equal to 3000 ppi, still further preferably higher than or equal to 5000 ppi, yet further preferably higher than or equal to 7000 ppi. The use of the display panel having one or both of such high definition and high resolution can further increase realistic sensation, sense of depth, and the like. There is no particular limitation on the screen ratio (aspect ratio) of the display panel of one embodiment of the present invention. For example, the display panel is compatible with a variety of screen ratios such as 1:1 (a square), 4:3, 16:9, and 16:10.

The electronic appliance in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic appliance in this embodiment can have a variety of functions. For example, the electronic appliance in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices are described with reference to FIGS. 46A to 46F. These wearable devices have at least one of a function of displaying AR contents, a function of displaying VR contents, a function of displaying SR contents, and a function of displaying MR contents. The electronic appliance having a function of displaying contents of at least one of AR, VR, SR, MR, and the like enables the user to feel a higher level of immersion.

An electronic appliance 700A illustrated in FIG. 46A includes a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic appliance is capable of performing ultrahigh-resolution display. The semiconductor device of one embodiment of the present invention can be used for the control portion (not illustrated). Accordingly, power consumption of the electronic appliance can be reduced.

The electronic appliance 700A can project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic appliance 700A is an electronic appliance capable of AR display.

In the electronic appliance 700A, a camera capable of capturing images of the front side may be provided as the image capturing portion. Furthermore, when the electronic appliance 700A is provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic appliance 700A is provided with a battery and thus can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a moving image can be paused or restarted by a tap operation, and can be fast-forwarded or fast-reversed by a slide operation. When the touch sensor module is provided in each of the two housings 721, the range of the operation can be increased.

Various touch sensors can be used for the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic appliance 800A illustrated in FIG. 46B and an electronic appliance 800B illustrated in FIG. 46C each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used for the display portions 820. Thus, the electronic appliances are capable of performing ultrahigh-resolution display. Such electronic appliances provide a high sense of immersion to the user. The semiconductor device of one embodiment of the present invention can be used for the control portion 824. Accordingly, power consumption of the electronic appliances can be reduced.

The display portions 820 are positioned inside the housing 821 so as to be seen through the lenses 832. When the pair of display portions 820 display different images, three-dimensional display using parallax can be performed.

The electronic appliances 800A and 800B can be regarded as electronic appliances for VR. The user who wears the electronic appliance 800A or 800B can see images displayed on the display portions 820 through the lenses 832.

The electronic appliances 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic appliances 800A and 800B preferably include a mechanism for adjusting focus by changing the distance between the lenses 832 and the display portions 820.

The electronic appliance 800A or 800B can be mounted on the user's head with the wearing portions 823. FIG. 46B and the like illustrate examples where the wearing portion 823 has a shape like a temple of glasses; however, one embodiment of the present invention is not limited thereto. The wearing portion 823 can have any shape with which the user can wear the electronic appliance, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portions 825 are provided is described here, a range sensor (hereinafter also referred to as a sensing portion) capable of measuring the distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic appliance 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic appliance 800A.

The electronic appliances 800A and 800B may each include an input terminal. To the input terminal, a cable for supplying a video signal from a video output device or the like, electric power for charging the battery provided in the electronic appliance, and the like can be connected.

The electronic appliance of one embodiment of the present invention may have a function of performing wireless communication with earphones 750. The earphones 750 include a communication portion (not illustrated) and have a wireless communication function. The earphones 750 can receive information (e.g., audio data) from the electronic appliance with the wireless communication function. For example, the electronic appliance 700A in FIG. 46A has a function of transmitting information to the earphones 750 with the wireless communication function.

The electronic appliance may include an earphone portion. The electronic appliance 800B in FIG. 46C includes earphone portions 827. For example, the earphone portion 827 can be connected to the control portion 824 by wire. Part of a wiring that connects the earphone portion 827 and the control portion 824 may be located inside the housing 821 or the wearing portion 823. Alternatively, the earphone portions 827 and the wearing portions 823 may include magnets. This structure is preferably employed, in which case the earphone portions 827 can be fixed to the wearing portions 823 with magnetic force and thus can be easily housed.

The electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of a headset by including the audio input mechanism.

FIGS. 46D and 46E are perspective views of a goggles-type electronic appliance 850A for VR. FIGS. 46D and 46E illustrate an example where a housing 845 includes a pair of curved display apparatuses 840 (a display apparatus 840_R and a display apparatus 840_L). The electronic appliance 850A includes a motion detection portion 841, an eye-gaze detection portion 842, an arithmetic portion 843, a communication portion 844, lenses 848, an operation button 851, a wearing tool 854, a sensor 855, a dial 856, and the like.

When the two display apparatuses 840 are provided, the user's eyes can see the respective display apparatuses. This allows a high-resolution image to be displayed even when three-dimensional display using parallax or the like is performed. In addition, the display apparatus 840 is curved around an arc with an approximate center at the user's eye. This keeps a certain distance between the user's eye and the display surface of the display apparatus 840, enabling the user to see a more natural image. Even when having what is called viewing angle dependence where the luminance or chromaticity of light changes depending on a viewing angle, the display apparatus 840 can have a structure where the user's eye is positioned in the normal direction of the display surface of the display apparatus 840; accordingly, the influence of the viewing angle dependence particularly in the horizontal direction can be practically ignored, enabling display of a more realistic video.

As illustrated in FIG. 46E, the lenses 848 are positioned between the display apparatuses 840 and the user's eyes. FIG. 46E illustrates an example where the dial 856 for changing the positions of the lenses for visibility adjustment is provided. Note that in the case where the electronic appliance 850A has an autofocus function, the dial 856 for visibility adjustment is not necessarily provided.

FIG. 46F illustrates a goggles-type electronic appliance 850B including one display apparatus 840. Such a structure can reduce the number of components.

The display apparatus 840 can display an image for the right eye and an image for the left eye side by side on a right region and a left region, respectively. Thus, a three-dimensional image using binocular parallax can be displayed. Note that the display apparatus 840 may display two different images using parallax side by side, or may display two same images side by side without using parallax.

One image that can be seen with both eyes may be displayed on the entire display apparatus 840. In that case, a panorama image can be displayed from end to end of the field of view, which can provide a higher sense of reality.

The display apparatus of one embodiment of the present invention can be used for the display apparatus 840. Since the display apparatus of one embodiment of the present invention has extremely high resolution, a more realistic image can be displayed while the pixels are not perceived by the user even when an image is magnified using the lenses 848.

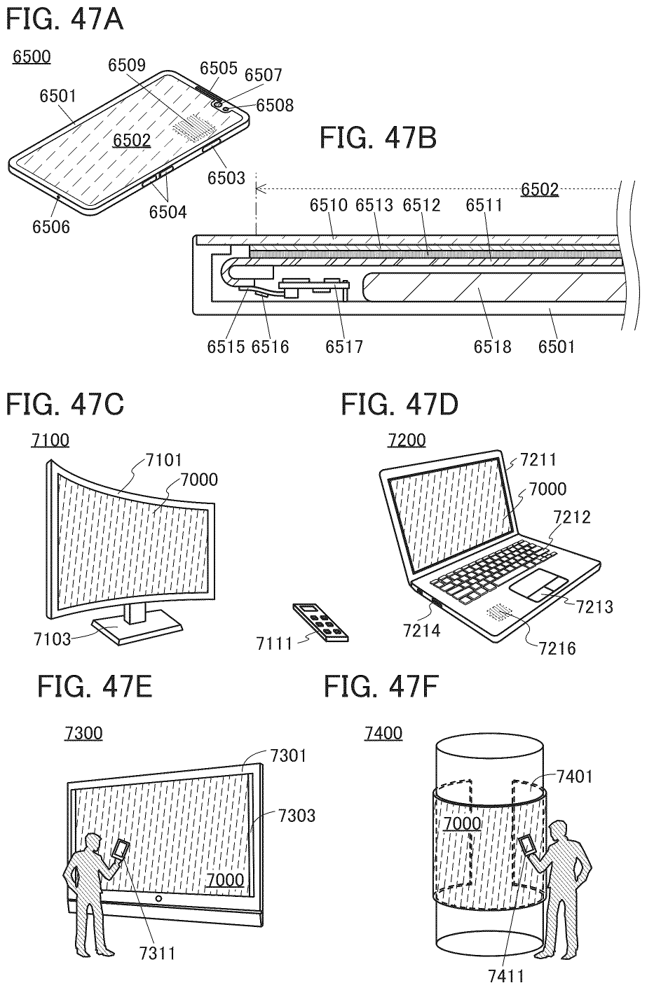

The electronic appliance 6500 illustrated in FIG. 47A is a portable information terminal that can be used as a smartphone.

The electronic appliance 6500 includes the housing 6501, the display portion 6502, the power button 6503, the buttons 6504, the speaker 6505, the microphone 6506, the camera 6507, the light source 6508, the control device 6509, and the like. The display portion 6502 has a touch panel function. Note that as the control device 6509, for example, one or more selected from a CPU, a GPU, and a memory device are included. The semiconductor device of one embodiment of the present invention can be used for the display portion 6502, the control device 6509, and the like. The semiconductor device of one embodiment of the present invention is preferably used for the control device 6509, in which case power consumption can be reduced.

The display panel of one embodiment of the present invention can be used for the display portion 6502.

FIG. 47B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display apparatus of one embodiment of the present invention can be used for the display panel 6511. Thus, an extremely lightweight electronic appliance can be achieved. Since the display panel 6511 is extremely thin, the battery 6518 with high capacity can be mounted without an increase in the thickness of the electronic appliance. An electronic appliance with a narrow bezel can be obtained when part of the display panel 6511 is folded back so that the portion connected to the FPC 6515 is provided on the back side of a pixel portion.

FIG. 47C illustrates an example of a television device. In a television device 7100, a display portion 7000 is incorporated in a housing 7101. Here, the housing 7101 is supported by a stand 7103.

Operation of the television device 7100 illustrated in FIG. 47C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 47D illustrates an example of a notebook personal computer. A laptop personal computer 7200 includes a housing 7211, a keyboard 7212, a pointing device 7213, an external connection port 7214, a control device 7216, and the like. The display portion 7000 is incorporated in the housing 7211. As the control device 7216, for example, one or more selected from a CPU, a GPU, and a memory device are included. The semiconductor device of one embodiment of the present invention can be used for the display portion 7000, the control device 7216, and the like. The semiconductor device of one embodiment of the present invention is preferably used for the display portion 7000, the control device 7216, and the like, in which case power consumption can be reduced.

FIGS. 47E and 47F illustrate examples of digital signage.

Digital signage 7300 illustrated in FIG. 47E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 47F illustrates digital signage 7400 attached to a cylindrical pillar 7401. The digital signage 7400 includes the display portion 7000 provided along a curved surface of the pillar 7401.

A larger area of the display portion 7000 can increase the amount of information that can be provided at a time. The display portion 7000 having a larger area attracts more attention, so that the effectiveness of the advertisement can be increased, for example.

A touch panel is preferably used for the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIGS. 47E and 47F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

The display panel of one embodiment of the present invention can be used for the display portion 7000 in each of FIGS. 47C to 47F.

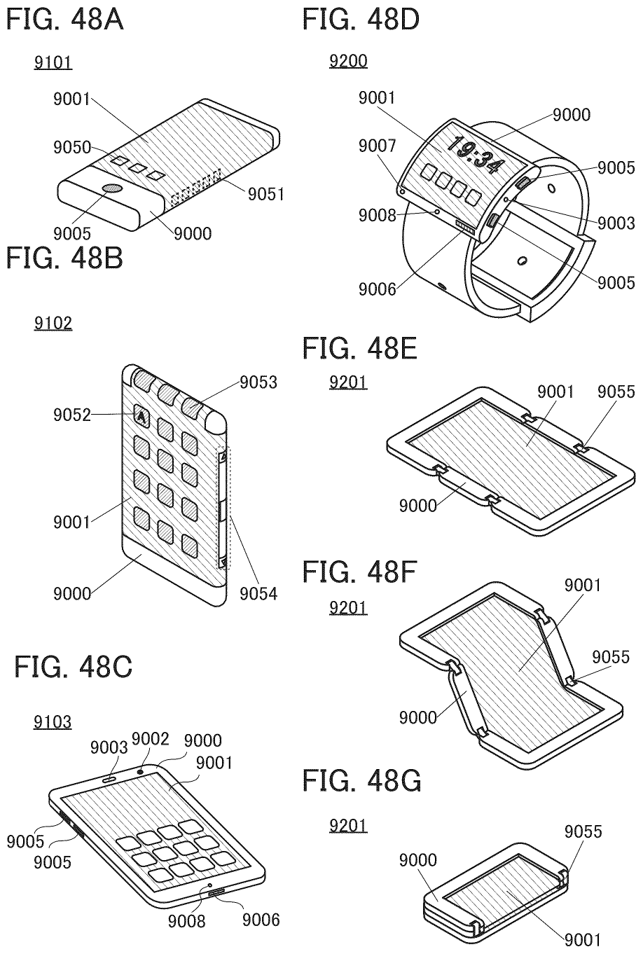

Electronic appliances illustrated in FIGS. 48A to 48G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, a smell, or infrared rays), a microphone 9008, and the like.

The electronic appliances illustrated in FIGS. 48A to 48G have a variety of functions. For example, the electronic appliances can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, a function of reading out and processing a program or data stored in a recording medium, and the like. Note that the functions of the electronic appliances are not limited thereto, and the electronic appliances can have a variety of functions. The electronic appliances may include a plurality of display portions. The electronic appliances may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic appliances in FIGS. 48A to 48G are described in detail below.

FIG. 48A is a perspective view illustrating a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 48A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 48B is a perspective view of a portable information terminal 9102. The portable information terminal 9102 has a function of displaying information on three or more surfaces of the display portion 9001. Here, an example in which information 9052, information 9053, and information 9054 are displayed on different surfaces is described. For example, the user of the portable information terminal 9102 can check the information 9053 displayed such that it can be seen from above the portable information terminal 9102, with the portable information terminal 9102 put in a breast pocket of his/her clothes. Thus, the user can see the display without taking out the portable information terminal 9102 from the pocket and decide whether to answer the call, for example.

FIG. 48C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 48D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 48E to 48G are perspective views of a foldable portable information terminal 9201. FIG. 48E is a perspective view illustrating the portable information terminal 9201 that is opened. FIG. 48G is a perspective view illustrating the portable information terminal 9201 that is folded. FIG. 48F is a perspective view illustrating the portable information terminal 9201 that is shifted from one of the states in FIGS. 48E and 48G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

At least part of this embodiment can be implemented as appropriate in combination with any of the other embodiments described in this specification.

This application is based on Japanese Patent Application Serial No. 2024-003487 filed with Japan Patent Office on Jan. 12, 2024, Japanese Patent Application Serial No. 2024-003489 filed with Japan Patent Office on Jan. 12, 2024, and Japanese Patent Application Serial No. 2024-022000 filed with Japan Patent Office on Feb. 16, 2024, the entire contents of which are hereby incorporated by reference.

What is claimed is:

1. A semiconductor device comprising:
an oxide semiconductor;
a first conductor and a second conductor separated from each other over the oxide semiconductor;
a first insulator over the first conductor and the second conductor, the first insulator comprising an opening overlapping with a region between the first conductor and the second conductor;
a second insulator in the opening, the second insulator being in contact with a top surface of the oxide semiconductor; and
a third conductor over the second insulator in the opening, the third conductor comprising a region overlapping with the oxide semiconductor with the second insulator therebetween,
wherein the oxide semiconductor comprises a first layer, a second layer over the first layer, and a third layer over the second layer in a region overlapping with the third conductor,
wherein the first layer comprises gallium and oxygen,
wherein the second layer comprises indium oxide,
wherein the third layer comprises indium, gallium, and oxygen, and
wherein an indium content of the second layer is higher than an indium content of the third layer.

2. The semiconductor device according to claim 1,
wherein a conduction band minimum of the first layer is closer to a vacuum level than a conduction band minimum of the second layer is, and
wherein a conduction band minimum of the third layer is closer to the vacuum level than the conduction band minimum of the second layer is.

3. The semiconductor device according to claim 1,
wherein the first layer comprises indium, and
wherein an indium content is lower than a gallium content in the first layer.

4. The semiconductor device according to claim 1,
wherein in a plan view, a side surface of part of the first insulator is aligned or substantially aligned with a side surface of the first conductor and a side surface of the second conductor.

5. The semiconductor device according to claim 1, further comprising:
a third insulator in contact with a top surface of the third conductor, an upper end portion of the second insulator, and a top surface of the first insulator; and
a fourth insulator in contact with a top surface of the third insulator.

6. The semiconductor device according to claim 5,
wherein the third insulator comprises aluminum oxide.

7. The semiconductor device according to claim 6,
wherein the fourth insulator comprises silicon nitride.

8. The semiconductor device according to claim 1,
wherein the first conductor and the second conductor each comprise a first conductive layer and a second conductive layer over the first conductive layer, and
wherein a shortest distance between the first conductive layer of the first conductor and the first conductive layer of the second conductor is smaller than a shortest distance between the second conductive layer of the first conductor and the second conductive layer of the second conductor.

9. The semiconductor device according to claim 8,
wherein in a plan view, a side surface of part of the first insulator is aligned or substantially aligned with a side surface of the second conductive layer of the first conductor and a side surface of the second conductive layer of the second conductor.

10. The semiconductor device according to claim 8,
wherein the first conductive layer of the first conductor and the first conductive layer of the second conductor each comprise tantalum nitride.

11. The semiconductor device according to claim 8, further comprising:
a fifth insulator,
wherein the fifth insulator is in the opening and is in contact with a top surface of the first conductive layer of the first conductor, a side surface of the second conductive layer of the first conductor, a top surface of the first conductive layer of the second conductor, and a side surface of the second conductive layer of the second conductor, and
wherein the fifth insulator comprises an opening overlapping with a region between the first conductive layer of the first conductor and the first conductive layer of the second conductor.

12. The semiconductor device according to claim 11,
wherein the fifth insulator comprises silicon nitride.

13. The semiconductor device according to claim 1,
wherein the second insulator comprises a first insulating layer, and
wherein the first insulating layer comprises oxide comprising hafnium.

14. The semiconductor device according to claim 13,
wherein the first insulating layer comprises hafnium zirconium oxide.

15. The semiconductor device according to claim 14,
wherein the second insulator comprises a second insulating layer over the first insulating layer, and
wherein the second insulating layer comprises silicon nitride.

16. The semiconductor device according to claim 14,
wherein a top surface of the first insulating layer is in contact with the third conductor.

17. The semiconductor device according to claim 1,
wherein the first layer and the second layer comprise crystallinity.

18. A memory device comprising the semiconductor device according to claim 1.

19. A display apparatus comprising the semiconductor device according to claim 1.

20. An electronic appliance comprising the semiconductor device according to claim 1.
